(19) United States
(12) Patent Application Publication
(10) Pub. No.: US 2017/0338476 A1
(43) Pub. Date: Nov. 23, 2017

(54) NANOSILICON MATERIAL PREPARATION FOR FUNCTIONALIZED GROUP IVA PARTICLE FRAMEWORKS

(71) Applicant: Kratos LLC, Lexington, SC (US)

(72) Inventors: Timothy D. Newbound, Chelsea, MI (US); Leslie Matthews, Mount Pleasant, UT (US); Jeff A. Norris, Lexington, SC (US); Jaroslaw Syzdek, Pittsburg, CA (US)

(21) Appl. No.: 15/665,623

(22) Filed: Aug. 1, 2017

Related U.S. Application Data
(63) Continuation of application No. 14/627,955, filed on Feb. 20, 2015.
(60) Provisional application No. 62/113,285, filed on Feb. 6, 2015.
(60) Provisional application No. 62/061,020, filed on Oct. 7, 2014.
(60) Provisional application No. 61/943,005, filed on Feb. 21, 2014.

(51) Int. Cl. H01M 4/36; C07F 7/02; B05D 1/40; B05D 5/00; H01M 4/62; H01M 4/42; H01M 4/38; H01M 4/1399; H01M 4/1395; H01M 4/1393; H01M 10/0565; H01M 4/04; H01L 31/0224; C07F 15/04; C07F 7/30; C07F 7/22; B05D 1/28; B05D 1/12; H01M 10/052

(52) U.S. Cl. CPC H01M 4/366; B05D 1/12; C07F 7/025; B05D 1/40; B05D 5/00; H01M 4/62; H01M 4/42; H01M 4/387; H01M 4/386; H01M 4/38; H01M 4/1399; H01M 4/1395; H01M 4/1393; H01M 10/0565; H01M 4/0419; H01M 4/0414; H01M 4/0409; H01L 31/022425; C07F 15/04; C07F 7/30; C07F 7/22; B05D 1/28; H01M 4/0471; H01M 10/052; Y02P 70/54; Y02E 60/122; H01M 2300/0082

(57) ABSTRACT

Functionalized Group IVA particles, methods of preparing the Group IVA particles, and methods of using the Group IVA particles are provided. The Group IVA particles may be passivated with at least one layer of material covering at least a portion of the particle. The layer of material may be a covalently bonded non-dielectric layer of material. The Group IVA particles may be used in various technologies, including lithium ion batteries and photovoltaic cells.

### CROSS-REFERENCE TO RELATED APPLICATION(S)

This is a continuation of U.S. patent application Ser. No. 14/627,955, filed on Feb. 20, 2015, which claims priority to U.S. Provisional Patent Application No. 62/113,285, filed on Feb. 6, 2015, U.S. Provisional Patent Application No. 62/061,020, filed on Oct. 7, 2014, and U.S. Provisional Patent Application No. 61/943,005, filed on Feb. 21, 2014, the entire contents of all of which are fully incorporated herein by reference.

### TECHNICAL FIELD

The present disclosure relates generally to functionalized Group IVA particles, composites including the functionalized Group IVA particles, and methods of preparation and use thereof.

### BACKGROUND

A battery is an electrochemical energy storage device. Batteries can be categorized as either primary (non-rechargeable) or secondary (rechargeable). In either case, a fully charged battery delivers electrical power as it undergoes an oxidation/reduction process and electrons are allowed to flow between the negative and positive polls of the battery. There is a need for materials and methods that improve upon existing battery technology.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 depicts a simplified representation of passivated Group IVA particles.

FIG. 2 depicts a simplified representation of a modification reaction from particle 2 to particle 3.

FIG. 3 depicts Group IVA nanoparticles functionalized with 2,3,6,7-tetrahydroxylanthracene groups.

FIG. 4 depicts one exemplary process for preparing functionalized Group IVA particles.

FIG. 5 depicts one exemplary composite for c-Si conductive films.

FIG. 6 depicts a lithium ion battery using a silicon-covalent porous framework anode.

FIG. 7 depicts a simplified representation of an anode material including functionalized Group IVA particles.

FIG. 8 depicts a simplified representation of an anode material including functionalized Group IVA particles and a conductive adhesion additive.

FIG. 9 depicts a simplified representation of an anode material including functionalized Group IVA particles, and a conductive adhesion additive and/or a dopant additive.

FIG. 10 depicts a porous framework composite including functionalized Group IVA particles.

FIG. 11 depicts one exemplary process for preparing a battery including functionalized Group IVA particles.

FIG. 12 depicts a schematic diagram of a photovoltaic cell including a semiconductor film incorporating functionalized Group IVA particles.

FIG. 13 depicts Si XPS spectroscopy comparing metallurgical Si milled: in heptane under aerobic conditions (top), and in mesitylene with added pyrene under aerobic versus anaerobic conditions (center and bottom, respectively). The Si 2p XPS signal was deconvoluted to illustrate the different surface compositions that result from comminution of metallurgical silicon in a passivating solvent (mesitylene) versus a non-passivating solvent (n-heptane) and anaerobic versus aerobic conditions. This study demonstrates that milled under anaerobic conditions in a passivating solvent such as mesitylene, the Si surfaces are practically free of SiO₂ and only a small contribution from SiOₓ can be observed. It has not been determined what portion of the residual oxygen that was observed under anaerobic conditions can be attributed to nascent oxides in the metallurgical silicon or what was formed in the milling process. Detection limits for SiOₓ are on the order of parts per thousand. No quantitative standardization was used for this study.

FIG. 14 depicts PXRD scans showing metallurgical silicon ground with a mortar and pestle to 325+ mesh (top) compared with metallurgical silicon milled anaerobically in mesitylene for 1 hr (middle) and for 6 hrs (bottom). PXRD data were collected with a Scintag X₂ powder X-ray diffractometer operating in the 2θ mode. The X-ray power was 45 kV @ 40 mA using CuK_{α1} radiation (λ=1.537395 Å). The θ range was 5-80° stepped in 0.02° increments with 1.00 s exposures per step. The samples were prepared on glass microscope slides and were embedded in a thin film of Dow Corning high-vacuum grease. No background correction was necessary (a very broad and very weak background diffraction peak centered at 12° was observed). The first sample was finely ground material with a mortar and pestle then passed through a 325 mesh sieve. Particle size distribution was estimated ca. 20-45 μm. This material had a BET surface area ≦0.7 m²/g. Note the relatively sharp diffraction peaks for this sample, entirely normal for crystalline silicon. The other samples were nanoparticles milled in mesitylene plus pyrene. The diffraction peaks become broader as the particle size decreases. However, note that the positions of the most intense peaks have not shifted, which indicates that the crystalline state of metallurgical silicon does not change during the milling process.

FIG. 15 depicts charge/discharge cycles for a Si-NP negative electrode composite with graphite and Li PA polymer made from aqueous slurry. The negative electrode was paired with a NCM523 counter electrode, with both referenced to a Li reference electrode.

FIG. 16 depicts charge/discharge cycles for the disclosed Si-NP negative electrode composite with graphite and PVDF polymer made in NMP solvent. The negative electrode was paired with a NCM523 counter electrode, with both referenced to a Li reference electrode.

FIG. 17 depicts an SEID diagram corresponding to FIG. 16.

### DETAILED DESCRIPTION

Disclosed are functionalized Group IVA particles, composites and compositions including the functionalized Group IVA particles, and methods of preparation and use thereof. The disclosed functionalized Group IVA particles may be substantially oxide free at the particle surface. The functionalized Group IVA particles, as a consequence, can exhibit thermal and kinetic stability, and improved electrical conductance between the core nanoparticles. Reduction or elimination of oxides at the particle surface enhances the stability and conductance of the particles, as oxides act as electrical insulators that inhibit lithiation of lithium-active alloys that may be present in the particle core.

The disclosed functionalized Group IVA particles may be prepared as mixed phase or alloy materials including at least one Group IVA element, and optionally one or more elements. The mixed phase or alloy material can be prepared by an anaerobic milling process. The milling process may be conducted under conditions (e.g., tip speed, bead size, time) to change the morphology of the milled materials to provide an amorphous- or mixed-phase (e.g., alloy) core material. Mill tip speed may create a velocity to bind elements together without using heat. Conductive metals in the Group IVA particle core material can provide improved conductivity, as these form amorphous and mixed-phase particles.

The disclosed functionalized Group IVA particles can be prepared by “top down” methods. Consequently, the disclosed particles can be manufactured using low cost materials, equipment, and processes as compared to “bottom up” methods, such as sputtering, plasmas and vapor deposition. For example, the functionalized Group IVA particles and composites can be prepared from micron-sized bulk materials by anaerobic milling (e.g., in glove box) in the presence of surface-modifying agents that form surface-protecting or surface-conducting layers on the produced nano-sized particles, with the surface preferably being substantially oxide free.

The disclosed functionalized particles and composites can be provided as a dispersion to prepare anode films. An exemplary dispersion includes the anaerobically milled nano-particle composite, optionally one or more carbon conducting additives, optionally one or more polymer binding agents, and optionally one or more solvents. Also provided are methods of disposing the dispersions on a conductive current collector to form active high capacity electrodes for lithium-ion batteries.

The disclosed functionalized particles and composites can be provided in anodes and batteries comprising the functionalized Group IVA particles, composites, and compositions, and methods of preparation and use thereof. The functionalized Group IVA particles and composites can provide an active material for high capacity lithium-ion batteries, forming an electrode composite that resists discharge capacity fade over multiple charge/discharge cycles. The disclosed functionalized Group IVA particles may be stabilized for electrochemical cycling by the surface modification. The functionalized Group IVA particles may have a particle size distribution (e.g., 20-150 nanometers) below the threshold where particle volume changes would otherwise lead to stress fracturing and disintegration of particles upon use in a lithium-ion battery. Lithium-ion batteries (LIBs) with anodes made, for example, from metallurgical silicon milled in an anaerobic and anhydrous environment (e.g., in a glovebox) can have a higher capacity, allow for more silicon nanoparticles per unit area of the current collector, can undergo lower discharge capacity fade, can charge and discharge faster than comparable nanoparticles that have been milled in the presence of oxygen or water, or any combination thereof.

The disclosed anodes (e.g., anode films) can be pre-lithiated. For example, an anode film can be contacted with a lithium source (e.g., a lithium foil) under a closed electrical circuit, such that the negative electrode (e.g., the anode film) behaves as a cathode and the foil behaves as an anode, where the foil pumps lithium into the negative electrode. The pre-lithiated anode may thereafter be incorporated into a LIB. The disclosed anode pre-lithiation can prevent depletion of lithium from the electrolyte present in a lithium-ion battery (e.g., prevents lithium depletion before the first cycle). Pre-lithiation thus prevents depletion of lithium in the battery. Pre-lithiation may also reduce swelling of the anode and prevent or reduce undesired SEI build-up, allowing establishment of a stable SEI layer.

The flexibility of the disclosed production process of Si-NPs entails in situ addition of a surface modifier that functions as a passivation layer to prevent the formation of surface oxides when particles are exposed to air and moisture. The surface modifier allows good ohmic contacts and free movement of Li across the Si particle surface. The surface modifier is electrochemically stable and is chemically bonded to the Si surface. It also maintains coverage of the Si particle surface while allowing for particle expansion and contraction. Superior performance on the first cycle may be attributed to the absence of SiOₓ on the particle surface as a result of the unique manufacturing process and passivating surface modifier. The low loss of Li to SiOₓ reduction translates to high FCE, enhanced electronic and ionic contact (no Li₂O on particle surface), and control over SEI formation.

While polymeric binders are useful components of electrode composites in lithium-ion battery manufacturing, typical processes common in the art produce Si-NPs with surfaces that are incompatible with certain polymer binders such as polyvinylidene fluoride (PVDF). However, the surface modification of Group IVA NPs described herein removes the constraints imposed by the electrochemical environment on the NP surface. Hence, the present disclosure provides the ability to combine a surface modified particle with polymeric binders such as PVDF and provide an unexpected advantage over existing surface modification and nanoparticle production technology. This compatibility represents a drop-in method for the production of Si-NPs and LIB electrodes that is beneficial in the production of lithium ion batteries.

Also disclosed are methods to form stable SEI dendrites from lithium salts and other electrolyte additives prior to assembling the battery that significantly reduces irreversible losses of the Li+ content in the electrolyte. One exemplary approach includes pre-soaking an anode comprising the functionalized Group IVA particles or composite in a solution containing Li⁺R₃NB₁₂H₁₁⁻, Li⁺R₃NB₁₂F₁₁⁻, (H₃N)₂B₁₂H₁₀, (H₃N)₂B₁₂F₁₀, LiAl(OR_{F})₄, or any combination thereof.

In addition, it has been surprisingly discovered that alkane solvents (e.g., heptane, hexane) can be used as the solvent in the disclosed milling processes to provide Group IVA particles. The alkane solvent is preferably non-reactive with freshly exposed Group IVA surfaces (e.g., silicon surfaces) produced by the milling process.

Use of alkanes as the milling solvent in the disclosed anaerobic milling processes provides several advantages. As one advantage, use of the alkane milling solvent (e.g., heptane) provides particles with less carbon on the surface than when milling is conducted in the presence of aromatic solvents. As another advantage, use of the alkane milling solvent provides processing and manufacturing flexibility. A single batch of milled material can be produced, which can be subsequently portioned as desired and modified as desired. For example, when Group IVA particles are milled under anaerobic conditions using an alkane solvent (e.g., heptane), surface-modification and addition of one or more optional additives can be delayed until the milling process is complete. The alkane can thereafter be removed to provide a nanoparticle material useful for construction of anodes for lithium ion batteries. As another advantage, use of the alkane milling solvents enhances preparation of synthetic SEI layers. A lithium aluminum alkoxide, lithium ammonia borofluoride, ammonia borofluoride, or a combination thereof can be used in the milling step, post-milling, or a combination thereof to prepare functionalized Group IVA particles and composites. This procedure allows for preparation of a synthetic SEI layer prior to incorporation of an anode comprising the particles into a lithium ion battery.

Furthermore, solvents may be chosen for the comminution process that promote the dispersion of graphite, carbon black, polymer binders and other components added to make homogenous electrode slurries. As such, group IVA NPs dispersed in the solvents in the comminution procedure may be used directly to make slurries for electronic film manufacturing. This creates several advantages that lower the cost of manufacturing. In particular the following may be realized: two steps in the manufacturing process are eliminated (stripping of solvent from the comminution slurry and re-dispersion of the NPs in another solvent, which usually requires sonication); NPs can be handled as slurries rather than as potentially hazardous dry powders; NPs dispersed in concentrated hydrocarbon slurries are generally more stable towards oxidation, adding further protection against oxidation with exposure to air; and less solvent is needed for the formation of electrode slurries.

The disclosed methods allow for the production of a synthetic SEI layer around functionalized Group IVA particles and composites. Generally, SEI layers are polymers that form around anode materials upon degradation of electrolyte solvent (e.g., ethylene carbonate) upon applied electrochemical potential to a cell, with these layers incorporating lithium into the matrix. The polymer forms around active sites where electrochemical potential is high. While the SEI layer allows for migration of lithium ions between the positive and negative electrodes, excessive formation of SEI layer can impede the insertion and deinsertion of lithium. Moreover, too much SEI layer formation can result in the loss of ohmic contacts necessary for proper anode function. The presently disclosed methods provide for the formation of a synthetic SEI layer prior to placement of a prepared anode material into a lithium ion battery. By forming the synthetic SEI layer (e.g., by treating a milled or post-milled material with a lithium aluminum alkoxide, lithium ammonia borofluoride, or an ammonia borofluoride) prior to the first charging of a battery comprising the treated anode material, the electrolyte solvent (e.g., carbonate solvents) will have limited or no access to active sites of the anode materials, and further SEI layer formation will be prevented or reduced. Consequently, lithium can migrate freely between the positive and negative electrodes. The synthetic SEI layer may prevent or reduce uncontrolled SEI growth, and can accommodate for the expansion and contraction of the anode material upon lithium insertion and deinsertion without loss of the anode material integrity.

The disclosed methods provide the further advantage that the anode materials can contain a higher weight percent of Group IVA material (e.g., silicon) compared to other anode materials based on Group IVA elements. With a higher weight percentage of silicon, for example, the disclosed anodes can be used to manufacture lithium ion batteries with superior performance (e.g., capacity, fade) and at less cost.

Taken together, the present disclosure provides scalable, inexpensive, and environmentally friendly drop-in methods for the production of Si-NPs for the production of LIB electrodes, such that independently validated processes and methods can be developed to allow LIB manufacturers to produce commercial Si based LIBs that perform in line with plug-in electric vehicle objectives among other applications.

The negative electrode composites made with the disclosed Si-NPs provide several performance and manufacturing advantages that overcome shortcomings of state-of-the-art silicon-based electrodes. These advantages include first cycle coulombic efficiency (FCE), coulombic efficiency (CE), capacity retention, scalability, and cost of manufacturing (energy and money). In contrast to existing methods of producing electrodes with silicon, the disclosed processes provide advantages in terms of both cost and energy requirements. As such, the disclosed Si-NPs can be deployed into existing manufacturing processes given they function in both aqueous and non-aqueous systems and work with a variety of solvents and binders. Given the process flexibility, the disclosed Si-based electrodes can be easily paired with next generation high capacity and high voltage cathodes as they become available.

### 1. Definition of Terms

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing of the present invention. All publications, patent applications, patents and other references mentioned herein are incorporated by reference in their entirety. The materials, methods, and examples disclosed herein are illustrative only and not intended to be limiting.

As used in the specification and the appended claims, the singular forms “a,” “an” and “the” include plural references unless the context clearly dictates otherwise. The terms “comprise(s),” “include(s),” “having,” “has,” “can,” “contain(s),” and variants thereof, as used herein, are intended to be open-ended transitional phrases, terms, or words that do not preclude the possibility of additional acts or structures. The present disclosure also contemplates other embodiments “comprising,” “consisting of” and “consisting essentially of,” the embodiments or elements presented herein, whether explicitly set forth or not.

The modifier “about” used in connection with a quantity is inclusive of the stated value and has the meaning dictated by the context (for example, it includes at least the degree of error associated with the measurement of the particular quantity). The modifier “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5 to 1.4.

The conjunctive term “or” includes any and all combinations of one or more listed elements associated by the conjunctive term. For example, the phrase “an apparatus comprising A or B” may refer to an apparatus including A where B is not present, an apparatus including B where A is not present, or an apparatus where both A and B are present. The phrases “at least one of A, B, . . . and N” or “at least one of A, B, . . . N, or combinations thereof” are defined in the broadest sense to mean one or more elements selected from the group comprising A, B, . . . and N, that is to say, any combination of one or more of the elements A, B, . . . or N including any one element alone or in combination with one or more of the other elements which may also include, in combination, additional elements not listed.

The term “lithium-active element,” as used herein, refers to elements that readily combine with lithium reversibly to form multiple phases or alloys.

The term “lithium-active,” as used herein, refers to the property of an element or compound to combine with lithium reversibly to form multiple phases or alloys.

The term “lithium-non-active,” as used herein, refers to the absence of lithium-active properties.

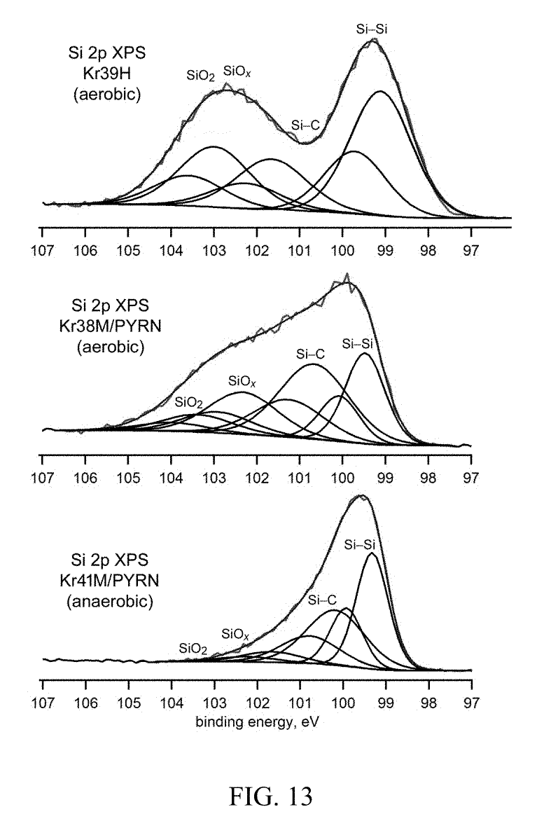

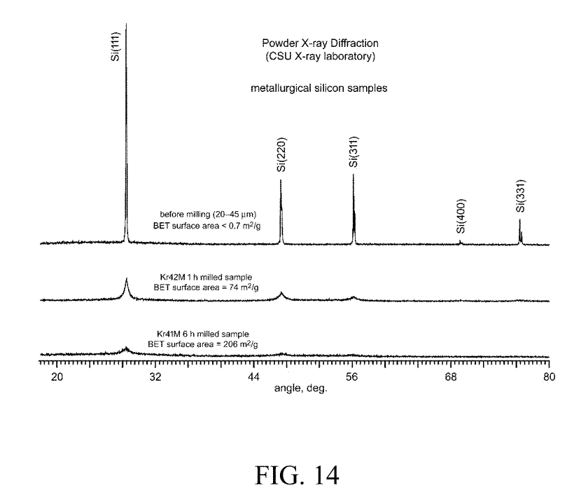

The term “substantially oxide free,” as used herein, refers to materials that exhibit Si 2p XPS signals (ppt) near or below the detection limit for SiO₂ and SiOₓ, for example as shown FIG. 13.

The term “Group IVA element,” as used herein, refers to C, Si, Ge, Sn, Pb. The Group IVA designation is CAS nomenclature. This group is otherwise known as Group 14 or the Crystallogens.

The term “surface-modifier,” as used herein, refers to any element or compound that is bonded to the surface of the Group IVA particles.

The term “passivate,” as used herein refers to treating or modifying the surface to make it less reactive chemically. The surface modifier can be bonded reversibly or non-reversibly.

The term “non-competing solvent,” as used herein, refers to solvents like normal alkanes (heptane) that do not “compete” with active sites on the particle surfaces.

The term “mixed-phase,” as used herein, refers to any compound or particle composed of multiple distinct solid phases.

The term “crystalline phase,” as used herein, refers to solid material whose constituent atoms, molecules or ions et cetera are arranged in an ordered pattern extending in all three spatial dimensions.

The term “polycrystalline phase,” as used herein, refers to a crystalline form that is composed of small crystallites or “grains” divided by grain boundaries and in which the crystalline planes of each grain may be randomly oriented or in some preferred alignment with respect to one another.

The term “amorphous phase,” as used herein, refers to a solid with no crystalline structure.

The term “homogenous phase,” as used herein, refers to a single solid phase, as opposed to a material composed of a conglomeration or mixture of two or more phases.

The term “capacity,” as used herein, refers to discharge capacity, or capacity to accept Li or Li+.

The term “fade,” as used herein, refers to loss in discharge capacity described as a percentage of the initial discharge capacity per cycle or per X cycles.

The term “Dcap,” as used herein, refers to discharge capacity.

The term “SEI,” as used herein refers to solid electrolyte interphase.

The term “pre-lithiation,” as used herein refers to loading with lithium prior to assembling into a cell.

The term “lithium insertion capacity,” as used herein refers to the capacity of the lithium-active material to accept lithium into the body of the particle.

The term “core material,” as used herein refers to the composition of the nanoparticle at or beneath the surface of the particle.

The term “BET surface areas,” as used herein refers the surface area of a material as measured by Brunauer-Emmett-Teller (BET) theory based on the physical adsorption of gas molecules on a solid surface.

The term “inert atmosphere,” as used herein refers to non-reactive gas atmosphere. Dinitrogen and argon are generally used.

The term “tip speed,” or “tip velocity,” as used herein refers to the velocity at the tip of the agitator as measured by rotational rate times the circumference of the outer radius.

The term “anhydrous,” as used herein refers to absent of adsorbed water.

The term “anaerobic,” as used herein refers to the condition of being absent of oxygen and moisture.

The term “functionalized Group IVA particle,” as used herein refers to a nano- to micrometer-sized particle including one or more Group IVA elements (e.g., carbon, silicon, germanium, tin, lead) where at least one surface of the Group IVA particle is modified with a surface-modifier. The mechanism of surface modification can be one or more of, for example, physisorption, chemisorption, or adsorption. In certain embodiments, a surface modifier may interact with the surface of a core material of the Group IVA particle by physisorption. In certain embodiments, a surface modifier may interact with a core material of the Group IVA particle by chemisorption. In certain embodiments, a surface modifier may interact with a core material of the Group IVA particle by a combination of physisorption and chemisorption. The surface modifier may provide a monolayer over the core material of the Group IVA nanoparticle, and optionally one or more additional layers associated with the surface-modier.

The term “polyvinylidene fluoride,” as used herein refers to a thermoplastic fluoropolymer produced by the polymerization of vinylidene difluoride. It may also be referred to as “polyvinylidene difluoride” and/or “PVDF.” The polyvinylidene fluoride may have a molecular weight of about 200,000 g/mol to about 1,500,000 g/mol. For example, the molecular weight may be about 200,000, about 300,000, about 400,000, about 500,000, about 600,000, about 700,000, about 800,000, about 900,000, about 1,000,000, about 1,100,000, about 1,200,000, about 1,300,000, about 1,400,000, or about 1,500,000.

### 2. Functionalized Group IVA Particles

In one aspect, disclosed are functionalized Group IVA particles, also referred to herein as “surface-modified Group IVA particles,” “passivated Group IVA particles,” or a derivative term thereof. The functionalized Group IVA particles include a core material comprising one or more Group IVA elements, wherein at least one surface of the core material is modified by a surface-modifying chemical entity.

The surfaces of the functionalized Group IVA particle may be substantially oxide-free (e.g., the Group IVA particle may be surface-modified such that the surface of the Group IVA particle is substantially oxide free). The functionalized Group IVA particles may be substantially free of native oxides (e.g., silicon oxide) and the surface of the particle may be passivated toward reaction to oxygen and moisture in the atmosphere. In certain embodiments, the outer surface of the functionalized Group IVA particle has a SiOₓ content of less than or equal to 1 part per thousand, less than equal to 1 part per million, or less than equal to 1 part per trillion, as characterized by X-ray photoelectron spectroscopy (XPS) or as assessed by XPS, wherein x is less than or equal to 2. In certain embodiments, the outer surface of the functionalized Group IVA particle has a SiOₓ content of less than or equal to 1%, as characterized by X-ray photoelectron spectroscopy (XPS) or as assessed by XPS, wherein x is less than or equal to 2.

Silicon, for example, is an oxophilic element, and is almost always found in nature surrounded by four oxygen atoms, either in quartz (crystalline SiO₂) or in numerous silicates and aluminosilicates. A freshly exposed surface of pure silicon can react with oxygen (O₂) or with water (H₂O) in the air within milliseconds. To avoid formation of surface Si—O and Si—O—R bonds, which are electrically insulating and inhibit lithiation by lithium-active alloys in the particle core, preferably the disclosed Group IVA particles are functionalized with a surface-modifying agent under anaerobic conditions, anhydrous conditions, or a combination thereof, so as to be substantially oxide-free at the particle surface. The surface-modifying agent of the functionalized Group IVA particle may be covalently bonded to the surface of the core particle or chemisorbed to the core particle.

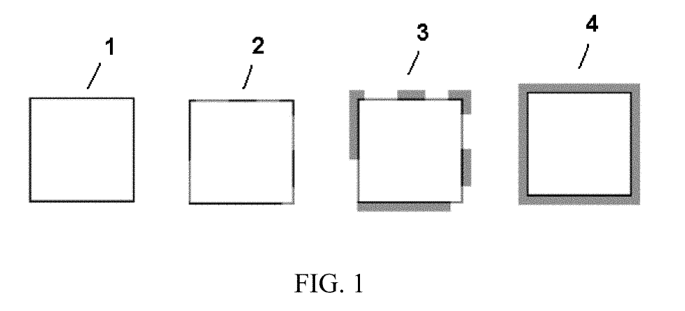

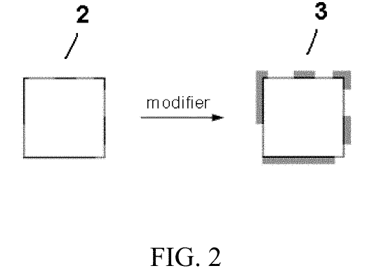

FIG. 1 depicts a simplified representation of functionalized Group IVA particles. The Group IVA particles are shown as squares, which are meant to represent cubic particles, although the particles may have irregular shapes and may have a distribution range of sizes. Particle 1, with a black outline, represents particles passivated with benzene, and can be prepared from wafers ground in the absence of oxygen or trace amounts of adventitious water. Particle 2 represents Group IVA particles that are partially passivated and partially oxidized (the putative oxidized portions of the surface are represented in light blue). The oxidized portion is inactive and may have been present prior to comminution or it may have been formed from the presence of oxygen or water during the comminution to the micron- or submicron-sized Group IVA particles. Particle 3 represents Group IVA particles after they have been surface-modified (e.g., with catechol, 2,3-dihydroxynaphthalene, or 9,10-dibromoanthracene). A modification reaction from particle 2 to particle 3 is shown in FIG. 2 (the modified surfaces of particle 3 are represented with lavender stripes). Particle 4 of FIG. 1 represents a Group IVA particle that is fully surface-modified. The disclosed surface-modified Group IVA particles may be illustrated by particle 4. The disclosed anaerobic milling methods may provide surface-modified Group IVA particles exemplified by particle 4.

The functionalized Group IVA particles may be micron or submicron sized particles. The Group IVA particles may be nano-sized particles. The particles may have a diameter of less than 25 microns, less than 20 microns, less than 15 microns, less 10 microns, less than 5 microns, less than 1 micron, less than 0.5 micron, less than 0.1 micron, or less than 0.05 micron. The particles may have a diameter ranging from about 0.05 micron to about 25 microns, or from about 0.1 micron to about 1 micron. The particles may have a diameter of 0.01 micron, 0.02 micron, 0.03 micron, 0.04 micron, 0.05 micron, 0.06 micron, 0.07 micron, 0.08 micron, 0.09 micron, 0.10 micron, 0.2 micron, 0.3 micron, 0.4 micron, 0.5 micron, 0.6 micron, 0.7 micron, 0.8 micron, 0.9 micron, or 1 micron. The particles may have a diameter ranging from 30 nanometers to 150 nanometers. The particles produced by the processes disclosed herein may be of uniform diameter, or as a distribution of particles of variable diameter. The particles produced by the processes disclosed herein may be substantially oxide-free at the particle surface.

a. Core Materials

The core material of the functionalized Group IVA particles includes at least one Group IVA element (e.g., carbon, silicon, germanium, tin, lead, or a combination thereof), and optionally one or more additional elements. The core material may be crystalline, polycrystalline, or amorphous. The core material may include one or more phases (e.g., crystalline or amorphous; mixed or homogenous; lithium-active or lithium-non-active). The core material may be a mixed-phase material or alloy including at least one Group IVA element. For example, the core material may be a mixed-phase or alloy material that includes at least one Group IVA element, and one or more conductive metals (e.g., aluminum, nickel, iron, copper, molybdenum, zinc, silver, gold, or any combination thereof). The conductive metals may or may not be lithium-active metals. The core material may be a mixed phase or alloy material that includes one or more lithium-active phases (e.g., phases including at least one Group IVA element) and one or more non-lithium-active phases. The mixed phase or alloy core material may be formed from a milling process. In certain embodiments, production of the mixed phase or alloy core material does not depend on use of thermal melt processes (e.g., spin-casting, or co-sputtering).

The core material of the functionalized Group IVA particles may include elemental silicon (Si), germanium (Ge), or tin (Sn), in their elemental form, or available in a wide range of purities. Impurities may be naturally occurring impurities that occur in metallurgical grade (MG) bulk materials, or may be intentionally added dopants to render the semiconducting properties of the Group IVA materials as n-type or p-type. For silicon, the metallurgical grade bulk material may range from amorphous to polycrystalline and crystalline; and purities may range from about 95% pure to 99.9999% pure. Dopants that render Group IVA materials as p-type semiconductors are typically from Group IIIA elements, such as boron (B) or aluminum (Al). Dopants that render Group IVA semiconductors as n-type are typically from Group VA elements, such as nitrogen (N), phosphorous (P) or arsenic (As). Naturally occurring impurities in metallurgical grade Si typically include metallic elements in the form of metal oxides, sulfides and silicides. The major metallic elements include aluminum (Al), calcium (Ca), iron (Fe) and titanium (Ti), but other elements can be observed in trace quantities.

In certain embodiments, the core material of the functionalized Group IVA particles include silicon, germanium, tin, or a combination thereof, with or without other metals or metalloid elements (e.g., aluminum, nickel, iron, copper, molybdenum, zinc, silver, gold, or any combination thereof) in separate or mixed phases. In certain embodiments, the core material of the functionalized Group IVA particles are mixed-phase metal alloys. For example, the core material may be a mixed-phase metal alloy including one or more of silicon, germanium, tin, copper, aluminum, titanium, and copper.

In certain embodiments, the core material of the functionalized Group IVA particles includes a lithium-active element and a non-lithium-active element. Suitable lithium-active elements include, but are not limited to C, Si, Ge, Al, Sn, Ti. Suitable non-lithium-active elements include, but are not limited to, Cu, and Ag.

In certain embodiments, the lithium-active elements in the core material of the functionalized Group IVA particles have formed sublithium phases due to the presence of lithium salts.

For example Si and Li for multiple phases including Li₂Si, Li₂₁Si₈, Li₁₅Si₄ and Li₂₂Si₅.

b. Surface-Modifying Chemical Entities

The Group IVA particles disclosed herein are functionalized with at least one surface-modifying chemical entity. The particles are functionalized over at least a portion of the particle surface. The surface modifier may be physisorbed to the particle, chemisorbed to the particle surface, or a combination thereof. The surface modifier may be covalently bonded to the Group IVA particle. The surface modifier may be a non-dielectric layer of material. The functionalized Group IVA particle may be stable to oxidation in air at room temperature.

The Group IVA particles may be functionalized with a variety of compounds or agents, also referred to as “modifiers” or “modifier reagents” or “surface-modifiers.” Suitable compounds include, but are not limited to, organic compounds (non-polymeric and polymeric), inorganic compounds (non-polymeric and polymeric), nanostructures, biological reagents, or any combination thereof. The chemical entity used for modification of the surface of the Group IVA particles (e.g., silicon nanoparticles) may be any of a group of organic molecular or polymer compounds that are capable of transmitting electrical charge through a conjugated pi-bonded system.

The chemical entity used for modification of the surface of the Group IVA particle (e.g., silicon nanoparticle) may be a symmetric aromatic compound. The symmetric aromatic compound can be used to passivate the Group IVA particle surface toward oxidation, while yielding its position without decomposition to more strongly binding surface modifiers. Exemplary symmetric aromatic surface modifiers include, but are not limited to, benzene, p-xylene, and mesitylene.

The chemical entity used for modification of the surface of the Group IVA particle (e.g., silicon nanoparticle) may be benzene, mesitylene, xylene, unsaturated alkanes, an alcohol, a carboxylic acid, a saccharide, an alkyllithium, a borane, a carborane, an alkene, an alkyne, an aldehyde, a ketone, a carbonic acid, an ester, an amine, an acetamine, an amide, an imide, a pyrrole, a nitrile, an isocyanide, a hydrocarbon substituted with boron, silicon, sulfur, phosphorous, a halogen, or any combination thereof; 2,3-dihydroxyanthracene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, pentacene, fluorine substituted pentacene, trifluromethyl substituted pentacene, pyrene, a polythiophene, poly(3-hexylthiophene-2,5-diyl), poly(3-hexylthiophene), polyvinylidene fluoride (PVDF), a polyacrylonitrile, polyaniline crosslinked with phytic acid, or conducting carbon additives such as single wall carbon nanotubes, multi-walled carbon nanotubes, C₆₀ fullerenes, C₇₀ fullerenes, graphene, carbon black or a combination thereof. It is understood that any combination of the foregoing may be used. [including fluorinated or trifluoromethylated substituted analogs of above.]

The chemical entity used for modification of the surface of the Group IVA particle may be an organic compound, such as a hydrocarbon based organic compound. In certain embodiments, the compound may be selected from the group consisting of alkenes, alkynes, aromatics, heteroaromatics, cycloalkenes, alcohols, glycols, thiols, disulfides, amines, amides, pyridines, pyrrols, furans, thiophenes, cyanates, isocyanates, isothiocyanates, ketones, carboxylic acids, amino acids, aldehydes, and any combination thereof. In certain embodiments, the compound may be selected from the group consisting of toluene, benzene, a polycyclic aromatic, a fullerene, a metallofullerene, a styrene, a cyclooctatetraene, a norbornadiene, a primary C₂-C₁₈ alkene, a primary C₂-C₁₈ alkyne, a saturated or unsaturated fatty acid, a peptide, a protein, an enzyme, 2,3,6,7-tetrahydroxyanthracene, catechol, 2,3-hydroxynaphthalene, 9,10-dibromoanthracene, and any combination thereof.

The chemical entity used for modification of the surface of the Group IVA particle can be a fullerene (e.g., C₆₀, C₇₀, and other fullerene derivatives including fullerene (F)ₙ, fullerene (CF₃)ₙ), a polyaromatic hydrocarbon (PAH), polycyclic aromatic hydrocarbon (CF₃)ₙ, polycyclic aromatic hydrocarbon (Fₙ), carbon black, nanospherical carbon, graphene, single-wall carbon nanotubes, multi-wall carbon nanotubes, graphene and substituted analogs thereof, a metal-organic framework, or a covalent-organic framework.

Hydrocarbons chosen for passivation may bear other functional groups that upon activation will form covalent bonds with other reagents. This property provides a basis for covalently linking the Group IVA particles as structural units in building reticular covalent networks. Hydrocarbons chosen for passivation can vary in size and polarity. Both size and polarity can be exploited for targeted particle size selectivity by solubility limits in particular solvents. Partitioning of particle size distributions based on solubility limits is one tactic for narrowing of particle size distributions in commercial scale processes.

While the possibilities of structure and function for functionalized Group IVA submicron particles made by the methods disclosed herein are unlimited, the following embodiments are given as examples to demonstrate the range of flexibility for building functional particles through low energy reactions conducted at or near room temperature, and preferably under anaerobic conditions.

In certain embodiments, the Group IVA particle may be passivated with toluene.

In certain embodiments, the Group IVA particle may be passivated with benzene, p-xylene, mesitylene, or a combination thereof. A benzene, p-xylene, or mesitylene passivated Group IVA particle may serve as a stable intermediate for further modification. Such surface-modifiers can bond reversibly to silicon surfaces. Thus, a benzene, p-xylene, or mesitylene passivated Group IVA material is a convenient stable intermediate for introducing other functional hydrocarbons to the particle surface.

In certain embodiments, the Group IVA particle may be passivated with an aromatic hydrocarbon, such as a polycyclic aromatic hydrocarbon (PAH). Aromatic hydrocarbons provide for charge mobility across the passivated particle surface. Hydrocarbons with extended pi systems through which charge can travel may be preferred in certain embodiments for non-dielectric passivation of Group IVA material surfaces. Suitable polycyclic aromatic hydrocarbons include, but are not limited to, naphthalene, anthracene, tetracene, pentacene, pyrene, perylene, phenanthrene, triphenylenes, and substituted analogs thereof.

In certain embodiments, the Group IVA particle may be passivated with a carbon nanostructure. Such materials may be applied to the particle surfaces either directly to hydrogen passivated surfaces, or by replacement of benzene passivated surfaces. Suitable carbon nanostructures include, but are not limited to, single-wall carbon nanotubes (SWCNT), multi-wall carbon nanotubes (MWCNT), fullerenes, metallofullerenes, graphene, and substituted analogs thereof. Fullerenes have a very high capacity to disperse electric charge and may impart properties useful in microelectronic applications.

In certain embodiments, the Group IVA particle may be passivated with a surface-modifying chemical entity that bears one or more functional groups. Suitable functional groups include, but are not limited to, alkenes, alkynes, alcohols, aldehydes, ketones, carboxylic acids, carbonic acids, esters, amines, acetamines, amides, imides, pyrrols, cyanides, isocyanides, cyano, isocyano, boron, silicon, sulfur, phosphorous, and halogens. In certain embodiments, the surface modifier is a hydrocarbon including one or more functional groups (e.g., boron, silicon, sulfur, phosphorous, or halogen). The functional groups may form a bond to the core particle elements.

In certain embodiments, the Group IVA particle may be passivated with styrene. Such materials may be applied directly to hydrogen or benzene passivated surfaces. Styrene is known to bond primarily through the pendant vinyl group, leaving the aromatic ring unchanged and free to interact with surrounding solvents, electrolytes, or to be modified by aromatic ring substitution reactions. Functional groups on the phenyl ring may be used as a reactive precursor for forming covalent bonds to a surrounding framework.

In certain embodiments, the Group IVA particle may be passivated with cyclooctatetraene (COT). Such a material may be applied to hydrogen, benzene, p-xylene, or mesitylene passivated surfaces, with alternating carbon atoms formally bonded to the particle surface while the other four carbon atoms not bonded directly to the particle surface are connected by two parallel double bonds, providing a diene site capable of Diels-Alder type reactions.

In certain embodiments, the Group IVA particle may be passivated with a norbornadiene reagent. Such materials may be applied passivated surfaces with attachment of one or both double bonds. If both double bonds interact with the particle surface, a strained structure comparable to quadracyclane may result. Norbornadiene/quadracyclane is known to be an energy storage couple that needs a sensitizer (acetophenone) to capture photons. In certain embodiments, silicon or germanium may also function as a sensitizer.

In certain embodiments, the Group IVA particle may be passivated with a normal primary alkene or alkyne having 6-12 carbon chain lengths. The alkene or alkyne can be used as the reactive medium for the purpose of attaching hydrocarbons to the surface of the Group IVA particles to increase particle size or to change solubility properties of the particles. The longer alkane chain lengths may garner more intermolecular attraction to solvents, resulting in increased solubility of the particles. Changing the size of Group IVA particles by attaching hydrocarbons may alter photoluminescence properties.

In certain embodiments, the Group IVA particle may be passivated with a biologically active reactive media. Such materials can be used to replace hydrogen passivated surfaces to synthesize biological markers that respond to photons. Fatty acids may bond to active surfaces through the carboxylate group or through one of the chain's unsaturated bonds. Amino acids are water soluble and may bond either though the primary amine or through the acid end, depending on pH. Similarly, peptides, proteins, enzymes all have particular biological functions that may be linked to Group IVA nanoparticle markers.

In certain embodiments, passivated Group IVA nanoparticles may reside in communication with a porous framework capable of transmitting charge in communication with liquid crystal media having charge conduction properties. Such particles may be used for the purpose of capturing and selectively sequestering chemical components of a complex mixture, as a method of measuring their relative concentrations in the mixture. The method of measurement may be by capture of photons by the semiconductor nanoparticles and measurement of electrical impulses generated from photovoltaic properties of said nanoparticles or by sensing photoluminescence as a result of reemitted photons from the media that has been influenced by the captured chemical components.

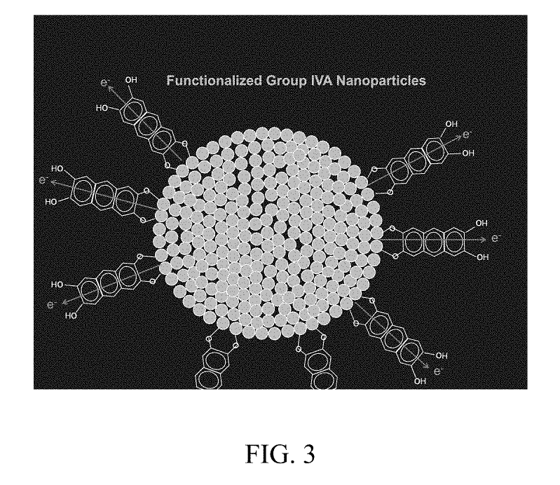

In certain embodiments, bifunctional organic chains may be used to replace hydrogen, benzene, p-xylene, or mesitylene passivated surfaces. For example, 2,3,6,7-tetrahydroxy-anthracene has two hydroxyl groups at each end of a fused chain of three aromatic rings. This hydrocarbon chain may be used to build a covalent framework and may be used to link Group IVA nanoparticles to the framework. The chain length structure and functional groups at the ends of the chains can vary. Some functional groups used for cross-linking between building units can include, but are not limited to: aldehydes, carboxylates, esters, borates, amines, amides, vinyl, halides, and any other cross-linking functional group used in polymer chemistry. Frameworks based on covalently linked porphyrin may have extraordinarily high charge (hole conducting) mobility, greater than amorphous silicon and higher than any other known hydrocarbon composite. Si nanoparticles linked covalently to porous covalent frameworks may serve as high capacity electrode composites for lithium-ion batteries. FIG. 3 depicts Group IVA nanoparticles functionalized with 2,3,6,7-tetrahydroxy-anthracene groups.

In certain embodiments, aromatic passivating hydrocarbons may be used to replace hydrogen bonded to reactive surfaces of the Group IVA particles. The aromatic hydrocarbons may promote high charge mobility and can interact with other planar pi systems in the media surrounding the particle. This embodiment may be applied to functioning solar photovoltaic (PV) cells. The aromatic hydrocarbons that form the passivating layer on the particle may or may not possess functional groups that form covalent bonds to the particle or the surrounding media. For example, toluene bonds to active surfaces on silicon, effectively passivating the surface and permitting electrical charge to move from photon generated electron hole pairs in p-type crystalline silicon particles. Sustained electrical diode properties have been measured in films made with high K-dielectric solvents and both p-type and n-type silicon particles passivated with toluene.

In certain embodiments, the Group IVA particle may be passivated with benzene, toluene, xylenes (e.g., p-xylene), mesitylene, catechol, 2,3-dihydroxynaphthalene, 2,3-dihydroxyanthracene, 2,3,6,7-tetrahydroxyanthracene, 9,10-dibromoanthracene, or a combination thereof. It is to be understood that the term “passivated,” as used herein, refers to Group IVA particles that may be partially or fully passivated. For example, in certain embodiments, the Group IVA particle may be partially passivated (e.g., with benzene, toluene, xylenes (e.g., p-xylene), mesitylene, catechol, 2,3-dihydroxynaphthalene, 2,3-dihydroxyanthracene, 2,3,6,7-tetrahydroxyanthracene, 9,10-dibromoanthracene, or a combination thereof). In certain embodiments, the Group IVA particle may be fully passivated (e.g., with benzene, toluene, xylenes (e.g., p-xylene), mesitylene, catechol, 2,3-dihydroxynaphthalene, 2,3-dihydroxyanthracene, 2,3,6,7-tetrahydroxyanthracene, 9,10-dibromoanthracene, or a combination thereof).

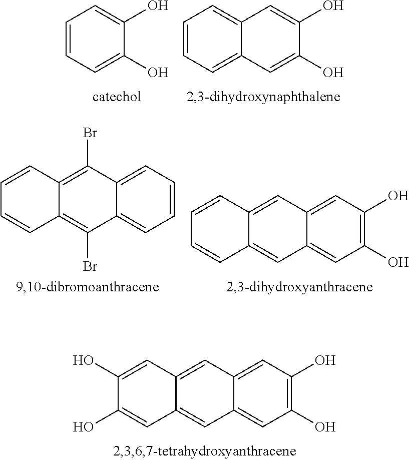

c. Characterization of Functionalized Group IVA Particles

The functionalized Group IVA particles may be characterized by a variety of methods. For example, characterization of the passivated particles may be accomplished with scanning electron microscopy (SEM), thermogravimetric analysis-mass spectrometry (TGA-MS), molecular fluorescence spectroscopy, x-ray photoelectron spectroscopy (XPS) and/or cross-polarization magic angle spinning nuclear magnetic resonance (CP-MAS NMR).

SEM images may be used to measure individual particles and to gain more assurance that particle size measurements truly represent individual particles rather than clusters of crystallites. While SEM instruments also have the capability to perform Energy Dispersive X-ray Spectrometry (EDS), it is also possible with sufficiently small particle sizes that an elemental composition will confirm the presence of carbon and the absence of oxides through observance and absence respectively of their characteristic K-alpha signals. Iron and other metal impurities may be observed and do not interfere with the observance of lighter elements.

Another analytical method that can be used to demonstrate the presence of and identify the composition of monolayers on nanoparticles is the combined method of thermogravimetric analysis and mass spectrometry (TGA-MS). With sufficient surface area, the fraction of surface molecules to the mass of the particles may be sufficiently high enough that mass of the monolayer can be detected gravimetrically as it desorbs or disbonds from the particle surfaces when a sample is heated. Excess solvent evolved as the mass is heated will appear near the normal boiling point of that solvent, while solvent molecules that belong to the bonded monolayer will be released at a significantly higher temperature. If the release of the monolayer comprises too small of a fraction of the total mass weight to be seen on a percentage scale of total mass lost, it may still be detected by a mass-spectrometer used to monitor off gases during a TGA experiment. Monitoring the total ion current derived from the major mass fragments of the surface molecules' parent ion is a very sensitive tool to verify composition and the precise temperature at which these molecules are released.

Still another very sensitive test to detect the presence of surface-bound unsaturated or aromatic hydrocarbons is by its fluorescence spectrum. While the measurement of a fluorescence spectrum can be accomplished by more than one method, a reflectance spectrum from a slurry or suspension of Group IVA particles in a non-fluorescing solvent flowing in a HPLC stream through a fluorescence detector can be employed with nanoparticles. By measuring shifts in the irradiation maxima and the resulting fluorescence spectra of the bound monolayer compared with that of the free solvent, the perturbation due to the surface bonding interactions can be assessed.

For nanoparticles less than about 50 nm, the use of nuclear magnetic resonance (NMR) becomes a feasible method to measure the effects of bonding of the surface molecules by observing the resonance of singlet state isotopes that have strong gyromagnetic ratios. Carbon 13, hydrogen, and silicon 29 are all candidates that exhibit reasonable sensitivity toward NMR. Because these nanoparticles may be insoluble in all solvents, a preferred technique to acquire NMR spectra in the solid state is by the method of cross-polarization-magic angle spinning (CP-MAS) NMR spectrometry. Significant resonance shifts would be expected from bonding interactions with surface molecules compared to the unperturbed or natural resonance positions. These resonance shifts may indicate the predominant mode of bonding between specific atoms of the surface molecules and the surface Group IVA atoms. The presence of any paramagnetic or ferromagnetic impurities in the Group IVA material may interfere with and prevent the acquisition of NMR spectra. Thus, preferably only highly pure, iron-free Group IVA particles of less than 50 nm diameter are candidates for NMR analysis.

### 3. Composites and Compositions

In another aspect, disclosed are composites and compositions including functionalized Group IVA particles. The functionalized Group IVA particles may promote interparticle electron mobility within the composite material. The composites optionally include one or more additional components (e.g., electrically conductive agents, polymer binding agents, and lithium salts or reagents). The surface-modified Group IVA particles may be combined with one or more additional components to provide a composition suitable for a particular application. For example, the surface-modified Group IVA particles may be combined with a conductive adhesion additive, a dopant additive, other additional components, or a combination thereof. The components in the composites may be combined with the disclosed Group IVA particles before the milling process to provide surface-modified Group IVA particles, during the milling process to provide surface-modified Group IVA particles, after the milling process to provide surface-modified Group IVA particles, or any combination thereof.

The functionalized Group IVA particles may be provided in compositions (e.g., inks, pastes, and the like) or composites. The compositions or composites may include the functionalized Group IVA particles, and optionally one or more additive components. In certain embodiments, a composition or composite includes functionalized Group IVA particles and a conductive cohesion additive. In certain embodiments, a composition or composite includes functionalized Group IVA particles and a dopant additive. In certain embodiments, a composition or composite includes functionalized Group IVA particles and a solvent. In certain embodiments, a composition or composite includes functionalized Group IVA particles, a conductive cohesion additive, and a dopant additive. In certain embodiments, a composition or composite includes functionalized Group IVA particles, a conductive cohesion additive, and a solvent. In certain embodiments, a composition or composite includes functionalized Group IVA particles, a dopant additive, and a solvent. In certain embodiments, a composition or composite includes functionalized Group IVA particles, a conductive cohesion additive, a dopant additive, and a solvent.

The functionalized Group IVA particles may be present in a composite in an amount ranging from 50 wt % to 100 wt %, 60 wt % to 100 wt %, or 75 wt % to 100 wt %. In certain embodiments, the functionalized Group IVA particles may be present in a composite in an amount of about 50 wt %, about 60 wt %, about 65 wt %, about 70 wt %, about 75 wt %, about 80 wt %, about 85 wt %, about 90 wt %, about 95 wt %, or about 100 wt %. In certain embodiments, the functionalized Group IVA particles may be present in a composite in an amount of 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, 95 wt %, 96 wt %, 97 wt %, 98 wt %, 99 wt %, or 100 wt %.

Suitable conductive cohesion additives (also referred to as conductive carbon additives) include, but are not limited to, single wall carbon nanotubes, multi-walled carbon nanotubes, C₆₀ fullerenes, C₇₀ fullerenes, other fullerene derivatives, graphene, and carbon black. These conductive cohesion additives may have powerful field effects and promote charge mobility across particle surfaces; promote film adhesion and cohesion to substrates by prompting inter-particle attraction, which leads to composite cohesion and film stability; promote high adhesion of an electrode film to the substrate surface; promote better lithium ion mobility and more complete lithiation of the Group IVA nanoparticles while supporting facile electron mobility between particles; and support lithium migration through a film composite and lithiation of nanoparticles further from the current-collector substrate.

The conductive cohesion additive may be present in a composite in an amount ranging from 0 wt % to 1 wt %, 0 wt % to 2 wt %, 0 wt % to 3 wt %, 0 wt % to 4 wt %, 0 wt % to 5 wt %, 0 wt % to 10 wt %, 0 wt % to 15 wt %, 0 wt % to 20 wt %, 0 wt % to 30 wt %, 0 wt % to 40 wt %, or 0 wt % to 50 wt %. In certain embodiments, the conductive cohesion additive may be present in a composite in an amount of about 0 wt %, about 5 wt %, about 10 wt %, about 15 wt %, about 20 wt %, about 25 wt %, about 30 wt %, about 35 wt %, about 40 wt %, about 45 wt %, or about 50 wt %. In certain embodiments, the conductive cohesion additive may be present in a composite in an amount of 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, or 50 wt %.

Suitable dopant additives include, but are not limited to, fullerene (F)ₙ, fullerene (CF₃)ₙ, polycyclic aromatic hydrocarbon (CF₃)ₙ, and polycyclic aromatic hydrocarbon (Fₙ). In certain embodiments, the dopant additive may be C₆₀F₄₈. The dopant additive may be present in a composite in an amount ranging from 0 wt % to 1 wt %, 0 wt % to 2 wt %, 0 wt % to 3 wt %, 0 wt % to 4 wt %, 0 wt % to 5 wt %, or 0 wt % to 10 wt %. In certain embodiments, the dopant additive may be present in a composite in an amount of about 0 wt %, about 1 wt %, about 2 wt %, about 3 wt %, about 4 wt %, about 5 wt %, about 6 wt %, about 7 wt %, about 8 wt %, about 9 wt %, or about 10 wt %. In certain embodiments, the dopant additive may be present in a composite in an amount of 0.1 wt %, 0.2 wt %, 0.3 wt %, 0.4 wt %, 0.5 wt %, 0.6 wt %, 0.7 wt %, 0.8 wt %, 0.9 wt %, 1.0 wt %, 1.1 wt %, 1.2 wt %, 1.3 wt %, 1.4 wt %, 1.5 wt %, 1.6 wt %, 1.7 wt %, 1.8 wt %, 1.9 wt %, 2.0 wt %, 2.1 wt %, 2.2 wt %, 2.3 wt %, 2.4 wt %, 2.5 wt %, 2.6 wt %, 2.7 wt %, 2.8 wt %, 2.9 wt %, 3.0 wt %, 3.1 wt %, 3.2 wt %, 3.3 wt %, 3.4 wt %, 3.5 wt %, 3.6 wt %, 3.7 wt %, 3.8 wt %, 3.9 wt %, 4.0 wt %, 4.1 wt %, 4.2 wt %, 4.3 wt %, 4.4 wt %, 4.5 wt %, 4.6 wt %, 4.7 wt %, 4.8 wt %, 4.9 wt %, 5.0 wt %, 5.1 wt %, 5.2 wt %, 5.3 wt %, 5.4 wt %, 5.5 wt %, 5.6 wt %, 5.7 wt %, 5.8 wt %, 5.9 wt %, 6.0 wt %, 6.1 wt %, 6.2 wt %, 6.3 wt %, 6.4 wt %, 6.5 wt %, 6.6 wt %, 6.7 wt %, 6.8 wt %, 6.9 wt %, 7.0 wt %, 7.1 wt %, 7.2 wt %, 7.3 wt %, 7.4 wt %, 7.5 wt %, 7.6 wt %, 7.7 wt %, 7.8 wt %, 7.9 wt %, 8.0 wt %, 8.1 wt %, 8.2 wt %, 8.3 wt %, 8.4 wt %, 8.5 wt %, 8.6 wt %, 8.7 wt %, 8.8 wt %, 8.9 wt %, 9.0 wt %, 9.1 wt %, 9.2 wt %, 9.3 wt %, 9.4 wt %, 9.5 wt %, 9.6 wt %, 9.7 wt %, 9.8 wt %, 9.9 wt %, or 10.0 wt %.

Suitable solvents include, but are not limited to, dichloromethane (also referred to as methylene chloride); 1,2-dichloroethane; 1,1-dichloroethane; 1,1,1-trichloropropane; 1,1,2-trichloropropane; 1,1,3-trichloropropane; 1,2,2-trichloropropane; 1,2,3-trichloropropane; 1,2-dichlorobenzene (also referred to as ortho-dichlorobenzene); 1,3-dichlorobenzene (also referred to as meta-dichlorobenzene); 1,4-dichlorobenzene (also referred to as para-dichlorobenzene); 1,2,3-trichlorobenzene; 1,3,5-trichlorobenzene; α,α,α-trichlorotoluene; and 2,4,5-trichlorotoluene. Suitable solvents may also include N-methyl pyrrolidinone (NMP), dimethylsulfoxide (DMSO), tetrahydrofuran (THF), nitromethane, hexamethylphosphoramide (HMPA), dimethylforamide (DMF), and sulfalone. The solvent may be present in a composite in an amount ranging from 0 wt % to 0.05 wt %, 0 wt % to 0.1 wt %, 0 wt % to 0.5 wt %, 0 wt % to 1 wt %, 0 wt % to 2 wt %, or 0 wt % to 3 wt %. The solvent may be present in a composite in an amount of 3 wt % or less, 2 wt % or less, 1 wt % or less, 0.5 wt % or less, 0.1 wt % or less, 0.01 wt % or less, or 0.001 wt % or less.

The solids loading (e.g., functionalized Group IVA particles, and optional additives) in an ink (e.g., for ink jet printing) may range from 1 wt % to 60 wt %, or 10 wt % to 50 wt %. In certain embodiments, the solids loading in an ink may be about 1 wt %, about 5 wt %, about 10 wt %, about 15 wt %, about 20 wt %, about 25 wt %, about 30 wt %, about 35 wt %, about 40 wt %, about 45 wt %, or about 50 wt %. In certain embodiments, the solids loading in an ink may be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, or 50 wt %. The balance of weight may be attributed to one or more solvents of the ink.

The solids loading (e.g., functionalized Group IVA particles, and optional additives) in a composition (e.g., for spreading or paintbrush application) may range from 1 wt % to 60 wt %, 10 wt % to 50 wt %, or 25 wt % to 40 wt %. In certain embodiments, the solids loading in a composition may be about 1 wt %, about 5 wt %, about 10 wt %, about 15 wt %, about 20 wt %, about 25 wt %, about 30 wt %, about 35 wt %, about 40 wt %, about 45 wt %, about 50 wt %, about 55 wt %, about 60 wt %, or about 65 wt %. In certain embodiments, the solids loading in a composition may be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, or 65 wt %. The balance of weight may be attributed to one or more solvents of the composition.

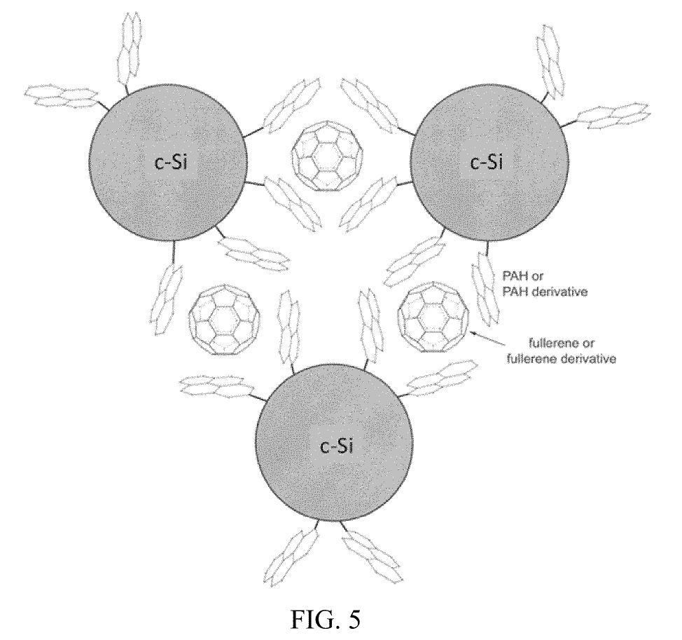

FIG. 5 shows one exemplary composite for c-Si conductive films. The composite includes a plurality of silicon particles functionalized with polycyclic aromatic hydrocarbon (PAH) compounds, which are covalently bound to the silicon particles. The composite further comprises fullerene or fullerene derivatives, which may serve as electron acceptor additives.

### 4. Methods of Preparing Functionalized Group IVA Particles

In another aspect, disclosed are methods of preparing functionalized Group IVA particles. The methods include reducing a Group IVA material to Group IVA particles in the presence of at least one surface-modifying agent to provide surface-modified Group IVA particles (e.g., surface-modified Group IVA nanoparticles). The Group IVA material can be reduced to Group IVA particles (e.g., Group IVA nanoparticles) over one or more steps (e.g., by grinding, grading, or milling), wherein at least one step includes functionalization of the Group IVA particles with a surface-modifying agent. One or more steps of production of surface-modified Group IVA particles (e.g., reduction of micrometer-sized particles to nanometer-sized particles) can be conducted under anaerobic conditions, anhydrous conditions, or a combination thereof.

In certain embodiments, the disclosed methods of preparing functionalized Group IVA particles include milling, preferably anaerobically milling, micrometer-sized Group IVA particles in the presence of one or more surface-modifying chemical entities to provide nanometer-sized, functionalized Group IVA particles. The one or more surface-modifying chemical entities may passivate highly reactive Group IVA particles surfaces (e.g., silicon surfaces) and metallic surfaces. The passivation may prevent or reduce oxidation of the Group IVA particle or metallic surfaces.

The milling can be performed in the presence of one or more solvents. The solvents may be surface-modifying agents, non-competing solvents, or a combination thereof. The milling can be performed under anaerobic conditions in one or more solvents, preferably deoxygenated and anhydrous solvents (e.g., solvents can be distilled under inert atmosphere). The solvents can be deoxygenated and rendered anhydrous by distillation under an inert atmosphere or by filtration through alumina and sparging with inert gas. For example, mesitylene may be dehydrated and free of oxygen (to <1 ppm of both O₂ and H₂O) by distilling over sodium metal under nitrogen or argon atmosphere. The absence of H₂O and O₂ can be indicated by adding benzophenone for example to the solvent still, upon which a blue or purple tone to the undistilled solvent will indicate the presence of benzophenone anions, which can only exist in the absence of oxygen and moisture.

In certain embodiments, the disclosed methods of preparing functionalized Group IVA particles include milling, preferably anaerobically milling, micrometer-sized Group IVA particles in the presence of one or more alkane solvents (e.g., heptane, hexane) to provide nanometer-sized Group IVA particles with reactive surfaces. The anaerobic milling process employing alkane solvents can include addition of one or more surface-modifying chemical entities before the milling process, during the milling process, after the milling process, or a combination thereof. The anaerobic milling process employing alkane solvents can include addition of one or more additives (e.g., polymer binders, electrically conductive carbon materials, metal-organic frameworks (MOF), and covalent-organic frameworks (COF)) before the milling process, during the milling process, after the milling process, or a combination thereof.

In certain embodiments, the milling process includes addition of a polymer binder (e.g., as the surface-modifying chemical entity and/or a binder). For example, polyvinylidene fluoride (PVDF) can be employed in the milling process (e.g., which can act as a surface modifier and/or a binder). Consequently, the disclosed processes can provide surface-modified Group IVA particles (e.g., modified silicon particles) that can be used in combination with PVDF, as well as other materials (e.g., graphite) to provide a composite containing the modified Group IVA particles, PVDF, and optionally additional materials (e.g., graphite).

In certain embodiments, the anaerobic milling process employing alkane solvents comprises anaerobic milling of Group IVA-containing materials in the presence of one or more alkane solvents; recovering a slurry or dispersion of milled material after milling; adding one or more surface-modifying chemical entities and optionally one or more additives to the dispersion or slurry to affect surface modification of the nano-sized Group IVA particles; and removing the alkane solvent to provide a material comprising functionalized Group IVA particles (e.g., a powder of functionalized nanoparticles).

In certain embodiments, the anaerobic milling process employing alkane solvents comprises anaerobic milling of Group IVA-containing materials in the presence of one or more alkane solvents; recovering a slurry or dispersion of milled material after milling; diluting the slurry with one or more alkane solvents, preferably the same alkane solvent used for milling; adding one or more surface-modifying chemical entities and optionally one or more additives to the diluted dispersion or slurry to affect surface modification of the nano-sized Group IVA particles; and removing the alkane solvent to provide a material comprising functionalized Group IVA particles (e.g., a powder of functionalized nanoparticles).

In certain embodiments, the anaerobic milling process employing alkane solvents comprises anaerobic milling of Group IVA-containing materials in the presence of one or more alkane solvents, one or more surface-modifying chemical entities, and optionally one or more additives; recovering a slurry or dispersion of milled material after milling; and removing the alkane solvent to provide a material comprising functionalized Group IVA particles (e.g., a powder of functionalized nanoparticles). In certain embodiments, the anaerobic milling process employing alkane solvents comprises anaerobic milling of Group IVA-containing materials in the presence of one or more alkane solvents, optionally one or more surface-modifying chemical entities, and optionally one or more additives; recovering a slurry or dispersion of milled material after milling; diluting the slurry or dispersion with one or more alkane solvents, preferably the same alkane solvent used for milling; optionally treating the diluted slurry or dispersion with one or more surface-modifying chemical entities, one or more additives, or combination thereof; and removing the alkane solvent to provide a material comprising functionalized Group IVA particles (e.g., a powder of functionalized nanoparticles). In certain embodiments, the methods include treatment of the Group IVA material with a lithium reagent during milling, after milling, or a combination thereof.

In certain embodiments, the slurry containing the surface modified nanoparticle may be maintained as a slurry without removing solvent. The slurry may be advantageous for the storing of the surface modified nanoparticle. The slurry may optionally be used directly for fabrication of composites or electrode films. For example, the slurry may be combined with one or more additional additives (e.g., graphite, binders, carbon black) and optionally one or more additional solvents (to support continuous or microemulsion fluidic phases), and used to manufacture a composite or electrode film.

The milling may provide the Group IVA particles with a core material that is crystalline, polycrystalline, amorphous, or a combination thereof. The core material may include one or more phases (e.g., crystalline or amorphous; mixed or homogenous; lithium-active or lithium-non-active). The core material may be a mixed-phase material or alloy including at least one Group IVA element. For example, the core material may be a mixed-phase or alloy material that includes at least one Group IVA element, and one or more conductive metals (e.g., aluminum, nickel, iron, copper, molybdenum, zinc, silver, gold, or any combination thereof). The conductive metals may or may not be lithium-active metals. The core material may be a mixed phase or alloy material that includes one or more lithium-active phases (e.g., phases including at least one Group IVA element) and one or more non-lithium-active phases.

In one exemplary embodiment, milling can be formed in the presence of a combination of Group IVA elements (e.g., Si, Sn, or Ge), one or more surface-modifying agents, one or more solvents, one or more conductive metals, one or more dopant elements (e.g., p-type or n-type), one or more polymer binders, or any combination thereof. The milling process can affect formation of the mixed-phase or alloy materials (e.g., by controlling tip velocity, bead size, mill time, or a combination thereof). The formation of such core materials may occur without use of a thermal process (e.g., co-sputtering, melt spin-casting, etc.).

The disclosed methods of preparing Group IVA particles may be conducted at or near room temperature. The methods may be conducted with no prior melting or annealing steps. The methods may be conducted without co-sputtering elements directly on a current collector substrate. The methods may be conducted without heating silicon, for example, with various metals to make melts followed by, for example, rapid cooling by a melt spin-casting technique to make ribbons that could be further comminuted into small particles (e.g., by cryogenic ball milling at temperatures between 0 to −30° C.). The methods allow functionalization of Group IVA materials for any application on any substrate/carrier that would otherwise require heat, sintering, environmentally controlled clean rooms and environmentally unfriendly etching, and substrates that would stand up to the heat processing, etc.

The disclosed methods of preparing functionalized Group IVA particles may include one or more steps selected from (a) providing Group IVA particles (e.g., micrometer sized Group IVA particles); (b) etching Group IVA particles (e.g., etching micron-sized Group IVA particles by one or more acid treatments); (c) milling, preferably anaerobically milling, Group IVA particles in the presence of one or more surface-modifying chemical entities and optionally in the presence of one or more solvents; and (d) conducting solvent removal and mild heat treatment of the milled material. One or more steps of the disclosed methods may be conducted under anaerobic conditions, anhydrous conditions, or a combination thereof.

The disclosed methods of preparing functionalized Group IVA particles may include one or more steps selected from (a) providing Group IVA particles (e.g., micrometer sized Group IVA particles); (b) etching Group IVA particles (e.g., etching micron-sized Group IVA particles by one or more acid treatments); (c) milling, preferably anaerobically milling, Group IVA particles in the presence of one or more one or more alkane solvents (e.g., heptane); (d) treating the resulting milled slurry with one or more surface-modifying chemical entities and optionally one or more additives; and (e) conducting solvent removal and mild heat treatment of the milled material. One or more steps of the disclosed methods may be conducted under anaerobic conditions, anhydrous conditions, or a combination thereof.

The disclosed methods of preparing functionalized Group IVA particles may include one or more steps selected from (a) providing Group IVA particles (e.g., micrometer sized Group IVA particles); (b) etching Group IVA particles (e.g., etching micron-sized Group IVA particles by one or more acid treatments); (c) milling, preferably anaerobically milling, Group IVA particles in the presence of one or more one or more alkane solvents (e.g., heptane); (d) diluting the resulting milled slurry with one or more alkane solvents; (e) treating the diluted slurry with one or more surface-modifying chemical entities and optionally one or more additives; and (0 conducting solvent removal and mild heat treatment of the milled material. One or more steps of the disclosed methods may be conducted under anaerobic conditions, anhydrous conditions, or a combination thereof.

The disclosed methods of preparing functionalized Group IVA particles may include one or more steps selected from (a) providing Group IVA particles (e.g., micrometer sized Group IVA particles); (b) etching Group IVA particles (e.g., etching micron-sized Group IVA particles by one or more acid treatments); (c) milling, preferably anaerobically milling, Group IVA particles in the presence of one or more one or more alkane solvents (e.g., heptane) and one or more surface-modifying chemical entities and optionally one or more additives; (d) optionally treating the resulting milled slurry with one or more surface-modifying chemical entities, one or more additives, or a combination thereof; and (e) conducting solvent removal and mild heat treatment of the milled material. One or more steps of the disclosed methods may be conducted under anaerobic conditions, anhydrous conditions, or a combination thereof.

The disclosed methods of preparing functionalized Group IVA particles may include one or more steps selected from (a) providing Group IVA particles (e.g., micrometer sized Group IVA particles); (b) etching Group IVA particles (e.g., etching micron-sized Group IVA particles by one or more acid treatments); (c) milling, preferably anaerobically milling, Group IVA particles in the presence of one or more one or more alkane solvents (e.g., heptane) and one or more surface-modifying chemical entities and optionally one or more additives; (d) diluting the resulting milled slurry with one or more alkane solvents; (e) optionally treating the diluted slurry with one or more surface-modifying chemical entities, one or more additives, or a combination thereof, and (0 conducting solvent removal and mild heat treatment of the milled material. One or more steps of the disclosed methods may be conducted under anaerobic conditions, anhydrous conditions, or a combination thereof.

In certain embodiments, a method of preparing functionalized Group IVA particles includes anaerobically milling Group IVA particles in the presence of one or more surface-modifying chemical entities and optionally in the presence of one or more solvents (e.g., surface-modifying solvents or non-competing solvents). In certain embodiments, a method of preparing functionalized Group IVA particles includes anaerobically milling Group IVA particles in the presence of one or more alkane solvents (e.g., heptane), and concurrently, subsequently, or a combination thereof, treating the slurry of milled material, a dilution of the slurred material, or a combination thereof, with one or more surface-modifying chemical entities, one or more additives, or a combination thereof.

a. Providing Group IVA Particles

A source of Group IVA material can be ground and recovered to produce Group IVA particles (e.g., micrometer-sized Group IVA particles, such as in the form of a powder). For example, a source of crystalline, polycrystalline, or amorphous silicon can be ground to produce micrometer sized particles. The source of Group IVA material can be ground to micrometer-sized materials by known grinding and grading methods. For example, a powder of micron-sized Group IVA particles may be produced by using a mortar and pestle to crush a material comprising Group IVA elements (e.g., silicon wafers), and passing the crushed material through a sieve.

The micrometer-sized Group IVA particles may be derived from a variety of feedstocks. In certain embodiments, the Group IVA particles may be derived from wafers, such as silicon wafers. Of the refined crystalline and polycrystalline bulk materials, wafers from ingots with specific resistivity are available from semiconductor microelectronics manufacturing and solar photovoltaic cell manufacturing. Kerf from wafer manufacturing and scrap, or defective wafers are also available at recycled material prices. In certain embodiments, the micrometer-sized Group IVA particles are derived from P-doped silicon wafers, B-doped silicon wafers, or a combination thereof.

Group IVA particles (e.g., micron sized particles) may be prepared from feedstocks by any suitable process. In certain embodiments, the Group IVA particles may be prepared from bulk Group IVA materials by comminution processes known in the art. Particle size ranges obtainable from comminution of bulk Group IVA materials has improved with the development of new milling technologies in recent years. Using milling techniques such as high energy ball milling (HEBM), fluidized bed bead mills, and steam jet milling, nanoparticle size ranges may be obtained. Bulk materials are available commercially in a wide range of specifications with narrow ranges of measured electrical resistivity and known dopant concentrations, and can be selected for milling. Other embodiments can be created to produce micron- to nano-sized particles using n-type Group IVA wafers, or wafers with higher or lower resistivity or bulk MG Group IVA ingot material.

b. Etching/Leaching

Group IVA-particles (e.g., micrometer-sized Group IVA particles) can be etched or leached to remove nascent oxides and provide reactive surfaces for functionalization with a surface-modifying chemical entity.

Any protic acid may be used to provide the hydrogen passivated Group IVA particles. In certain embodiments, the protic acid is a strong protic acid. In certain embodiments, the protic acid is selected from the group consisting of nitric acid (HNO₃), hydrochloric acid (HCl), hydrofluoric acid (HF), hydrobromic acid (HBr), or any combination thereof. The protic acid may function to passivate the first Group IVA particle by leaching metal element impurities from the particles, which forms soluble metal chloride salts and gaseous hydrogen (H₂), such that the remaining surface (e.g., Si surface) from which impurities have been leached become weakly passivated with hydrogen.

In one exemplary embodiment, etched particles may be prepared by treating micron-sized Group IVA particles with one or more acids, with subsequent washing and drying steps as necessary. For example, etched Group IVA particles can be prepared by treatment with hydrochloric acid, followed by treatment with hydrofluoric acid and ammonia. The particles may be further treated with hydrofluoric acid before washing with water and drying. Etching of B-doped Si particles may be accomplished using silver nitrate (AgNO₃) in hydrofluoric acid (HF).

The treatment of the micron or submicron particles with the protic acid may be conducted in the presence of an agitation device, such as a stir bar or ceramic balls. The agitation of the container to passivate the particles with hydrogen may be accomplished with a roller mill (e.g., at 60 rpm for two hours). The container may be a screw top container. After agitating the container for hydrogen passivation (e.g., for two hours), the container may be allowed to stand motionless (e.g., for another two hours). The container may then be opened to release pressure and at least a portion of the liquid phase removed. Optionally, additional protic acid may be added and the hydrogen passivation step repeated. After hydrogen passivation, the container may be opened to release pressure and the liquid portion may be separated from the solids (e.g., by decantation). In the same or different container and under agitation, the hydrogen passivated submicron particles may be treated with the compound for passivation for a sufficient time (e.g., four to six hours) to affect passivation. The liquid phase may thereafter be removed from the solids (e.g., by syringe).

c. Milling & Surface Modification

Functionalized Group IVA nanoparticles may be produced from micron-sized elemental particles. Milling the micron-sized particles can be performed under anaerobic conditions, anhydrous conditions, or a combination thereof. Milling under anaerobic conditions, anhydrous conditions, or a combination thereof can produce Group IVA nanoparticles substantially free of surface oxides.

The milling process may produce Group IVA nanoparticles that are essentially free of oxygen. The milling process may produce Group IVA nanoparticles that are substantially free of oxygen. The milling process may produce Group IVA nanoparticles that are free of oxygen. The milling process may produce Group IVA nanoparticles that are essentially free of oxides. The milling process may produce Group IVA nanoparticles that are substantially free of oxides. The milling process may produce Group IVA nanoparticles that are free of oxides.

The milling process may be performed under a variety of conditions, such as in an evacuated chamber, with circulating fluid slurries, in reactive media, in inert media, or any combinations thereof. The milling process may be accomplished under anaerobic conditions. The milling process may be accomplished under an inert atmosphere (e.g., a nitrogen atmosphere or an argon atmosphere). The milling process may be accomplished under an atmosphere essentially free of oxygen. The milling process may be accomplished under an atmosphere essentially free of water. The milling process may be accomplished under an atmosphere essentially free of oxygen and water.

While anaerobic milling processes described herein may rigorously exclude oxygen from the milling process (e.g., in glove box), anaerobic milling may also be achieved under less rigorous conditions (e.g. on the bench top). As such, milling may be conducted in a controlled fluidic environment by purging the atmosphere in communication with the circulated slurry with inert gas and optionally with hydrogen gas, or another reducing agent to maintain a reducing environment. Reducing agents may be, but are not limited to, gases such as hydrogen, carbon monoxide, and ethylene; liquids such as butyllithium solutions in hexane, pentane or heptane; and solids such as lithium metal.

The milling process may be may be achieved in an environment wherein the O₂ content is 1000 ppm or less, 500 ppm or less, 100 ppm or less, 50 ppm or less, 20 ppm or less, 10 ppm or less, 9 ppm or less, 8 ppm or less, 7 ppm or less, 6 ppm or less, 5 ppm or less, 4 ppm or less, 3 ppm or less, 2 ppm or less, or 1 ppm or less, and the H₂O content is 1000 ppm or less, 500 ppm or less, 100 ppm or less, 50 ppm or less, 20 ppm or less, 10 ppm or less, 9 ppm or less, 8 ppm or less, 7 ppm or less, 6 ppm or less, 5 ppm or less, 4 ppm or less, 3 ppm or less, 2 ppm or less, or 1 ppm or less.

The source of the micron-sized particles may be a metallurgical group IVA element, a chemically etched metallurgical group IVA element, Al-doped group IVA element, B-doped group IVA element, Ga-doped group IVA element, P-doped group IVA element, N-doped group IVA element, As-doped group IVA element, Sb-doped group IVA element, or a combination thereof. For example, the source of the micron-sized particles may be metallurgical silicon, chemically etched metallurgical silicon, Al-doped silicon, B-doped silicon, Ga-doped silicon, P-doped silicon, N-doped silicon, As-doped silicon, Sb-doped silicon, or a combination thereof.

Functionalized Group IVA nanoparticles may be prepared from the micron-sized particles by a mechanical milling process. The mechanical milling process may include low energy ball milling, planetary milling, high energy ball milling, jet milling, bead milling, or a combination thereof. The milling process may be accomplished under “dry” conditions, wherein no solvents are used. The milling process may be accomplished under “wet” conditions, wherein one or more solvents are employed. “Wet” milling may be preferable when smaller and more uniform particle size distributions are desired. Solvents that may be used in the “wet” milling process include benzene, mesitylene, p-xylene, n-hexane, n-heptane decane, dodecane, petroleum ether, diglyme, triglyme, xylenes, toluene, alcohols or a combination thereof. The solvents are preferably deoxygenated and anhydrous. For example, the solvents may freshly distilled under inert atmosphere. The solvents may have an oxygen level of less than 1 ppm and a water content of less than 1 ppm.

In certain embodiments, the milling process is achieved in a bead mill one or more surface modifiers, one or more solvents, one or more polymer binders, or one or more other additives, and produces a circulating slurry of solvent-passivated nanoparticles.

The beads used in the bead mill may be spherical ceramic metal-oxide beads. The diameter of the beads may be about 0.1 mm, about 0.2 mm, about 0.3 mm, about 0.4 mm, about 0.5 mm, about 0.6 mm, about 0.7 mm, about 0.8 mm, about 0.9 mm, or about 1.0 mm. The diameter of the beads may be about 0.1 mm to about 1.0 mm, about 0.1 mm to about 0.9 mm, about 0.1 mm to about 0.8 mm, about 0.2 mm to about 0.8 mm, about 0.2 mm to about 0.7 mm, about 0.2 mm to about 0.6 mm, about 0.2 mm to about 0.5 mm, about 0.2 mm to about 0.4 mm, about 0.2 mm to about 0.3 mm, about 0.3 mm to about 0.7 mm, about 0.3 mm to about 0.6 mm, about 0.3 mm to about 0.5 mm, about 0.3 mm to about 0.4 mm, about 0.4 mm to about 0.7 mm, about 0.4 mm to about 0.6 mm, about 0.4 mm to about 0.5 mm, or about 0.5 mm to about 0.6 mm. In an exemplary embodiment, a powder of micrometer-sized Group IVA particles may be reduced to submicron particles by a Netzsch Dynostar mill using 0.4-0.6 mm yttrium-stabilized zirconia beads. Further processing to smaller average particle size (APS) may be accomplished by using a smaller bead size. A 0.1 mm diameter bead or smaller may allow APS reduction to less than 100 nm.

The bead mill agitator may have a tip velocity (also referred to as tip speed) of about 1 meters per second (m/sec), about 2 m/sec, about 3 m/sec, about 4 m/sec, about 5 m/sec, about 6 m/sec, about 7 m/sec, about 8 m/sec, about 9 m/sec, about 10 m/sec, about 11 m/sec, about 12 m/sec, about 13 m/sec, about 14 m/sec, about 15 m/sec, about 16 m/sec, about 17 m/sec, about 18 m/sec, about 19 m/sec, or about 20 m/sec. The bead mill agitator rotation rate may be adjusted so that a tip velocity of greater than about 12 m/sec delivers sufficient mechanical energy to cause changes in the nanoparticle morphology. The bead mill agitator rotation rate may be adjusted to induce the formation of alloys or mixed phase nanoparticles when two or more elements are co-comminuted (e.g., when silicon and tin are co-comminuted). Preferred tip speeds are 10 m/s or greater, 12 m/s or greater, or 12.6 m/s or greater.

The milling process may provide nanoparticle powders with BET surface area of greater than 10 m²/g, 50 m²/g, greater than 100 m²/g, greater than 150 m²/g, greater than 200 m²/g, greater than 250 m²/g, greater than 300 m²/g, greater than 350 m²/g, greater than 400 m²/g, greater than 450 m²/g, or greater than 500 m²/g.

The milling process can be conducted in the presence of one or more solvents, one or more surface-modifying agents, one or more metals or metalloid agents, one or more lithium reagents, one or more polymeric binder materials, and combinations thereof. The additional materials may have been pretreated so as to be anaerobic, anhydrous, or a combination thereof. For example, solvents used in the milling process can be dried and deoxygenated (e.g., by distillation).

The milling process may include the addition of particles of additional elements to form alloy nanoparticles. For example, silicon particles may be alloyed with tin, germanium, titanium, nickel, aluminum, copper or a combination thereof to form alloy nanoparticles.

The milling process may be done in the presence of lithium reagents. Treatment with lithium reagents can achieve lithiation of the surface of the Group IVA nanoparticles (e.g. silicon nanoparticles). The alkyllithium reagent may be n-butyllithium, t-butyllithium, s-butyllithium, phenyllithium, methyllithium, or a combination thereof.

The milling process may be done in the presence of one or more reagents to form a synthetic SEI layer or shell around active sites of the Group IVA materials. Exemplary reagents include, but are not limited to, alkyl lithium reagents, lithium alkoxide reagents, lithium ammonia borofluoride reagents, ammonia borofluoride reagents, and any combination thereof. Exemplary alkyl lithium reagents include, but are not limited to, n-butyllithium, t-butyllithium, s-butyllithium, phenyllithium, and methyllithium. Exemplary lithium alkoxides include, but are not limited to, those of formula LiAl(OR_{F})₄, wherein R_{F} at each occurrence is independently fluoroalkyl, fluoroaryl, and aryl. One exemplary lithium alkoxide is LiAl(OC(Ph)(CF₃)₂)₄. Exemplary lithium ammonia borofluorides and ammonia borofluorides include, but are not limited to, those of formula Li⁺R₃NB₁₂H₁₁⁻, Li⁺R₃NB₁₂F₁₁⁻, (H₃N)₂B₁₂H₁₀, (H₃N)₂B₁₂F₁₀, wherein R₃ at each occurrence is independently selected from hydrogen and C₁-C₄ alkyl (e.g., methyl, ethyl, propyl, butyl). Exemplary lithium ammonia borofluorides and ammonia borofluorides include, but are not limited to Li⁺H₃NB₁₂H₁₁⁻, Li⁺NB₃NB₁₂H₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, and 1,12-(H₃N)₂B₁₂F₁₀.

d. Recovering Functionalized Group IVA Particles

Functionalized Group IVA submicron particles may be dried by evaporation, optionally at reduced pressure at room temperature. Optionally, evaporation may be achieved under reduced pressure. Preferably, when under reduced pressure, care is taken to provide sufficient heat to the evacuated vessel to avoid freezing of the solvent(s). Preferably, care is taken to avoid sweeping nano particles into the receiving flask when the velocity of the solvent vapors is high. The functionalized Group IVA particles may be maintained in an inert atmosphere, preferably an anaerobic environment, anhydrous environment, or a combination thereof.

e. Exemplary Embodiments

In certain embodiments, passivated Group IVA particles may be prepared by providing a first Group IVA micron or submicron sized particle; and treating the particle under anaerobic conditions with a material for passivation to provide a passivated Group IVA particle. For example, a passivated Group IVA nanoparticle can be provided by milling a micron-sized Group IVA material in bead mill contained with a glove box maintained under anaerobic conditions.

In certain embodiments, passivated Group IVA particles may be prepared by providing a first Group IVA micron or submicron sized particle; and treating the first particle under anaerobic conditions with a compound (preferably other than hydrogen) to provide a passivated Group IVA particle. In certain embodiments, the compound may be benzene, p-xylene, or mesitylene. In certain embodiments, the compound may be a material for passivating the Group IVA particle by forming one or more covalent bonds therewith.

In certain embodiments, passivated Group IVA particles may be prepared by subjecting a material comprising a Group IVA element (e.g., bulk crystalline silicon (c-Si) ingots and/or silicon powder such as 325 mesh silicon powder) to comminution in the presence of one or more surface modifiers (e.g., benzene, p-xylene, mesitylene, 2,3-dihydroxyanthracene, 2,3-dihydroxynaphthalene, or a combination thereof) and optionally one or more non-competing solvents to provide sub-micron to nano-sized benzene-passivated Group IVA particles (e.g., 30-300 nm, 30-150 nm, or 200-300 nm Group IVA particles). Optionally, the passivated Group IVA particles may be combined with one or more additives (e.g., conductive adhesion additives and/or dopant additives) before, during, or after milling to provide a composition or a composite.

In certain embodiments, passivated Group IVA particles may be prepared by subjecting a material comprising a Group IVA element (e.g., bulk crystalline silicon (c-Si) ingots and/or silicon powder such as 325 mesh silicon powder) to comminution under anaerobic conditions in the presence of a material for passivation (other than benzene or hydrogen). The comminution may include use of benzene, p-xylene, mesitylene, or a combination thereof, and/or a non-competing solvent (e.g., triglyme) to provide the sub-micron to nano-sized passivated Group IVA particles (e.g., 30-300 nm, 30-150 nm, or 200-300 nm Group IVA particles). Optionally, the passivated Group IVA particles may be combined with one or more additives (e.g., conductive adhesion additives and/or dopant additives) before, during, or after milling to provide a composition or a composite.

In certain embodiments, passivated Group IVA particles may be prepared by subjecting a material comprising a Group IVA element (e.g., bulk crystalline silicon (c-Si) ingots and/or silicon powder such as 325 mesh silicon powder) to comminution under anaerobic conditions in the presence of benzene, p-xylene, or mesitylene and optionally one or more non-competing solvents to provide sub-micron to nano-sized benzene-passivated Group IVA particles (e.g., 200-300 nm Group IVA particles); isolating the passivated Group IVA particles (e.g., by removing solvent(s) under vacuum); treating the passivated Group IVA particles with a modifier reagent (e.g., 2,3-dihydroxynaphthalene), optionally in the presence of a non-competing solvent (e.g., triglyme) for a selected time (e.g., 6 hours) and temperature (e.g., 220° C.); and isolating the modified Group IVA particles. Optionally, the modified Group IVA particles may be combined with one or more conductive adhesion additives (e.g., C₆₀, C₇₀ Fullerene derivatives) and/or dopant additives (e.g., C₆₀F₄₈) in a selected solvent (e.g., dichloromethane) to provide a slurry; sonicated for a selected time period (e.g., 10 minutes); and optionally dried to provide a composition of modified Group IVA particles and additives.

In certain embodiments, passivated Group IVA particles may be prepared by subjecting a material comprising a Group IVA element (e.g., bulk crystalline silicon (c-Si) ingots and/or silicon powder such as 325 mesh silicon powder) to comminution under anaerobic conditions in the presence of a material for passivation (other than benzene or hydrogen) and optionally one or more non-competing solvents and/or benzene to provide sub-micron to nano-sized passivated Group IVA particles (e.g., 30-300 nm, 30-150 nm, or 200-300 nm Group IVA particles); and isolating the passivated Group IVA particles (e.g., by removing solvent(s) under vacuum). Optionally, the modified Group IVA particles may be combined with one or more conductive adhesion additives (e.g., C₆₀, C₇₀ Fullerene derivatives) and/or dopant additives (e.g., C₆₀F₄₈ or C₆₀F₃₆) in a selected solvent (e.g., dichloromethane) to provide a slurry; sonicated for a selected time period (e.g., 10 minutes); and optionally dried to provide a composition of modified Group IVA particles and additives.

In certain embodiments, passivated Group IVA particles may be prepared by providing a first Group IVA micron or submicron sized particle; and treating the first particle under anaerobic conditions with a compound (preferably other than hydrogen, and optionally other than benzene) to provide a passivated Group IVA particle.

In certain embodiments, passivated Group IVA particles may be prepared by providing a first Group IVA micron or submicron sized particle; treating the first particle with benzene, p-xylene, or mesitylene to yield a passivated Group IVA particle; and treating the passivated Group IVA particle with a compound (preferably other than hydrogen and benzene) to provide a passivated Group IVA particle.

In certain embodiments, passivated Group IVA particles may be prepared by providing a first Group IVA micron or submicron sized particle; treating the first particle with a protic acid to provide a hydrogen passivated Group IVA particle; and treating the hydrogen passivated Group IVA particle under anaerobic conditions with a compound (preferably other than hydrogen) to provide a passivated Group IVA particle.

In certain embodiments, passivated Group IVA particles may be prepared by providing a first Group IVA micron or submicron sized particle; treating the first particle with a protic acid to provide a hydrogen passivated Group IVA particle; treating the hydrogen passivated Group IVA particle under anaerobic conditions with benzene, p-xylene, or mesitylene to yield a benzene passivated Group IVA particle; and treating the passivated Group IVA particle under anaerobic conditions with a compound (preferably other than hydrogen) to provide a passivated Group IVA particle.

In cases where it is desirable to replace benzene, p-xylene, or mesitylene monolayers with functional hydrocarbons other than solvents, it may be necessary to stir the passivated particles in a non-functional solvent (also referred to herein as a “non-competing solvent”) with the desired functional hydrocarbon dissolved or suspended in it. Exemplary non-functional solvents useful in methods of preparing surface-modified Group IVA particles include, but are not limited to, 1,2-dimethoxyethane (also referred to as glyme, monoglyme, dimethyl glycol, or dimethyl cellosolve); 1-methoxy-2-(2-methoxyethoxy)ethane (also referred to as diglyme, 2-methoxyethyl ether, di(2-methoxyethyl) ether, or diethylene glycol dimethyl ether); 1,2-bis(2-methoxyethoxy)ethane (also referred to as triglyme, triethylene glycol dimethyl ether, 2,5,8,11-tetraoxadodecane, 1,2-bis(2-methoxyethoxy)ethane, or dimethyltriglycol); 2,5,8,11,14-pentaoxapentadecane (also referred to as tetraglyme, tetraethylene glycol dimethyl ether, bis[2-(2-methoxyethoxy)ethyl]ether, or dimethoxytetraglycol); dimethoxymethane (also referred to as methylal); methoxyethane (also referred to as ethyl methyl ether); methyl tert-butyl ether (also referred to as MTBE); diethyl ether; diisopropyl ether; di-tert-butyl ether; ethyl tert-butyl ether; dioxane; furan; tetrahydrofuran; 2-methyltetrahydrofuran; and diphenyl ether. For example, naphthalene dissolved in triglyme replaces benzene on the surface of Group IVA particles upon stirring at reflux temperature under nitrogen atmosphere.

Hydrogen can then be replaced from the Group IVA particles with a selected compound. In certain embodiments, the hydrogen passivated Group IVA particles may be treated with certain functional organic materials (e.g., hydrocarbons) that form strong covalent bonds with Group IVA element. Examples of functional groups that form bonds with Group IVA surfaces (e.g., Si surfaces) include, but are not limited to, alkenes, alkynes, phenyl (or any aromatic cyclic organic compounds), alcohols, glycols, thiols, disulfides, amines, amides, pyridines, pyrrols, furans, thiophenes, cyanates, isocyanates, isothiocyanates, ketones, carboxylic acids, amino acids, aldehydes, and other functional groups able to share electrons through pi bonds or lone pair electrons.

In certain embodiments, following the above sequence of treatments, silicon particles made from impure grades of bulk Si may have irregular shapes, but include a monolayer of hydrocarbons on Si surfaces that have been freshly exposed by leaching gettered impurities or by fracturing during a milling process. Hydrocarbons can be chosen to replace hydrogen bonding to the Si surface that allow a high degree of charge mobility, thus rendering the Si surface effectively non-dielectric. Further reaction of the Si surface with oxygen leading to SiO₂ formation may be inhibited by the presence of the hydrocarbon monolayer. Even if areas of the nanoparticle surface are not completely free of dielectric oxides, charge mobility from the nanoparticle to a surrounding framework, or vice versa, may still occur through the non-dielectric passivated areas on the surfaces.

In certain embodiments, passivated Group IVA particles may be prepared by providing a Group IVA powder; reducing the Group IVA powder to submicron particles; within a closed container treating at least a portion of the submicron particles with an aqueous liquid comprising a protic acid; agitating the container for a time sufficient to passivate the submicron particles therein with hydrogen; separating at least a portion of the aqueous liquid from the hydrogen passivated submicron particles; and within a closed container treating the hydrogen passivated submicron particles with a compound (other than hydrogen) to provide passivated Group IVA particles.

In an industrial process, solvents may be removed by circulating dry nitrogen gas across heated evaporations plates covered with a slurry of the particles/solvent at near atmospheric pressure. The solvent saturated gas may be passed through a condenser to recover the solvents and restore the unsaturated gas for further recirculation. This process may minimize carryover of nanoparticles into the solvent condenser.

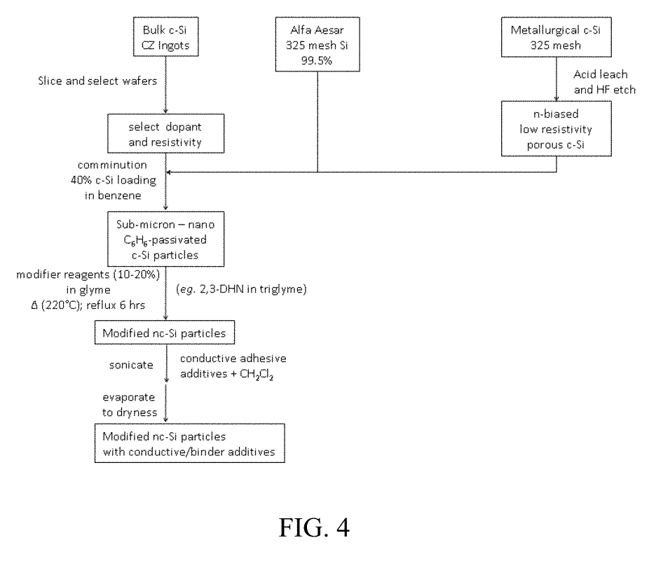

FIG. 4 shows one exemplary process for preparing functionalized Group IVA particles. The Group IVA particles may be derived from bulk crystalline silicon (c-Si) ingots (e.g., P-doped (n-type) silicon having a resistivity of 0.4-0.6 Ωcm⁻¹), and/or silicon powder such as 325 mesh silicon powder (e.g., 325 mesh Si, 99.5% available from Alfa Aesar, 26 Parkridge Rd Ward Hill, Mass. 01835 USA; or metallurgical grade c-Si 325 mesh). The bulk c-Si ingots can be sliced into wafers. Where metallurgical c-Si 325 mesh is used, the material may be subjected to acid leaching and hydrofluoric (HF) acid etching to provide n-biased low resistivity porous c-Si. The sliced wafers and/or the silicon powder may be subjected to comminution in benzene, p-xylene, or mesitylene to provide sub-micron to nano-sized passivated c-Si particles (e.g., 20-300 nm particles). The initial solids loading in the comminution slurry may be between 10 wt % to 40 wt %, and decrease (by adding additional solvent) as the particle size distribution declines in order to maintain an optimum slurry viscosity. The solvent may be removed via vacuum distillation followed by vacuum drying (e.g., for 6 hours or longer at 23° C.) to provide the passivated c-Si particles. A selected amount (e.g., 1 gram) of the passivated c-Si particles may be treated with a modifier reagent (e.g., 2,3-dihydroxynaphthalene) in a non-functional solvent (e.g., triglyme) under anaerobic conditions and refluxed for a selected time (e.g., 6 hours) and temperature (e.g., 220° C.). After refluxing, the modified nc-Si particles may be allowed to settle and the non-functional solvent removed (e.g., by decanting, or filtering). The modified nc-Si particles may be washed (e.g., with an ether solvent) and then dried. The modified nc-Si particles (e.g., optionally in a dried and powdered form) may be combined with one or more conductive adhesion additives (e.g., C₆₀, C₇₀ Fullerene derivatives) in a selected solvent (e.g., dichloromethane) to provide a slurry. Optionally, a dopant additive (e.g., C₆₀F₄₈) may also be added to the slurry. The slurry may be sonicated for a selected time period (e.g., 10 minutes) and then dried (e.g., air dried or vacuum) to provide a composition of modified nc-Si particles and conductive/binder additives.

One or more of the foregoing described steps can be conducted in an inert atmosphere (e.g., in a glove box) that has an oxygen content of less than 1 ppm, and a water content of less than 1 ppm.

### 5. SEI Films

Functionalized Group IVA particles may be incorporated into a composite for use in anodes of lithium ion batteries, functioning as high capacity anodes having high charge mobility. The composite can provide optimum porosity, allowing ion flow in all directions, thereby reducing internal resistance that can lead to the generation of heat. The composite can accommodate space requirements for lithium at the anode, and resist mechanical breakdown as compared to known silicon based composites. The composite can also provide conduits for electrical charge mobility and lithium ion mobility to and from sites where lithium ions (Li⁺) reside in an electron-rich environment, and the reverse process in which Li⁺ migrates from the negative electrode to the positive electrode to combine atoms in an oxidized state. The facile electron mobility may be beneficial also in suppressing the formation of solid electrolyte interface (SEI) films believed to form from solvent decomposition as a consequence of localized electrical potentials. While SEI formation is essential for the continued operation of all solvent-based secondary Li⁺ batteries, too much buildup of SEI leads to high internal resistance and discharge capacity fade with eventual complete failure of the battery. Silicon (Si) surfaces that are not modified with an electrically conductive passivation layer tend to form multiple SEI layers as cycling occurs due to the delamination of the previously formed SEI layer from the Si surface by particle expansion between the SEI and the Si surface and reformation of a new SEI layer.

The benefit of a covalently bonded conductive monolayer on the silicon surface is that it forces the Li⁺ permeable SEI layer to form above the Si surface, allowing Li⁺ to migrate close to the Si surface without delaminating the SEI layer. By selecting the optimum length, shape, and electronic properties of the molecules that comprise the conductive monolayer that modify the Si surface, the monolayer becomes an integral part of the conductive framework while it also prevents the initial formation of SEI too close to the Si surface and provides space to accommodate particle expansion upon lithiation. The original SEI layer stays in-tact because the composite as described above suppresses delamination of the original SEI layer and the formation of additional SEI layers. The composite, which conducts charge efficiently, can provide increased recharge rate, decreasing the time required to recharge the battery.

Pre-lithiation of anode materials produced from the functionalized Group IVA particles can promote stable SEI formation. Pre-lithiation can also prevent depletion of lithium of battery electrolyte solutions. These advantages of provided by the pre-lithiation can increase battery lifetime (e.g., number of cycles), capacity, fade, and charge/discharge time. Pre-lithiation of the negative electrode may be accomplished by exposing the surface of the negative electrode to lithium foil, in an electrolyte solution and in a closed electrical circuit.

The disclosed methods provide for preparation of synthetic SEI layers or shells around the functionalized Group IVA particles and composite materials. Generally, SEI layers are polymers that form around anode materials upon degradation of electrolyte solvent (e.g., ethylene carbonate) upon applied electrochemical potential to a cell, with these layers incorporating lithium into the matrix. The polymer forms around active sites where electrochemical potential is high. While the SEI layer allows for migration of lithium ions between the positive and negative electrodes, excessive formation of SEI layer can impede the insertion and deinsertion of lithium. Moreover, too much SEI layer formation can result in the loss of ohmic contacts necessary for proper anode function. The presently disclosed methods provide for the formation of a synthetic SEI layer prior to placement of a prepared anode material into a lithium ion battery. By forming the synthetic SEI layer (e.g., by treating a milled or post-milled material with a lithium aluminum alkoxide, lithium ammonia borofluoride, or an ammonia borofluoride) prior to the first charging of a battery comprising the treated anode material, the electrolyte solvent (e.g., carbonate solvents) will have limited or no access to active sites of the anode materials, and further SEI layer formation will be prevented or reduced. Consequently, lithium can migrate freely between the positive and negative electrodes. The presence of the synthetic SEI layer can improve battery performance over a number of cycles (e.g., capacity, fade) and extend the lifetime of the battery as insertion and deinsertion of lithium will result in little or no breakdown of the anode material due to expansion and re-expansion.

### 6. Applications

The functionalized Group IVA particles, including compositions and composites comprising the functionalized Group IVA particles, may be used in a variety of applications. The Group IVA particles may be used where spectral shifting due to quantum confinement is desirable, and particle size distributions under 15 nanometers (nm) are required. The Group IVA particles may be used where particle size compatibility with a porous framework is desired, or it is desired to have material properties that resist alloyation with other metals such as lithium (Li). The Group IVA particles may be used to provide viable commercial products using specific particle size distribution ranges.

The functionalized Group IVA particles may be prepared and stored for use.

The functionalized Group IVA particles may be provided into a selected solvent and applied to a selected substrate to provide a conductive film. The surface-modified Group IVA particle/solvent mixture useful for application to a substrate may be referred to as an “ink,” a “paste,” or an “anode paste.” Suitable solvents for preparing the inks include, but are not limited to, dichloromethane (also referred to as methylene chloride); 1,2-dichloroethane; 1,1-dichloroethane; 1,1,1-trichloropropane; 1,1,2-trichloropropane; 1,1,3-trichloropropane; 1,2,2-trichloropropane; 1,2,3-trichloropropane; 1,2-dichlorobenzene (also referred to as ortho-dichlorobenzene); 1,3-dichlorobenzene (also referred to as meta-dichlorobenzene); 1,4-dichlorobenzene (also referred to as para-dichlorobenzene); 1,2,3-trichlorobenzene; 1,3,5-trichlorobenzene; α,α,α-trichlorotoluene; and 2,4,5-trichlorotoluene. Substrates coated with the ink may be further processed for fabrication of products and devices including the conductive film.

A conductive film may have a thickness of 10 microns. A conductive film may have dimensions of 18 mm diameter.

Fields of useful applications for the functionalized Group IVA particles and conductive films including the particles include, but are not limited to, rendering solubility of functional nano particles in various solvent systems for the purpose of separation of particle size distributions; to enhance transport properties in biological systems such as blood or across diffusible membranes; to alter quantum effects of nanoparticles and to optimize the properties of electronic films used in solar photovoltaics, luminescence, biosensors, field-effect transistors, pigments, electromagnetic energy sensitizers and catalysts involving electron transfers.

a. Battery Applications

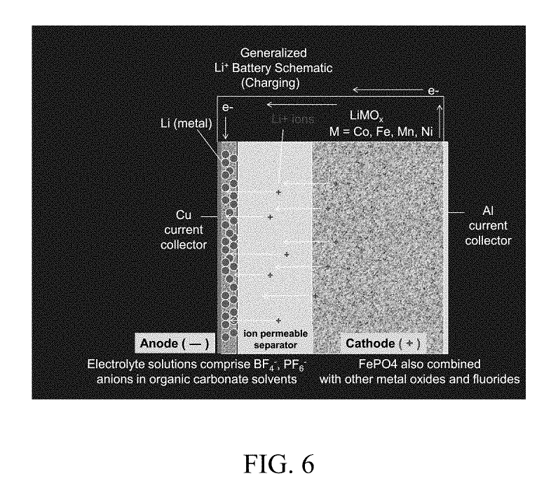

The functionalized Group IVA particles may be useful in battery applications, particularly in anodes of lithium ion batteries. FIG. 6 depicts a lithium ion battery using a anode fabricated using functionalized Group IVA composites (e.g., a composite comprising functionalized Group IVA particles, polymer binders, conductive carbon additives, or dopant additives).

Anodes fabricated from the functionalized Group IVA particles may exhibit suitable performance in one or more of specific charge capacity, fade, and discharge/recharge current, such that secondary lithium-ion (Li+) batteries containing anodes made with the surface-modified Group IVA particles are commercially viable. The term “specific charge capacity,” as used herein, may refer to how much energy a battery can deliver per gram of surface-modified Group IVA particles in the battery anode. The term “fade,” as used herein, may refer to how many discharge/recharge cycles a battery can undergo before a given loss of charge capacity occurs (e.g., no more than 2% over 100 cycles, or 10% over 500 cycles, or some other value determined in part by how the battery will be used). The term “discharge/recharge current,” as used herein, may refer to how fast a battery can be discharged and recharged without sacrificing charge-capacity or resistance to fade.

The disclosed lithium-ion batteries may have a fade, over 20 cycles, of 5% or less, 4% or less, 3% or less, 2% or less, or 1% or less. The disclosed lithium-ion batteries may have a fade, over 25 cycles, of 5% or less, 4% or less, 3% or less, 2% or less, or 1% or less. The disclosed lithium-ion batteries may have a fade, over 30 cycles, of 5% or less, 4% or less, 3% or less, 2% or less, or 1% or less. The disclosed lithium-ion batteries may have a fade, over 35 cycles, of 5% or less, 4% or less, 3% or less, 2% or less, or 1% or less. The disclosed lithium-ion batteries may have a fade, over 40 cycles, of 5% or less, 4% or less, 3% or less, 2% or less, or 1% or less. The disclosed lithium-ion batteries may have a fade, over 45 cycles, of 5% or less, 4% or less, 3% or less, 2% or less, or 1% or less. The disclosed lithium-ion batteries may have a fade, over 50 cycles, of 5% or less, 4% or less, 3% or less, 2% or less, or 1% or less.

The disclosed batteries may have a capacity of 2,000 of milliamp-hours per gram or greater, 2,500 of milliamp-hours per gram or greater, or 3,000 of milliamp-hours per gram or greater.

The disclosed batteries may have a 0.03 milliamp charging rate or greater, 0.04 milliamp charge rate or greater, 0.05 milliamp charge rate or greater, or 0.06 milliamp charge rate or greater. [mA]

The disclosed batteries may be manufactured under conditions of greater safety compared to conventional processes.

Specific charge capacity, fade, and discharge/recharge current may not be dependent on one another. In certain embodiments, a battery comprising an anode fabricated with the surface-modified Group IVA particles may exhibit good specific charge capacity but poor resistance to fade. In certain embodiments, a battery comprising an anode fabricated with the surface-modified Group IVA particles may exhibit a modest specific charge capacity but very good resistance to fade. In certain embodiments, a battery comprising an anode fabricated with the surface-modified Group IVA particles may exhibit either good specific charge capacity, good resistance to fade, or both, with either a good (high) discharge/recharge current or a poor (low) discharge/recharge current. In certain embodiments, a battery comprising an anode fabricated with the surface-modified Group IVA particles may exhibit a high specific charge capacity (as close to the theoretical maximum of 4,000 mAh/g as possible), excellent resistance to fade, and very fast discharging/recharging.

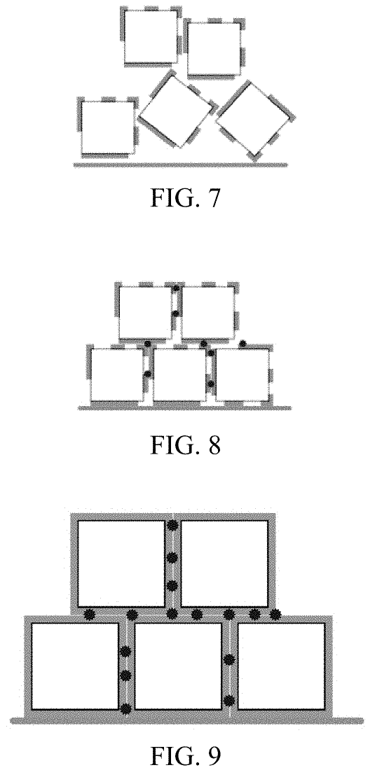

Anodes prepared with unmodified, partially-oxidized particles have poor conductivity (hence low discharge/recharge current) because the particles are only in electrical contact over a fraction of their surface, and they have poor specific charge capacity because some of the particles are not in electrical contact with the majority of the particles. This situation can be mitigated to some extent when the Group IVA are modified (e.g., with 2,3-dihydroxynaphthalene) before they are made into anodes. FIGS. 7-9 depict a simplified representation of plurality of passivated Group IVA particles in electrical contact in an anode. An anode material according to FIG. 7 may provide batteries with poor specific charge capacity but good resistance to fade. FIG. 8 shows an anode of surface-modified Group IVA particles in the presence of a C₆₀ conductive adhesion additive (the C₆₀ molecules are dark-blue Vercro-like circles). When C₆₀ is added to the anode paste before making the anode, the density of the anode per unit volume increases, the specific-charge capacity of the anode increases, and in some cases the discharge/recharge current increases. The C₆₀ molecules may “glue” the particles together, increasing the fraction of particles in electrical contact and increasing the electrical conductivity (and hence increasing the speed at which Li⁺ ions are initially charged into, are discharged out of, or are recharged into, the anode). When an additional dopant additive C₆₀F₄₈ is present (not shown in FIG. 8), one or more of specific charge capacity, fade, and discharge/recharge current may be improved. FIG. 9 shows an anode fabricated from an anode paste comprising un-oxidized functionalized Group IVA particles, a conductive adhesion additive, and a dopant additive. The anode of FIG. 9 may exhibit superior performance in all of specific charge capacity, fade, and discharge/recharge current.

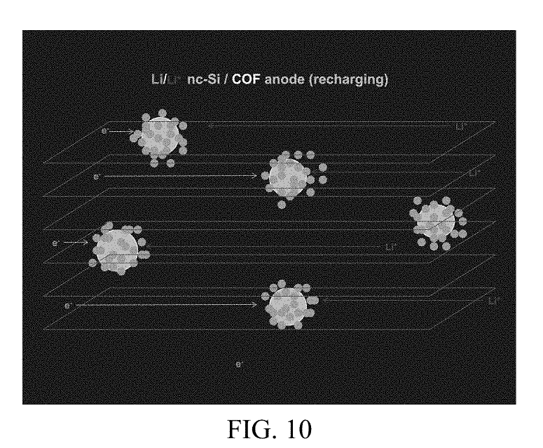

In certain embodiments, the passivated Group IVA particles may be covalently bonded to a porous covalent framework. The framework including the Group IVA particles may be particularly useful in lithium ion battery applications. The framework may be a covalent organic framework, a metal organic framework, or a zeolitic imidazolate framework. The framework may be a 2-dimensional framework or a 3-dimensional framework. A complete framework composite may comprise multiple sheets of frameworks stacked and aligned on top of one another. The sheets may be aligned and stacked in close proximity with one another to provide electron mobility in the perpendicular direction to the plane of the sheets. FIG. 10 depicts one porous framework composite according to the present invention that may serve as an anode in a lithium ion battery application.

Submicron silicon particles bonded to a porous covalent framework with high charge mobility may provide a high capacity anode in lithium-ion batteries. Silicon is known to form alloys with lithium having the capacity to attract a greater mass of lithium than any other known element. Anodes with silicon have the capacity to attract more than 10 times the mass of lithium than conventional carbon-based anode composites. Consequently, material scientists and battery manufacturers have attempted to form silicon bearing composites that function as the anode in lithium-ion batteries. The primary hurdle facing these efforts relates the charge/recharge cycle stability of the anode composites. This is because no structural form of bulk silicon (or germanium) can accommodate the spatial requirement imposed by the accumulated lithium and the composites degrade mechanically after the first charge cycle.

Because lithium-ion batteries are often developed as secondary batteries (rechargeable) they must undergo many charge/recharge cycles (1000 or more) without significant loss of charge capacity. Thus, if silicon is used in lithium-ion battery anodes, the structure of the composite must be capable of accommodating large amounts of lithium (as much as 4 times the volume with a full Li charge compared to the composite with no Li accumulation). Si particles must also be small enough to resist alloyation by lithium. Si nanowires and nanoporous silicon and quantum dots have all demonstrated the ability to attract lithium without causing mechanical fracturing of the silicon particles. Thus, a nanoporous composite comprising surface-modified crystalline or amorphous silicon particles may be produced to provide porosity and high surface area that allows access to lithium ions and space in between particles for expansion for the growth of reduced lithium metal.

A framework that supports silicon particles may allow Li⁺ ions to migrate. The porous framework may accommodate solvents and electrolytes and allow free migration of ions ideally in all directions. The frameworks can be designed with optimum porosity. The reticular pattern with which the structural units are assembled may result in perfectly even porosity throughout the framework, allowing ion flow in all directions with no “hot spots” or areas of restricted flow that contribute to a battery's internal resistance leading to the generation of heat. A framework may be constructed from efficient packing of particles of random shapes within a size distribution that provides adequate porosity for permeation of Li⁺ ions and electrolyte solutions.

Porous electrode composites may allow charge to be conducted from sites where reduction and oxidation occurs to the current collector. The conduction path is bidirectional since the direction of charge and electrolyte flow are reversed when the battery is being recharged as opposed to when the battery is providing electrical power. Frameworks using planar porphyrin structural units or other conductive structural units within appropriate geometric shapes (i.e, Fullerenes or polycyclic aromatic hydrocarbons (PACs)) have the ability to accommodate electrical charge in its extended pi system and the alignment of the structural units by the reticular assembly provides an efficient path for electrons as demonstrated by charge mobility measurements. While some electrode designs require the inclusion of conductive carbon in the composite, the electrode with conductive frameworks may or may not. For example, the functional cells may use no added conductive carbon-based Fullerenes or PAHs other than by passivating monolayer bonded to and modifying the crystalline particle surface.

While many conductive frameworks could be constructed, examples of organic boronic ester frameworks are of particular interest because their syntheses can be accomplished using mild non-toxic reagents and conditions and because they have interesting fire-retardant properties. Covalent Organic Frameworks (COFs) that incorporate either trisboronic- or tetraboronicester vertices bound by aromatic struts builds layered two-dimensional or three-dimensional frameworks, respectively. Two aromatic precursors, 1,2,4,5-tetrahydroxybenzene and 2,3,6,7-tetrahydroxyanthracene have been described and have been combined with boronic acids, building COFs that have very high electron mobility and remarkably good fire suppression properties. Incorporating Group IVA particles functionalized with these symmetric tetraols provides a means of covalently bonding the Group IVA particles to the COF matrix. Functionalization of benzene passivated Group IVA particles with either of these symmetric tetraols can be accomplished by refluxing the benzene functionalized Group IVA particles suspended with the tetraol in benzene or in a non-competing solvent such as tryglyme. While benzene can leave the particle surface without decomposition, the tetraol forms a chelate and once bonded to the particle surface will not leave.

While Group IVA particles covalently bonded to a conductive organic framework could make a novel composite for lithium battery anodes, a functionalized Group IVA particle incorporated in layered graphite, stacked carbon nanotubes, Fullerenes, activated carbon or other less structured porous carbon or polymer composites could also significantly enhance the properties of those materials toward lithium storage or other properties outlined above. In other words, the incorporation of functionalized Group IVA particles does not necessarily have to be formally bonded into a coherent framework to realize benefits in the composites. In these applications, the choice of dopants that render “n-type” (nitrogen, phosphorous, antimony) and “p-type” (boron) would be chosen to populate the conduction band or depopulate the valence band respectively of these Group IVA semiconductors with electrons. While the n-type configuration would behave more like a conductor, the p-type configuration would be prone to capturing photon energy and converting it to charged particles. Furthermore, incorporation of photo-active semiconductors capable of capturing and transferring photon energy to electrical charge could be useful when combined with porous electrically active materials that bear functional groups capable of producing unstable radicals. These radicals are known to catalyze chemical transformations, particularly the oxidation of stable hydrocarbons and the oxidation of stable metals in low valence states to higher valence states. Such activity could be useful for treatment of chemical waste, water and air purification and the capture of toxic metals such as arsenic, selenium, lead and mercury.

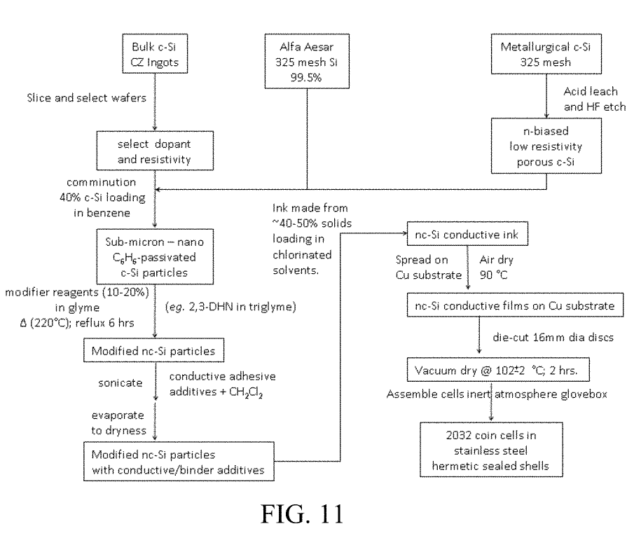

FIG. 11 depicts one exemplary process for preparing a battery comprising the functionalized Group IVA particles. The Group IVA particles may be derived from bulk crystalline silicon (c-Si) ingots (e.g., P-doped (n-type) silicon having a resistivity of 0.4-0.6 Ωcm⁻¹), and/or silicon powder such as 325 mesh silicon powder (e.g., 325 mesh Si, 99.5% available from Alfa Aesar, 26 Parkridge Rd Ward Hill, Mass. 01835 USA; or metallurgical grade c-Si 325 mesh). The bulk c-Si ingots can be sliced into wafers and surface orientation can be selected and the precise resistivity of individual wafers can be measured and selected prior to comminution. Where metallurgical c-Si 325 mesh is used, the material may be subjected to acid leaching and hydrofluoric (HF) acid etching to provide n-biased low resistivity porous c-Si. The sliced wafers and/or the silicon powder may be subjected to comminution in presence of one or more surface modifiers under anaerobic conditions to provide sub-micron to nano-sized passivated c-Si particles (e.g., 200-300 nm particles). The solvent may be removed via vacuum distillation followed by vacuum drying (e.g., 6 hours at 23° C.) to provide the passivated c-Si particles. A selected amount (e.g., 1 gram) of the passivated c-Si particles may be treated with a modifier reagent (e.g., 2,3-dihydroxynaphthalene) in a non-functional solvent (e.g., triglyme) under anaerobic conditions and refluxed for a selected time (e.g., 6 hours) and temperature (e.g., 220° C.). After refluxing, the modified nc-Si particles may be allowed to settle and the non-functional solvent removed (e.g., by decanting, or filtering). The modified nc-Si particles may be washed with an ether solvent and then dried. The modified nc-Si particles (e.g., in a dried and powdered form) may be combined with one or more conductive adhesion additives (e.g., C₆₀, C₇₀, Fullerene derivatives) in a selected solvent (e.g., dichloromethane) to provide a slurry. Optionally, a dopant additive (e.g., C₆₀F₄₈) may also be added to the slurry. The slurry may be sonicated for a selected time period (e.g., 10 minutes) and then dried (e.g., air dried or vacuum) to provide the modified nc-Si particles with conductive/binder additives, such as polythiophenes (e.g., P3HT).

The modified nc-Si particles with the conductive/binder additives may be combined with a selected solvent (e.g., a chlorinated solvent such as trichloropropane) to provide a conductive ink (e.g., 40-50 wt % solids loading). The conductive ink may be applied (e.g., paintbrush application, film spreader) to a selected substrate (e.g., a copper substrate, with or without a carbon coating) and thereafter dried under a selected atmosphere (e.g., inert atmosphere) and temperature (e.g., 90° C.). The ink-coated substrate may then be die-cut to discs (e.g., 16 millimeter discs) using a die cutter or calendared to provide anode disks or an anode sheet. The discs or sheets may then be dried under a vacuum for a selected time period (e.g. 2 hours) at a selected temperature (e.g., 100° C.).

Anode discs, along with other components for preparing a coin cell battery (e.g., cathode, separator, electrolyte), may be assembled into a coin cell under an inert atmosphere (e.g., in a glove box). A controlled atmosphere glovebox with coin cell assembling equipment, including a hydraulic crimper for crimping 2032 coin cells can be used. The coin cells may include a stainless steel container that includes a polymer to seal the top and bottom and sides of the cell from each other.

b. Photovoltaic Applications

The functionalized Group IVA particles may be useful in photovoltaic applications. The Group IVA particles may be used to provide a semiconductor film comprised of submicron Group IVA particles dispersed and in communication with an electrically-conductive fluid matrix or liquid crystal. The film may be prepared by making a semiconductor particle suspension, depositing the semiconductor particle suspension on a substrate, and curing the semiconductor particle suspension at a temperature of 200° C. or less to form the semiconductor film. The semiconductor particles may be comprised of elements from the group consisting of B, Al, Ga, In, Si, Ge, Sn, N, P, As, Sb, O, S, Te, Se, F, Cl, Br, I, Ti, Zr, Hf, V, Nb, Ta, Cr, Mo, W, Mn, Re, Fe, Ru, Os, Co, Rh, Ir, Ni, Pd, Pt, Ag, Cu, Au, Zn, Cd, lanthanides, and actinides. The semiconductor particles may be p-type or n-type. The method may be performed completely at room temperature.

The semiconductor films that may be applied in sequence on a substrate, rigid or flexible, may be integral parts of a functioning semiconductor device having been assembled monolithically with no annealing during any part of the manufacturing process. The semiconductor films may be applied as inks printed on the substrate by ink-jet or any known printing process capable of creating uniform films on a substrate surface. Conductive circuitry may also be printed in the same manner as the semiconductor films, all becoming integral parts of the complete electronic device.

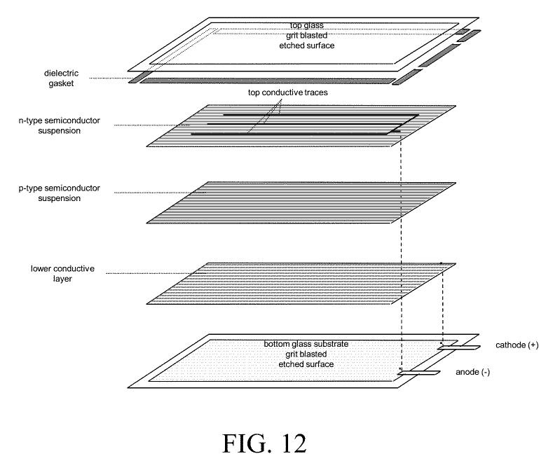

For example, in the case where the semiconductor device is a photovoltaic cell, a p-type semiconductor film (abbreviated as “p-film”) may be applied by ink-jet to the substrate with a conductive surface. Upon sufficient curing of the p-film, an n-type semiconductor film (n-film) may be applied directly on the partially cured p-film. After the first two films are sufficiently cured, conductive circuitry may be applied on top of the n-film. The conductive circuitry can be printed through a mask or by such print jet capable of making narrow, wire-like conduction pathways. The conductive circuitry on top may minimize the area that shades incident light on the surface of the semiconductor films. The conductive circuitry on top of the n-film may be connected to the negative terminal (anode), while the conductive surface under the p-film and on the substrate may be connected to the positive terminal (cathode). The cell may then be hermetically sealed with a sunlight-transparent covering, gaskets and cement. A schematic diagram of such a cell is depicted in FIG. 12.

Also disclosed herein is a method of making a photovoltaic cell at room temperature from semiconductor films composed of Group IVA submicron particles. In certain embodiments, photovoltaic activity may be observed in cells made by the methods in this invention using crystalline silicon films having a mean particle size distribution above 1 micron. Yet in other embodiments, higher photovoltaic efficiency may be achieved from films made with nanoparticle size distributions such that quantum confinement becomes an important factor in the absorption of photons and photon-electron transitions. Distinct advantages are gained with the use of nanoparticle films in solar PV collectors, one being the efficiency and breadth of the solar radiation spectrum that can be absorbed and converted to electrical energy using crystalline silicon. For example, solar cells made from bulk silicon wafers are typically 30 thousandths (˜0.7 mm) thick, while some silicon nanoparticle thin films that have equivalent photon absorption capacity need only be less than 100 nm.

Bulk crystalline silicon is inherently an indirect band gap semiconductor, which explains why photon absorption efficiency is low even though the natural band gap for silicon is nearly perfectly centered in the solar spectrum. For absorption and conversion of a photon to an electron hole pair to occur in indirect band gap semiconductors (p-type), the conversion must be accompanied with the production of a phonon (a smaller packet of thermal energy). Not only is some energy lost in each conversion of photon to electron, but these conversions do not readily occur because it is a forbidden transition. Still, forbidden transitions can and do occur, but they happen much less frequently than in direct band-gap semiconductors. Similarly, florescence (resulting in the annihilation of an electron or electron hole pair with the emission of a photon) also is forbidden in indirect band-gap semiconductors and allowed in direct band-gap semiconductors. Consequently, silicon is a poor luminescence semiconductor, but it is capable of preserving energy in the form of an electron hole pair for long enough to allow the charge to migrate to the p-n junction where it meets an electron from the conduction band of the n-semiconductor layer.

Under ideal conditions the maximum theoretical photovoltaic efficiency of bulk crystalline silicon is just over 30%, while in practice the best photovoltaic efficiency in crystalline silicon wafer solar cells is 22-24%. Still, crystalline silicon wafer technology is most commonly used in commercial solar PV panels because their efficiency is far better than amorphous silicon films and the PV efficiency fade over time is very low compared to other solar PV technologies. PV efficiency for silicon nanoparticle films has been measured in the laboratory as high as 40-50% with some expectations that even higher efficiencies are attainable. However, these devices have not yet been commercialized presumably because the cost of commercialization is too high to compete with existing technologies.

While others have used expensive heat processing methods to fuse various elements of the semiconductor materials to form functioning semiconductor devices, disclosed herein is a method of making these devices function through the formation of formal covalent bonds and pi overlapping interactions in liquid crystal and covalent framework structures through low temperature reactions. The overlying benefit from this approach is to lower the cost of manufacturing superior performing devices. This is especially important for solar PV manufacturing where the Levelized Cost of Energy (LCOE) must decline for solar power to approach parity with other sources of electrical energy.

Also disclosed herein is a method of applying passivated Group IVA semiconductor particles suspended with an electrically conductive fluid. The semiconductor particles and the constituents of the liquid crystal or electrically conducting fluid or framework may be suspended in a high-K dielectric solvent to form a liquid ink with the appropriate viscosity suitable for the method of application. For jet printing, viscosities in the range of 10 centipoise (cp) to 30 cp may be suitable, while for gravure printing may require viscosities over 100 cp. High K solvents are used to promote the dispersion of nanoparticles and prevent particle agglomeration. Films may require a period of curing to allow the alignment and or self assembly of the fluid matrix or structural units of the framework and to establish electrical communication with the semiconductor particles. The curing process may involve complete or partial evaporation of one or more components of solvent used in making the inks.

Solvents used in making submicron semiconductor inks may include, but are not limited to, N-methyl pyrrolidinone (NMP), dimethylsulfoxide (DMSO), tetrahydrofuran (THF), nitromethane, hexamethylphosphoramide (HMPA), dimethylforamide (DMF), and sulfalone. Many organic-based compounds are available that form columnar discotic liquid crystals. Examples of these include a class of compounds derived from triphenylene-base compounds that align with each other in stacked columns by hydrogen bonding. Similarly, other symmetric and asymmetric polyaromatic hydrocarbons with planar pi systems and ring substituents that participate in their alignment into stack columns may be used for a discotic liquid crystal matrix. Porphyrin based compounds may be used to form stacked arrays that can be classified with liquid crystals, or with appropriate functional groups may form covalent organic frameworks that allow high charge mobility in their frameworks. Some combination of one or more of the above solvents and organic-based liquid crystal or conductive framework structural units may be used for the semiconductor film matrixes.

c. Pollutant Capture

The functionalized Group IVA particles, as well as functionalized and non-functionalized transition metals (e.g., copper), may be useful in the capture of pollutants, and in particular, pollutants from combustion processes. Emission of mercury, for example, from combustion gas sources such as coal-fired and oil-fired boilers has become a major environmental concern. Mercury (Hg) is a potent neurotoxin that can affect human health at very low concentrations. The largest source of mercury emission in the United States is coal-fired electric power plants. Coal-fired power plants account for between one-third and one-half of total mercury emissions in the United States. Mercury is found predominantly in the vapor-phase in coal-fired boiler flue gas. Mercury can also be bound to fly ash in the flue gas.

Mercury and other pollutants can be captured and removed from a flue gas stream by injection of a sorbent into the exhaust stream with subsequent collection in a particulate matter control device such as an electrostatic precipitator or a fabric filter. Adsorptive capture of Hg from flue gas is a complex process that involves many variables. These variables include the temperature and composition of the flue gas, the concentration and speciation of Hg in the exhaust stream, residence time, and the physical and chemical characteristics of the sorbent.

Currently, the most commonly used method for mercury emission reduction is the injection of powdered activated carbon (PAC) into the flue stream of coal-fired and oil-fired plants. However, despite available technologies, there is an ongoing need to provide improved pollution control sorbents and methods for their manufacture.

Aspects of the invention include compositions, methods of manufacture, and systems and methods for removal of heavy metals and other pollutants from gas streams. In particular, the compositions and systems are useful for, but not limited to, the removal of mercury from flue gas streams generated by the combustion of coal. One aspect of the present invention relates to a sorbent comprising a Group IVA functionalized particle as described herein, and/or a functionalized or non-functionalized transition metal (e.g., copper).

In certain embodiments, a method of removing pollutants (e.g., mercury) from a combustion flue gas stream includes injecting into the flue gas stream a sorbent comprising a functionalized Group IVA particle as described herein, and/or a functionalized or non-functionalized transition metal (e.g., copper). The sorbent can be used and maintain functionality under a variety of conditions, including conditions typical of flue gas streams found in combustion processes. In certain embodiments, the sorbent can be provided into a flue gas or process having a temperature of 200° F. to 2100° F., or 400° F. to 1100° F. In certain embodiments, the sorbent can be provided into a flue gas or process having a temperature of 50° F. or greater, 100° F. or greater, 200° F. or greater, 300° F. or greater, 400° F. or greater, 500° F. or greater, 600° F. or greater, 700° F. or greater, 800° F. or greater, 900° F. or greater, 1000° F. or greater, 1100° F. or greater, 1200° F. or greater, 1300° F. or greater, 1400° F. or greater, 1500° F. or greater, 1600° F. or greater, 1700° F. or greater, 1800° F. or greater, 1900° F. or greater, 2000° F. or greater, or 2100° F. or greater. Optionally, the injected sorbent may be collected downstream of the injection point in a solids collection device. Optionally, the injected sorbent can be recycled for repeat use.

In certain embodiments, the Group IVA particles described herein, and/or functionalized or non-functionalized transition metals (e.g., copper), can be used to provide improved capture of mercury at electrostatic precipitators (ESPs). The majority of coal plants now have electrostatic precipitators. The Group IVA particles described herein, and/or functionalized or non-functionalized transition metals (e.g., copper), may be introduced into a scrubbing process before, after, or on the ESP highly charged plates. The captured mercury may then stay on the plates or fall into the fly ash as oxidized. Given the transfer of the energy, hydroxyl radicals may be formed and oxidation of the Hg occurs. In particular, the Group IV particles described herein, and/or functionalized or non-functionalized transition metals (e.g., copper), can be used as photo sensitizers for mercury removal. The photo sensitizers can be combined with activated carbon to remove Hg.

d. Other Applications

Other applications for functionalized Group IVA particles include biosensors, thermoelectric films, and other semiconductor devices.

### 7. Examples

The foregoing may be better understood by reference to the following examples, which are presented for purposes of illustration and are not intended to limit the scope of the invention.

General Experimental Methods:

Reagents and solvents were obtained commercially and distilled prior to use. [Distillation was accomplished by heating the solvents in a glass distillation apparatus under nitrogen or argon with sodium metal immediately prior to use.]

Abbreviations used herein are as follows: 2,3-DHN: 2,3-dihydroxynaphthalene; 2,3-DHA: 2,3-dihydroxyanthracene; MWCNT: multi-walled carbon nanotube; SWCNT: single wall carbon nanotube; CCA: conducting carbon additive; P3HT: poly(3-hexylthiophene-2,5-diyl); nSi: nano silicon particles.

### Example 1. Preparation of Nano-Sized Si Powder from P-Doped Si

A sample of micron-sized particles from P-doped Si wafers was milled in benzene, followed by solvent removal to produce a nano-sized Si powder (nSi).

### Example 2. Preparation of Nano-Sized Si Powder from B-Doped Si

A sample of micron-sized particles from B-doped Si wafers was milled in benzene, followed by solvent removal to produce a nano-sized Si powder (nSi).

### Example 3. Preparation of Nano-Sized Si Powder from Metallurgical Si

A sample of micron-sized particles of metallurgical Si was milled in benzene, followed by solvent removal to produce a nano-sized Si powder (nSi).

### Example 4. Preparation of 2,3-DHN Modified Nano-Sized Si Powder

A sample of nSi prepared as described in Example 1 was heated in polyether in the presence of 2,3-DHN to produce nSi with surfaces modified by 2,3-DHN.

### Example 5. Preparation of 2,3-DHA Modified Nano-Sized Si Powder

A sample of nSi prepared as described in Example 1 was heated in polyether in the presence of 2,3-DHA to produce nSi with surfaces modified by 2,3-DHA.

### Example 6. Preparation of 2,3-DHN Modified Nano-Sized Si Powder

A sample of micron-sized particles from P-doped Si wafers was milled in benzene in the presence of 2,3-DHN, followed by solvent removal to produce nSi powder with surfaces modified by 2,3-DHN.

### Example 7. Preparation of C₆₀/C₇₀ Modified Nano-Sized Si Powder

A sample of micron-sized particles from P-doped Si wafers was milled in benzene in the presence of C₆₀/C₇₀ fullerene extract, followed by solvent removal to produce a nano-sized surface-modified Si powder.

### Example 8. Fabrication of an nSi Battery

Preparation of Anode Paste:

The nSi powder prepared as described in Example 4 was used as anode material (AM) and 9%, by weight, C₆₀ fullerene was used as conducting carbon additive (CCA). The solids were mixed. To the solid mixture approximately 3 ml of dichloromethane was added, and the mixture was sonicated for 10 min. The mixture was then dried to a powder with a dry air purge at room temperature.

Formation of Anode:

1,2,3-Trichloropropane was added to the dried solid such that a solids-loading of approximately 8.5% was achieved [% weight of the solids in the slurry] The mixture was sonicated using a Biologics probe sonicator at 40% power until a smooth suspension was formed. The suspension was spread on carbon coated copper foil with a doctor blade (from “ductor blade”, it is a metal or ceramic blade positioned with a predetermined gap just above the substrate, then moved across the substrate with a mass of ink in front of it, effectively spreading the ink on the substrate at some predictable thickness). The film was dried on the spreader at 90° C. for 30 min. From the dried film 16 mm anode discs were punched out.

Fabrication of Battery:

The anode discs were dried in a vacuum oven at 100° C. under dynamic vacuum for 1 h. Each battery was assembled and sealed under an atmosphere of nitrogen in a glovebox using the anode disc and a 19 mm LiCoO₂ disc on aluminum substrate as the cathode. The electrodes were separated with a 20 mm diameter Celgard disc and the components assembled in a 2032 coin-cell stainless steel housing filled with electrolyte composed of 1M LiPF₆ dissolved in a blend of organic carbonate solvents with vinylene carbonate additive. A spacer and wave spring was placed on top of the anode side of the cell before crimping and hermetically sealing each coin cell battery.

Charging/Discharging Cycle Tests:

The batteries were charged and discharged between 3.00 and 3.85 V at a constant current of 0.02 mA. The specific discharge capacity was 769 mAh/g (after 1^{st} cycle).

### Example 9. Fabrication of an nSi Battery

The procedure of Example 8 was modified to use 18% C₆₀, by weight. The specific discharge capacity of the resulting battery was measured as 349 mAh/g.

### Example 10. Fabrication of an nSi Battery

The procedure of Example 8 was modified to replace carbon coated copper foil with uncoated copper foil. The specific discharge capacity of the resulting battery was measured as 697 mAh/g.

### Example 11. Fabrication of an nSi Battery

The procedure of Example 8 was modified to replace 9% C₆₀, by weight, with 9% nanospherical carbon, by weight. The specific discharge capacity of the resulting battery was measured as 558 mAh/g.

### Example 12. Fabrication of an nSi Battery

The procedure of Example 8 was modified to also include 9% poly(3-hexylthiophene), by weight. The specific discharge capacity of the resulting battery was measured as 918 mAh/g.

### Example 13. Fabrication of an nSi Battery

The procedure of Example 12 was modified to replace carbon coated copper foil with uncoated copper foil. The specific discharge capacity of the resulting battery was measured as 1020 mAh/g.

### Example 14. Fabrication of an nSi Battery

The procedure of Example 8 was modified to also include 9% polyaniline crosslinked with phytic acid, by weight. The anode film was prepared differently than Example 14 in the following ways: (i) the solvent added to solids was water with a solids loading of ca. 25%, and after sonicating the mixture was stirred on a stir plate for 40 minutes; (ii) the film was not dried on the spreader, it was dried at room temperature for 72 hours; (iii) after the discs were punched out they were dipped in distilled, deionized water and agitated gently five times; and (iv) the discs were then dried at room temperature under dynamic vacuum for 19 hours. The specific discharge capacity was measured as 496 mAh/g.

### Example 15. Fabrication of an nSi Battery

The procedure of Example 8 was modified to replace 9% C₆₀, by weight, with 9% single wall carbon nanotubes, by weight. The specific discharge capacity of the resulting battery was measured as 473 mAh/g.

### Example 16. Fabrication of an nSi Battery

The procedure of Example 8 was modified to eliminate the use of a CCA. The specific discharge capacity of the resulting battery was measured as 548 mAh/g.

### Example 17. Fabrication of an nSi Battery

The procedure of Example 8 was modified to employ the nSi powder prepared in Example 1. The specific discharge capacity of the resulting battery was measured as 454 mAh/g.

### Example 18. Fabrication of an nSi Battery

The procedure of Example 8 was modified to employ the nSi powder prepared in Example 7, and no CCA was added in the post-milling procedure. The specific discharge capacity of the resulting battery was measured as 644 mAh/g.

### Example 19. Fabrication of an nSi Battery

The procedure of Example 8 was modified to employ the nSi powder prepared in Example 7, and no CCA was added in the post-milling procedure. In addition, 9% poly(3-hexylthiophene) (a conductive polymer), by weight, was used in the modified procedure. The specific discharge capacity of the resulting battery was measured as 301 mAh/g.

### Example 20. Fabrication of an nSi Battery

The procedure of Example 8 was modified to employ the nSi powder prepared in Example 7. The procedure was further modified to replace 9% C₆₀, by weight, with 9% single wall carbon nanotubes, by weight. The specific discharge capacity of the resulting battery was measured as 582 mAh/g.

### Example 21. Fabrication of an nSi Battery

The procedure of Example 8 was modified to employ the nSi powder prepared in Example 7, and no CCA was added in the post-milling procedure. The charging/discharging cycle test of the resulting battery was modified to charge at a constant current of 0.03 mA. The specific discharge capacity of the battery was measured as 692 mAh/g.

### Example 22. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 3.90 V. The specific discharge capacity of the battery was measured as 1400 mAh/g.

### Example 23. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 3.90 V at a constant current of 0.03 mA. The specific discharge capacity of the battery was measured as 1600 mAh/g.

### Example 24. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 3.95 V at a constant current of 0.03 mA. The specific discharge capacity of the battery was measured as 2840 mAh/g.

### Example 25. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 3.95 V. The specific discharge capacity of the battery was measured as 1600 mAh/g.

### Example 26. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 4.00 V at a constant current of 0.03 mA. The specific discharge capacity of the battery was measured as 2550 mAh/g.

### Example 27. Fabrication of an nSi Battery

The procedure of Example 8 was modified to employ the nSi powder prepared in Example 7, and no CCA was added in the post-milling procedure. The charging/discharging cycle test of the resulting battery was modified to charge and discharge between 3.00 and 4.00 V. The specific discharge capacity of the battery was measured as 2460 mAh/g.

### Example 28. Preparation of 2,3-DHA Modified Nano-Sized Si Powder

A sample of micron-sized particles from P-doped Si wafers was milled in benzene in the presence of 2,3-DHA, followed by solvent removal to produce nSi powder with surfaces modified by 2,3-DHA.

### Example 29. Preparation of 9,10-phenanthrenequinone Modified Nano-Sized Si Powder

A sample of micron-sized particles from P-doped Si wafers was milled in benzene in the presence of 9,10-phenanthrenequinone, followed by solvent removal to produce nSi powder with surfaces modified by 9,10-phenanthrenequinone.

### Example 30. Preparation of Etched Metallurgical Si Particles

Micron-sized metallurgical Si particles were treated at room temperature with two successive 1-hour washings with agitation in 6.2 M HCl. After each treatment, the acid solution was decanted from the particles followed by a rinse with deionized water (DI). The resulting Si particles were further treated with a 2.5M HF/2.8M NH₃ etching solution for about 10 minutes at room temperature. The etching solution was poured into a filtration device and the particles were washed thoroughly with DI water. The Si particles were then exposed to 2.5 M HF for about 5 minutes, filtered and washed thoroughly with DI water. The Si particles were spun dried then evacuated at 50° C. for several hours.

### Example 31. Preparation of 2,3-DHA Modified Etched Metallurgical Si Particles

A sample of micron-sized Si particles prepared as described in Example 30 was milled in benzene in the presence of 2,3-DHA, followed by solvent removal to produce nSi powder with surfaces modified by 2,3-DHA.

### Example 32. Preparation of C₆₀/C₇₀ Fullerene Modified Etched Metallurgical Si Particles

A sample of micron-sized Si particles prepared as described in Example 30 was milled in benzene in the presence of C₆₀/C₇₀ fullerene extract, followed by solvent removal to produce nSi powder with surfaces modified by C₆₀/C₇₀ fullerene.

### Example 33. Preparation of Graphene Modified Etched Metallurgical Si Particles

A sample of micron-sized Si particles prepared as described in Example 30 was milled in benzene in the presence of grapheme, followed by solvent removal to produce nSi powder with surfaces modified by graphene.

### Example 34. Preparation of Single Wall Carbon Nanotube Modified Etched Metallurgical Si Particles

A sample of micron-sized Si particles prepared as described in Example 30 was milled in benzene in the presence of single wall carbon nanotubes, followed by solvent removal to produce nSi powder with surfaces modified by single wall carbon nanotubes.

### Example 35. Preparation of Multi-Wall Carbon Nanotube Modified Etched Metallurgical Si Particles

A sample of micron-sized Si particles prepared as described in Example 30 was milled in benzene in the presence of multi-wall carbon nanotubes, followed by solvent removal to produce nSi powder with surfaces modified by multi-wall carbon nanotubes.

### Example 36. Preparation of 9,10-phenanthrenequinone Modified Etched Metallurgical Si Particles

A sample of micron-sized Si particles prepared as described in Example 30 was milled in benzene in the presence of 9,10-phenanthrenequinone, followed by solvent removal to produce nSi powder with surfaces modified by 9,10-phenanthrenequinone.

### Example 37. Preparation of 2,3-DHA Modified Etched Metallurgical Si Particles

A sample of micron-sized Si particles prepared as described in Example 30 is milled in benzene in the presence of 2,3-DHA with substituents in the 9 and 10 positions (i.e., 2,3-dihydroxyanthracene 9,10-substituent), followed by solvent removal to produce nSi powder with surfaces modified by 2,3-DHA with substituents in the 9 and 10 positions, the substituents being fluorine or trifluoromethyl.

### Example 38. Preparation of 2,3-dihydroxytetracene Modified Etched Metallurgical Si Particles

A sample of micron-sized Si particles prepared as described in Example 30 was milled in benzene in the presence of 2,3-dihydroxytetracene, followed by solvent removal to produce nSi powder with surfaces modified by 2,3-dihydroxytetracene.

### Example 39. Preparation of 2,3-dihydroxytetracene Modified Etched Metallurgical Si Particles

A sample of micron-sized Si particles prepared as described in Example 30 was milled in benzene in the presence of fluorine or trifluromethyl substituted 2,3-dihydroxytetracene, followed by solvent removal to produce nSi powder with surfaces modified by fluorine or trifluromethyl substituted 2,3-dihydroxytetracene.

### Example 40. Preparation of 2,3-dihydroxypentacene Modified Etched Metallurgical Si Particles

A sample of micron-sized Si particles prepared as described in Example 30 was milled in benzene in the presence of 2,3-dihydroxypentacene, followed by solvent removal to produce nSi powder with surfaces modified by 2,3-dihydroxypentacene.

### Example 41. Preparation of 2,3-dihydroxypentacene Modified Etched Metallurgical Si Particles

A sample of micron-sized Si particles prepared as described in Example 30 was milled in benzene in the presence of fluorine or trifluromethyl substituted 2,3-dihydroxypentacene, followed by solvent removal to produce nSi powder with surfaces modified by fluorine or trifluromethyl substituted 2,3-dihydroxypentacene.

### Example 42. Preparation of Pentacene Modified Etched Metallurgical Si Particles

A sample of micron-sized Si particles prepared as described in Example 30 was milled in benzene in the presence of pentacene, followed by solvent removal to produce nSi powder with surfaces modified by pentacene.

### Example 43. Preparation of Pentacene Modified Etched Metallurgical Si Particles

A sample of micron-sized Si particles prepared as described in Example 30 was milled in benzene in the presence of fluorine or trifluromethyl substituted pentacene, followed by solvent removal to produce nSi powder with surfaces modified by fluorine or trifluromethyl substituted pentacene.

### Example 44. Preparation of 2,3-DHA Modified Etched Metallurgical Si Particles

Micron-sized metallurgical Si particles were treated at room temperature with two successive 1-hour washings with agitation in 6.2 M HCl. After each treatment, the acid solution was decanted from the particles followed by a rinse with deionized water (DI). The resulting Si particles were further treated with a 2.5M HF/2.8M NH₃ etching solution for about 10 minutes at room temperature. The etching solution was poured into a filtration device and the particles were washed thoroughly with DI water. The micron-sized Si particles prepared were milled in benzene in the presence of 2,3-DHA, followed by solvent removal to produce nSi powder with surfaces modified by 2,3-DHA.

### Example 45. Preparation of Surface Modified Etched Metallurgical Si Particles

The procedure described in Example 44 was modified by replacing 2,3-DHA with each of the reagents described in Examples 32-43: C₆₀/C₇₀ fullerene extract, graphene, single wall carbon nanotubes, multi-wall carbon nanotubes, 9,10-phenanthrenequinone, 2,3-DHA with substituents in the 9,10 positions, 2,3-dihydroxytetracene, fluorine or trifluromethyl substituted 2,3-dihydroxytetracene, pentacene, and fluorinated or trifluromethylated pentacene.

### Example 46. Preparation of 2,3-DHA Modified Etched Metallurgical Si Particles

Micron-sized metallurgical Si particles were treated at room temperature with two successive 1-hour washings with agitation in 6.2 M HCl. After each treatment, the acid solution was decanted from the particles followed by a rinse with deionized water. The micron-sized Si particles prepared were milled in benzene in the presence of 2,3-DHA, followed by solvent removal to produce nSi powder with surfaces modified by 2,3-DHA.

### Example 47. Preparation of Surface Modified Etched Metallurgical Si Particles

The procedure described in Example 46 was modified by replacing 2,3-DHA with each of the reagents described in Examples 32-43: C₆₀/C₇₀ fullerene extract, graphene, single wall carbon nanotubes, multi-wall carbon nanotubes, 9,10-phenanthrenequinone, 2,3-DHA with substituents in the 9,10 positions, 2,3-dihydroxytetracene, fluorine or trifluromethyl substituted 2,3-dihydroxytetracene, pentacene, and fluorinated or trifluromethylated pentacene.

### Example 48. Modified Battery Charging/Discharging Cycle Tests

The battery charging/discharging cycle tests as described in Example 8 were modified to employ the use of imide pyrrolidinium electrolytes.

### Example 49. Modified Battery Charging/Discharging Cycle Tests

The battery charging/discharging cycle tests as described in Example 8 were modified to employ the use of perfluoropolyether electrolytes.

### Example 50. Fabrication of an nSi Battery

The battery preparation as described in Example 8 was modified to employ the use of LiFePO₄ as the cathode material.

### Example 51. Fabrication of an nSi Battery

The battery preparation as described in Example 8 was modified to employ the use of LiNMC (LiNi_{1/3Co}⅓Mn_{1/3}O₂) as the cathode material.

### Example 52. Fabrication of an nSi Battery

Micron-sized P-doped silicon particles (0.01-0.02 Ωcm) were milled in benzene in the presence of 5% by wt. C₆₀/C₇₀ fullerene extract pre-dissolved in benzene, followed by evaporation of solvent to produce nSi powder with surfaces modified by C₆₀ and C₇₀. This anode formulation was used to prepare coin cells as described in Example 8 with anode mass of 1.8-2.6 mg. Charging 0.03 mA between 3.9-3.0 V, the initial specific discharge capacity ranged from 662-951 mAh/g. Average specific discharge capacity fade after the first 5 cycles was 11%.

### Example 53. Fabrication of an nSi Battery

To the nSi particles of Example 52 was added P3HT (8% by wt.) and multi-wall carbon nanotubes (8% by wt.) following the procedure of Example 14. The anode mass ranged from 1.1-1.3 mg. Charging 0.03 mA from 3.9-3.0 V, the initial specific discharge capacity ranged between 1350-1720 mAh/g.

### Example 54. Fabrication of an nSi Battery

The procedure in Example 53 was modified to replace pyrene with industrial grade multi-wall carbon nanotubes (1.3% by wt.) and C₆₀/C₇₀ fullerene extract (1.4% by wt.). The anode mass ranged from 1.1-1.3 mg. Charging CC 0.03 mA from 3.9-3.0 V, the initial specific discharge capacity ranged between 1350-1720 mAh/g.

### Example 55. Fabrication of an nSi Battery

Micron-sized Si particles prepared as described in Example 30 were milled in benzene in the presence of pyrene (8.5% by wt.) and C₆₀/C₇₀ fullerene extract (1.7% by wt.) pre-dissolved in benzene, followed by evaporation of the solvent to produce nSi powder with surfaces modified by fullerenes and pyrene. This anode formulation was used to make coin cells as described in Example 8 with anode mass of 0.6-1.1 mg. Charging CC 0.03 mA between 3.9 to 3.0V, the initial specific discharge capacity ranged between 1380-2550 mAh/g. Average specific discharge capacity fade after the first 4 cycles was 14%.

### Example 56. Fabrication of an nSi Battery

Micron-sized particles prepared as described in Example 30 were milled in mesitylene in the presence of pyrene, followed by evaporation of the solvent to produce nSi powder with surfaces modified by pyrene. This anode formulation was used to prepare coin cells as described in Example 8 with anode mass of 0.5-0.7 mg. Charging 0.03 mA between 3.9-3.0 V, the specific discharge capacity ranged from 2360-3000 mAh/g.

### Example 57. Preparation of Mesitylene Modified nSi/Sn Alloy Nanoparticles

Micron-sized particles prepared as described in Example 30 were milled in mesitylene in the presence of added Sn particles (20% by wt.), followed by evaporation of the solvent to produce nSi/Sn alloy nanoparticles with surfaces modified by mesitylene.

### Example 58. Preparation of Mesitylene Modified nSi/Ge Alloy Nanoparticles

Micron-sized particles prepared as described in Example 30 were milled in mesitylene in the presence of added Ge particles (20% by wt.), followed by evaporation of the solvent to produce nSi/Ge alloy nanoparticles with surfaces modified by mesitylene.

### Example 59. Preparation of Mesitylene Modified nSi/Sn/Ni Alloy Nanoparticles

Micron-sized particles prepared as described in Example 30 were milled in mesitylene in the presence of added Sn particles (15% by wt.) and Ni particles (15%), followed by evaporation of the solvent to produce nSi/Sn/Ni alloy nanoparticles with surfaces modified by mesitylene.

### Example 60. Preparation of Mesitylene Modified nSi/Ti/Ni Alloy Nanoparticles

Micron-sized particles prepared as described in Example 30 were milled in mesitylene in the presence of added Ti particles (15% by wt.) and Ni particles (15%), followed by evaporation of the solvent to produce nSi/Ti/Ni alloy nanoparticles with surfaces modified by mesitylene.

### Example 61. Preparation of Mesitylene Modified nSi/Sn Alloy Nanoparticles

Micron-sized particles prepared as described in Example 30 were milled in mesitylene (15% by wt.) in the presence of added Sn particles (20% by wt.), followed by evaporation of the solvent to produce nSi/Sn alloy nanoparticles with surfaces modified by mesitylene.

### Example 62. Preparation of Mesitylene Modified nSi/Sn Alloy Nanoparticles

Micron-sized particles prepared as described in Example 30 were milled with C₆₀/C₇₀ fullerenes extract (5% by wt.) dissolved in mesitylene in the presence of added Sn particles (20% by wt.), followed by evaporation of the solvent to produce nSi/Sn alloy nanoparticles with surfaces modified by C₆₀/C₇₀ fullerenes and mesitylene.

### Example 63. Preparation of Carbonized Conductive Carbon Modified nSi Nanoparticles

Micron-sized Si particles prepared as described in Example 30 were milled in xylenes following evaporation of the solvents to produce nSi particles with surfaces modified by xylenes. Subsequent heating of the particles to 650° C. under an atmosphere of argon with 1% H₂ produced silicon nanoparticles with surfaces surrounded by carbonized conductive carbon.

### Example 64. Fabrication of an nSi Battery

The procedure in Example 14 was modified to employ the use of multi-wall carbon nanotubes (8% by wt.) in addition to P3HT (8% by wt.). Anode mass ranged from 1.1-1.3 mg. Charging CC 0.03 mA from 3.9-3.0 V, the initial specific discharge capacity ranged between 1350-1720 mAh/g

### Example 65. Fabrication of an nSi Battery

The procedure for forming the electrodes in Example 8 was modified to include no additional conductive carbon added to the anode formulation, and the battery components were sized to 57× larger area (114 cm²) cut in a rectangular shape. The components were laid together between rigid glass plates with the positive and negative current collectors wired to the leads of a 0-5V battery analyzer (MTI BST8-MA) [MTI model designation] (0.1-10 mA). Charge/discharge CC 1.0 mA between 3.9 to 3.0 V gave a peak specific discharge capacity of 951 mAh/g on the second discharge cycle. Cycle retention after the first 8 cycles based on the specific discharge capacity of cycle 2 was 96.1%.

### Example 66. Preparation of Nano-Sized Si Powder from Metallurgical Si

A sample of micron-sized particles of metallurgical Si was milled in p-xylene, followed by solvent removal to produce a nano-sized Si powder (nSi) passivated by p-xylene.

### Example 67. Preparation of 2,3-DHN Modified Etched Metallurgical Si Particles

The procedure in Example 31 was modified to employ p-xylene as the comminution solvent instead of benzene and 2,3-DHN was employed to replace 2,3-DHA, and produce nSi particles with surfaces modified by 2,3-DHN.

### Example 68. Fabrication of an nSi Battery

To the nSi particles of Example 52 was added carbon black (60% by wt.) following the procedure of Example 14. The anode mass ranged from 1.3-1.9 mg. Charging CC 0.03 mA from 3.9-3.0 V, the initial specific discharge capacity ranged between 587-968 mAh/g.

### Example 69. Fabrication of an nSi Battery

To the nSi particles of Example 52 was added carbon black (45% by wt.) and P3HT [poly-3-hexylthiophene](15% by wt.) following the procedure of Example 14. The anode mass ranged from 1.0-1.9 mg. Charging CC 0.03 mA from 3.9-3.0 V, the initial specific discharge capacity ranged between 627-1500 mAh/g.

### Example 70. Fabrication of an nSi Battery

To the nSi particles of Example 56 was added carbon black (45% by wt.) and P3HT [poly-3-hexylthiophene] (15% by wt.) following the procedure of Example 14. The anode mass ranged from 0.6-0.9 mg. Charging CC 0.03 mA from 3.9-3.0 V, the initial specific discharge capacity ranged between 1460-2200 mAh/g.

### Example 71. Fabrication of an nSi Battery

Anodes were made as in Example 68 except that dried anodes were calendered with a roller-press. The thickness of the calendered anode film decreased from 14 micron to 4 micron. Anode mass ranged from 1.5-1.8 mg. Charging CC 0.03 mA from 3.9-3.0 V, the initial specific discharge capacity ranged between 846-1002 mAh/g.

### Example 72. Pre-Lithiation of the Negative Electrode

A 16 mm diameter lithium foil disc and a 16 mm diameter negative electrode on copper substrate were positioned together with a 20 mm Celgard separator film between. These discs were soaked in a 1M LiPF₆ electrolyte solution (as described in Example 8) and positioned between stainless steel discs pressed together, submerged in the electrolyte solution and the potential across the stack was monitored. Lithiation was considered complete after the monitored potential dropped to zero. The lithium molar percentage was 30-60% depending on the mass ratio of the lithium foil to silicon nanoparticles.

### Example 73. Pre-Lithiation of the Negative Electrode

Micron-sized Si particles prepared as described in Example 30 were milled in diglyme in the presence of tert-butyllithium followed by addition of mesitylene. Subsequent evaporation of the solvents produced lithiated nSi powder with surfaces modified by mesitylene

### Example 74. Evaluation of Charge/Discharge Cycles of a Si-NP Negative Electrode

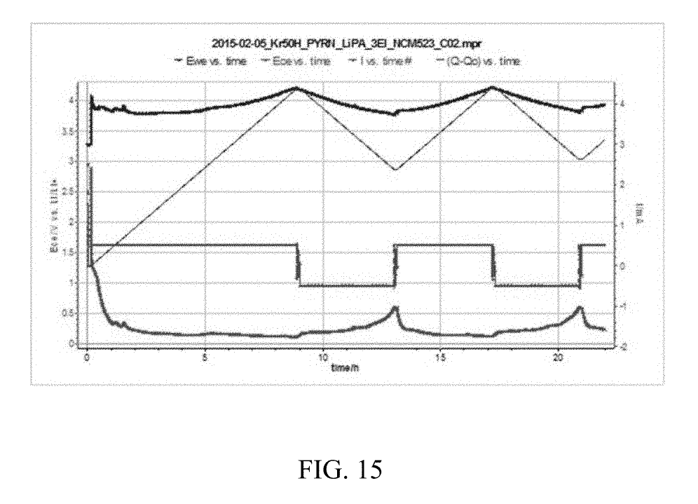

A Si-NP negative electrode composite was prepared by combining the Si-NP solids dispersed in NMP with graphite and carbon black in an aqueous slurry of 15 wt. % Li PA polymer. The negative electrode (counter electrode) was paired with a NCM523 working electrode, with both electrodes referenced to a Li reference electrode. FIG. 15 depicts charge/discharge voltage and current profiles that resulted from the electrochemical evaluations in this study.

### Example 75. Evaluation of Charge/Discharge Cycles of a Si-NP Negative Electrode

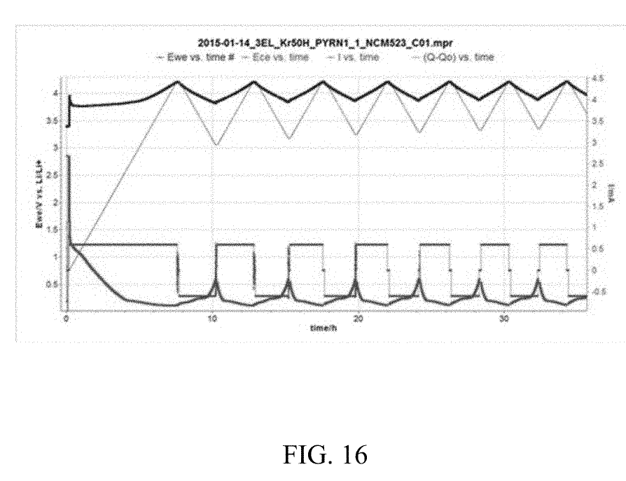

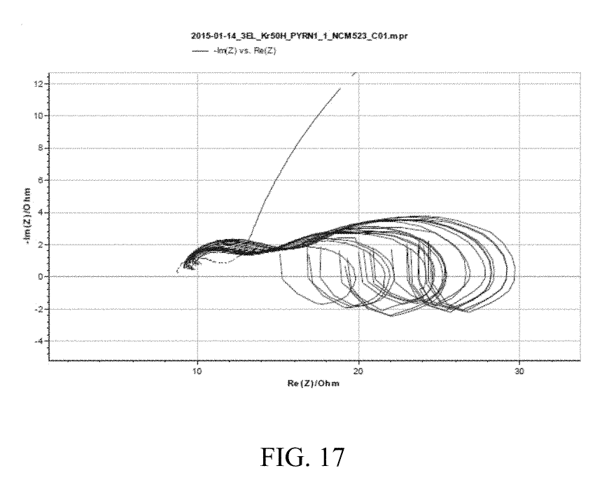

A Si-NP negative electrode composite was prepared by combining graphite and carbon black and the Si-NP in a slurry prepared with a 5 wt. % solution of PVDF in NMP solvent. The negative electrode (counter electrode) was paired with a NCM523 (working) electrode, with both referenced to a Li reference electrode. FIG. 16 depicts charge/discharge voltage and current profiles that resulted from the electrochemical evaluations in this study. FIG. 17 shows the potentiostatic electrochemical impedance profiles measured during charge/discharge cycling.

### 8. Exemplary Embodiments

For reasons of completeness, various aspects of the disclosure are set out in the following numbered clauses:

Clause 1. A functionalized Group IVA particle comprising a surface-modified core material.

Clause 2. The functionalized Group IVA particle of clause 1, wherein the surface of the core material is substantially oxide free.

Clause 3. The functionalized Group IVA particle of clause 1 or clause 2, wherein the particle is a nanoparticle.

Clause 4. The functionalized Group IVA particle of any one of clauses 1-3, wherein the particle has a diameter of 30 nanometers to 150 nanometers.

Clause 5. The functionalized Group IVA particle of any one of clauses 1-4, wherein the particle has an oxide content of lower than 10% of the oxide composition of particles milled aerobically (as judged by XPS).

Clause 6. The functionalized Group IVA particle of any one of clauses 1-5, wherein the particle has a BET surface area of greater than 100 m²/g.

Clause 7. The functionalized Group IVA particle of any one of clauses 1-6, wherein the particle has a BET surface area of greater than 200 m²/g.

Clause 8. The functionalized Group IVA particle of any one of clauses 1-7, wherein the particle has a BET surface area of greater than 300 m²/g.

Clause 9. The functionalized Group IVA particle of any one of clauses 1-8, wherein the core material comprises one or more Group IVA elements independently selected from carbon, silicon, germanium, tin, and lead.

Clause 10. The functionalized Group IVA particle of any one of clauses 1-9, wherein the core material comprises one or more elements used for p-type semiconductor doping.

Clause 11. The functionalized Group IVA particle of any one of clauses 1-10, wherein the core material comprises one or more elements used for p-type semiconductor doping, the elements independently selected from boron, aluminum, and gallium.

Clause 12. The functionalized Group IVA particle of any one of clauses 1-11, wherein the core material comprises one or more elements used for n-type semiconductor doping.

Clause 13. The functionalized Group IVA particle of any one of clauses 1-12, wherein the core material comprises one or more elements used for n-type semiconductor doping, the elements independently selected from nitrogen, phosphorous, arsenic, and antimony.

Clause 14. The functionalized Group IVA particle of any one of clauses 1-13, wherein the core material comprises one or more elements found in metallurgical silicon.

Clause 15. The functionalized Group IVA particle of any one of clauses 1-14, wherein the core material comprises one or more elements found in metallurgical silicon, the elements independently selected from aluminum, calcium, titanium, iron, and copper.

Clause 16. The functionalized Group IVA particle of any one of clauses 1-15, wherein the core material comprises one or more conductive metals.

Clause 17. The functionalized Group IVA particle of any one of clauses 1-16, wherein the core material comprises one or more conductive metals independently selected from aluminum, nickel, iron, copper, molybdenum, zing, silver, and gold.

Clause 18. The functionalized Group IVA particle of any one of clauses 1-17, wherein the core material comprises a crystalline phase.

Clause 19. The functionalized Group IVA particle of any one of clauses 1-18, wherein the core material comprises an amorphous phase.

Clause 20. The functionalized Group IVA particle of any one of clauses 1-19, wherein the core material comprises an amorphous sublithium phase.

Clause 21. The functionalized Group IVA particle of any one of clauses 1-20, wherein the core material comprises a mixed-phase.

Clause 22. The functionalized Group IVA particle of any one of clauses 1-21, wherein the core material comprises a homogenous phase.

Clause 23. The functionalized Group IVA particle of any one of clauses 1-22, wherein the core material comprises a lithium-active phase.

Clause 24. The functionalized Group IVA particle of any one of clauses 1-23, wherein the core material comprises a lithium-non-active phase.

Clause 25. The functionalized Group IVA particle of any one of clauses 1-24, where the core material is surface-modified with one or more electrically conductive surface-modifying chemical entities.

Clause 26. The functionalized Group IVA particle of any one of clauses 1-25, where the core material is surface-modified with one or more surface-modifying chemical entities independently selected from monocyclic aromatic compounds, polycyclic aromatic compounds, polynuclear aromatic compounds, inorganic conductive carbon, fullerenes, carbon nanotubes, graphene, boranes, and electrically conductive polymers.

Clause 27. The functionalized Group IVA particle of any one of clauses 1-26, wherein the core material is surface-modified with one or more chemical entities independently selected from benzene, mesitylene, xylene, unsaturated alkanes, an alcohol, a carboxylic acid, a saccharide, an alkyllithium, a borane, a carborane, an alkene, an alkyne, an aldehyde, a ketone, a carbonic acid, an ester, an amine, an acetamine, an amide, an imide, a pyrrole, a nitrile, an isocyanide, a hydrocarbon substituted with boron, silicon, sulfur, phosphorous, or halogen, 2,3-dihydroxyanthracene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, pentacene, fluorine substituted pentacene, trifluromethyl substituted pentacene, pyrene, a polythiophene, poly(3-hexylthiophene-2,5-diyl), poly(3-hexylthiophene), polyvinylidene fluoride, a polyacrylonitrile, polyaniline crosslinked with phytic acid, and conducting carbon additives.

Clause 28. The functionalized Group IVA particle of any one of clauses 1-27, wherein the core material is surface-modified with one or more conducting carbon additives independently selected from single wall carbon nanotubes, multi-walled carbon nanotubes, C₆₀ fullerenes, C₇₀ fullerenes, graphene, and carbon black.

Clause 29. The functionalized Group IVA particle of any one of clauses 1-28, wherein the core material is surface modified with a metal-organic framework, a covalent-organic framework, or a combination thereof.

Clause 30. A composite comprising a functionalized Group IVA particle of any one of clauses 1-29.

Clause 31. The composite of clause 30, comprising one or more additives.

Clause 32. The composite of clause 30 or clause 31, comprising one or more additives independently selected from polymer binders, electrically conductive carbon materials, metal-organic frameworks (MOF), and covalent-organic frameworks (COF).

Clause 33. The composite of any one of clauses 30-32, comprising one or more polymer binders.

Clause 34. The composite of any one of clauses 30-33, comprising one or more polymer binders independently selected from polythiophenes, polyvinylidene difluoride (PVDF), polyacrylonitrile, and sodium alginate.

Clause 35. The composite of any one of clauses 30-34, comprising one or more electrically conductive carbon materials.

Clause 36. The composite of any one of clauses 30-35, comprising one or more electrically conductive carbon materials independently selected from carbon black, nanospherical carbon, graphene, fullerenes, single-wall carbon nanotubes (SWCNT), and multi-wall carbon nanotubes (MWCNT).

Clause 37. The composite of any one of clauses 30-36, comprising one or more metal-organic frameworks.

Clause 38. The composite of any one of clauses 30-37, comprising one or more covalent-organic frameworks.

Clause 39. A composition comprising the functionalized Group IVA particle of any one of clauses 1-29.

Clause 40. A composition comprising the composite of any one of clauses 30-39.

Clause 41. The composition of clause 39 or clause 40 comprising one or more solvents.

Clause 42. The composition of any one of clauses 39-41, comprising one or more chlorinated solvents.

Clause 43. The composition of any one of clauses 39-42, comprising one or more chlorinated solvents independently selected from methylene chloride, 1,2-dichloromethane, and 1,2,3-trichloropropane.

Clause 44. The composition of any one of clauses 39-43, comprising one or more additives.

Clause 45. The composition of any one of clauses 39-44, comprising one or more additives independently selected from polymer binders, electrically conductive carbon materials, metal-organic frameworks (MOF), and covalent-organic frameworks (COF).

Clause 46. The composition of any one of clauses 39-45, comprising one or more polymer binders.

Clause 47. The composition of any one of clauses 39-46, comprising one or more polymer binders independently selected from polythiophenes, polyvinylidene difluoride (PVDF), polyacrylonitrile, and sodium alginate.

Clause 48. The composition of any one of clauses 39-47, comprising one or more electrically conductive carbon materials.

Clause 49. The composition of any one of clauses 39-48, comprising one or more electrically conductive carbon materials independently selected from carbon black, nanospherical carbon, graphene, fullerenes, single-wall carbon nanotubes (SWCNT), and multi-wall carbon nanotubes (MWCNT).

Clause 50. The composition of any one of clauses 39-49, comprising one or more metal-organic frameworks.

Clause 51. The composition of any one of clauses 39-50, comprising one or more covalent-organic frameworks.

Clause 52. The composition of any one of clauses 39-51, wherein the composition is a suspension.

Clause 53. The composition of any one of clauses 39-52, wherein the composition is an anode paste.

Clause 54. The composition of any one of clauses 39-53, wherein the composition is an ink.

Clause 55. The composition of any one of clauses 39-54, wherein the composition is anaerobic, anhydrous, or a combination thereof.

Clause 56. The composition of any one of clauses 39-55, comprising one or more lithium salts.

Clause 57. The composition of any one of clauses 39-56, comprising Li⁺R₃NB₁₂H₁₁⁻, Li₊R₃NB₁₂F₁₁⁻, (H₃N)₂B₁₂H₁₀, (H₃N)₂B₁₂F₁₀, LiAl(OR_{F})₄, or any combination thereof, wherein R₃ at each occurrence is independently selected from methyl, ethyl, and butyl, and R_{F} at each occurrence is independently selected from fluoroalkyl.

Clause 58. The composition of any one of clauses 39-57, Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

Clause 59. The composition of any one of clauses 39-58, wherein the composition is in contact with a current collector.

Clause 60. The composition of any one of clauses 39-59, wherein the composition is in contact with a current collector under an inert atmosphere.

Clause 61. An electrode film comprising the functionalized Group IVA particle of any one of clauses 1-29.

Clause 62. An electrode film comprising the composite of any one of clauses 30-38.

Clause 63. An electrode film comprising the composition of any one of clauses 39-60.

Clause 64. The electrode film of any one of clauses 61-63, having a thickness of 1 micron or greater, 5 microns or greater, or 10 microns or greater.

Clause 65. The electrode film of any one of clauses 61-63, having a thickness of 40 microns or less, 20 microns or less, or 10 microns or less.

Clause 66. The electrode film of any one of clauses 61-65, part of a 2032 coin cell having a 16 mm anode; a 19 mm cathode, and a 20 mm separator film.

Clause 67. An anode comprising the electrode film of any one of clauses 61-66.

Clause 68. An anode comprising the electrode film of any one of clauses 61-66, wherein the anode is prepared by calendaring anode sheets or anode disks.

Clause 69. The anode of clause 67 or clause 68, wherein the anode comprises stable SEI dendrites.

Clause 70. A lithium ion battery comprising: a positive electrode; a negative electrode comprising a functionalized Group IVA particle according to any one of clauses 1-29; a lithium ion permeable separator between the positive electrode and the negative electrode; and an electrolyte comprising lithium ions.

Clause 71. A lithium ion battery comprising: a positive electrode; a negative electrode comprising a composite according to any one of clauses 30-38; a lithium ion permeable separator between the positive electrode and the negative electrode; and an electrolyte comprising lithium ions.

Clause 72. A lithium ion battery comprising: a positive electrode; a negative electrode comprising a composition according to any one of clauses 39-60; a lithium ion permeable separator between the positive electrode and the negative electrode; and an electrolyte comprising lithium ions.

Clause 73. A lithium ion battery comprising: a positive electrode comprising one or more metal oxide compounds able to accommodate and transport lithium ions; a negative electrode comprising a Group IVA functionalized particle according to any one of clauses 1-29, a composite according to any one of clauses 30-38, or a composition according to any one of clauses 39-60; an electrically insulating separator film that is permeable to electrolyte ions and solvents, the separator film being disposed between the positive and negative electrodes; and a non-aqueous electrolyte system.

Clause 74. The lithium ion battery of any one of clauses 70-73, comprising a solvent that is a mixture of at least ethylene and propylene carbonates.

Clause 75. The lithium ion battery of any one of clauses 70-74, having a fade, over 20 cycles, of 5% or less, 4% or less, 3% or less, 2% or less, or 1% or less.

Clause 76. The lithium ion battery of any one of clauses 70-75, having a fade, over 25 cycles, of 5% or less, 4% or less, 3% or less, 2% or less, or 1% or less.

Clause 77. The lithium ion battery of any one of clauses 70-76, having a fade, over 30 cycles, of 5% or less, 4% or less, 3% or less, 2% or less, or 1% or less.

Clause 78. The lithium ion battery of any one of clauses 70-77, having a fade, over 35 cycles, of 5% or less, 4% or less, 3% or less, 2% or less, or 1% or less.

Clause 79. The lithium ion battery of any one of clauses 70-78, having a fade, over 40 cycles, of 5% or less, 4% or less, 3% or less, 2% or less, or 1% or less.

Clause 80. The lithium ion battery of any one of clauses 70-79, having a fade, over 45 cycles, of 5% or less, 4% or less, 3% or less, 2% or less, or 1% or less.

Clause 81. The lithium ion battery of any one of clauses 70-80, having a fade, over 50 cycles, of 5% or less, 4% or less, 3% or less, 2% or less, or 1% or less.

Clause 82. The lithium ion battery of any one of clauses 70-81, having a capacity of 2,000 milliamp-hours per gram or greater

Clause 83. The lithium ion battery of any one of clauses 70-82, having a capacity of 2,500 milliamp-hours per gram or greater.

Clause 84. The lithium ion battery of any one of clauses 70-83, having a capacity of 3,000 milliamp-hours per gram or greater.

Clause 85. The lithium ion battery of any one of clauses 70-84, having a charging rate of 0.03 milliamp or greater.

Clause 86. The lithium ion battery of any one of clauses 70-85, having a charging rate of 0.04 milliamp or greater.

Clause 87. The lithium ion battery of any one of clauses 70-86, having a charging rate of 0.05 milliamp or greater.

Clause 88. The lithium ion battery of any one of clauses 70-87, having a charging rate of 0.06 milliamp or greater.

Clause 89. The lithium ion battery of any one of clauses 70-88, wherein the negative electrode comprises a stable SEI layer.

Clause 90. The lithium ion battery of any one of clauses 70-89, wherein the electrolyte comprises one or more of monofluoroethylene carbonate, Li⁺R₃NB₁₂H₁₁⁻, Li⁺R₃NB₁₂F₁₁⁻, (H₃N)₂B₁₂H₁₀, (H₃N)₂B₁₂F₁₀, LiAl(OR_{F})₄, or any combination thereof, wherein R₃ at each occurrence is independently selected from methyl, ethyl, and butyl, and R_{F} at each occurrence is independently selected from fluoroalkyl.

Clause 91. The lithium ion battery of any one of clauses 70-90, wherein the electrolyte comprises one or more of monofluoroethylene carbonate, Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

Clause 92. The lithium ion battery of any one of clauses 70-91, wherein the negative electrode comprises an anode sheet.

Clause 93. The lithium ion battery of any one of clauses 70-92, wherein the negative electrode comprises an anode disk.

Clause 94. The lithium ion battery of any one of clauses 70-93, wherein the negative electrode comprises an anode prepared by calendaring prior to battery assembly.

Clause 95. The lithium ion battery of any one of clauses 70-94, wherein the negative electrode comprises an anode that has been prelithiated.

Clause 96. The lithium ion battery of any one of clauses 70-95, wherein the negative electrode comprises an anode that has been previously soaked in one or more of Li⁺R₃NB₁₂H₁₁⁻, Li⁺R₃NB₁₂F₁₁⁻, (H₃N)₂B₁₂H₁₀, (H₃N)₂B₁₂F₁₀, LiAl(OR_{F})₄, or any combination thereof, wherein R₃ at each occurrence is independently selected from methyl, ethyl, and butyl, and R_{F} at each occurrence is independently selected from fluoroalkyl.

Clause 97. The lithium ion battery of any one of clauses 70-96, wherein the negative electrode comprises an anode that has been previously soaked in one or more of monofluoroethylene carbonate, Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

Clause 98. A milling mixture comprising: one or more micrometer-sized Group IVA particles, one or more nanometer-sized Group IVA particles, or a combination thereof; one or more surface-modifiers; and optionally one or more solvents.

Clause 99. The milling mixture of clause 98, wherein the one or more solvents are non-competing solvents.

Clause 100. The milling mixture of clause 98 or clause 99, wherein the one or more solvents are independently selected from polyether, petroleum ether, unsaturated alkane, benzene, xylenes, and mesitylene.

Clause 101. The milling mixture of any one of clauses 98-100, wherein at least one of the one or more solvents prevent or reduce sedimentation or colloid formation of the particles in the milling mixture.

Clause 102. The milling mixture of any one of clauses 98-101, wherein at least one of the one or more solvents prevent or reduce sedimentation or colloid formation of the particles in the milling mixture, wherein the solvent that prevents or reduces sedimentation is diglyme, triglyme, or a combination thereof.

Clause 103. The milling mixture of any one of clauses 98-102, comprising silicon, tin, germanium, or a combination thereof.

Clause 104. The milling mixture of any one of clauses 98-103, comprising one or more conductive metals.

Clause 105. The milling mixture of any one of clauses 98-104, comprising one or more metals independently selected from Al, Ti, V, Cr, Mn, Fe, Co, Cu, Ni, and Co.

Clause 106. The milling mixture of any one of clauses 98-105, comprising one or more lithium-containing reagents.

Clause 107. The milling mixture of any one of clauses 98-106, comprising one or more lithium-containing reagents independently selected from alkyllithium reagents and lithium salts.

Clause 108. The milling mixture of any one of clauses 98-107, comprising butyllithium.

Clause 109. The milling mixture of any one of clauses 98-108, comprising one or more additives.

Clause 110. The milling mixture of any one of clauses 98-109, comprising one or more additives independently selected from polymer binders, electrically conductive carbon materials, metal-organic frameworks (MOF), and covalent-organic frameworks (COF).

Clause 111. The milling mixture of any one of clauses 98-110, comprising one or more polymer binders.

Clause 112. The milling mixture of any one of clauses 98-111, comprising one or more polymer binders independently selected from polythiophenes, polyvinylidene difluoride (PVDF), polyacrylonitrile, and sodium alginate.

Clause 113. The milling mixture of any one of clauses 98-112, comprising one or more electrically conductive carbon materials.

Clause 114. The milling mixture of any one of clauses 98-113, comprising one or more electrically conductive carbon materials independently selected from carbon black, nanospherical carbon, graphene, fullerenes, single-wall carbon nanotubes (SWCNT), and multi-wall carbon nanotubes (MWCNT).

Clause 115. The milling mixture of any one of clauses 98-114, comprising one or more metal-organic frameworks.

Clause 116. The milling mixture of any one of clauses 98-115, comprising one or more covalent-organic frameworks.

Clause 117. The milling mixture of any one of clauses 98-116, wherein the milling mixture is under inert atmosphere.

Clause 118. The milling mixture of any one of clauses 98-117, wherein the milling mixture is substantially free of oxygen.

Clause 119. The milling mixture of any one of clauses 98-118, wherein the milling mixture has an oxygen concentration configured to provide functionalized Group IVA particles with less than 10% of oxides when milled in aerobic conditions.

Clause 120. The milling mixture of any one of clauses 98-119, wherein the milling mixture is substantially free of water.

Clause 121. The milling mixture of any one of clauses 98-120, wherein the milling mixture has a water content of less than 1 ppm.

Clause 122. The milling mixture of any one of clauses 98-121, comprising milling beads having a diameter of 0.05 mm to 0.6 mm.

Clause 123. The milling mixture of any one of clauses 98-122, comprising milling beads having a diameter of 0.3 mm to 0.4 mm.

Clause 124. A method of forming a surface-modified Group IVA nanoparticle, comprising milling micrometer-sized Group IVA-containing materials under anaerobic conditions in the presence of one or more surface-modifying agents.

Clause 125. A method of preparing an amorphous- or mixed-phase surface-modified Group IVA nanoparticle, comprising milling micrometer-sized Group IVA-containing materials under anaerobic conditions in the presence of one or more surface-modifying agents.

Clause 126. A method of preparing a surface-modified Group IVA nanoparticle, comprising treating micrometer-sized Group IVA-containing materials with a protic acid to provide hydrogen-passivated Group IVA particles; and milling the hydrogen passivated Group IVA particles in the presence of a surface-modifier under anaerobic conditions to provide Group IVA particles passivated with a non-dielectric layer over at least a portion of a surface of the Group IVA particles.

Clause 127. The method clause 126, wherein the protic acid is nitric acid, hydrochloric acid, hydrofluoric acid, hydrobromic acid, or any combination thereof.

Clause 128. The method of clause any one of clauses 124-127, wherein the method is non-thermal.

Clause 129. The method of clause any one of clauses 124-128, wherein the anaerobic conditions are defined as an O₂ content of less than 1 ppm and an H₂O content of less than 1 ppm.

Clause 130. The method of any one of clauses 124-129, wherein the milling is performed with a tip speed of greater than 10 meters/second.

Clause 131. The method of any one of clauses 124-130, wherein the milling is performed with a tip speed of 10 meters/second to 16 meters per second.

Clause 132. The method of any one of clauses 124-131, wherein the milling is performed with a tip speed of 10 meters/second to 12.6 meters/second.

Clause 133. The method of any one of clauses 124-132, wherein the mill comprises beads having a diameter of 0.05 mm to 0.6 mm.

Clause 134. The method of any one of clauses 124-133, wherein the mill comprises beads having a diameter of 0.3 mm to 0.4 mm.

Clause 135. The method of any one of clauses 124-134, wherein the milling time is about 1 hour to about 6 hours.

Clause 136. The method of any one of clauses 124-135, wherein the surface-modified Group IVA nanoparticle is substantially oxide free at the particle surface.

Clause 137. The method of any one of clauses 124-136, wherein the particle has an oxide content of less than 10% of oxides, as determined by XPS, in particles when milled in non-rigorous anaerobic conditions.

Clause 138. The method of any one of clauses 124-137, wherein the particle has a diameter or length of 30 nanometers to 150 nanometers.

Clause 139. The method of any one of clauses 124-138, wherein the surface-modified Group IVA nanoparticle has a core material comprising one or more Group IVA elements independently selected from carbon, silicon, germanium, tin, and lead.

Clause 140. The method of any one of clauses 124-139, wherein the surface-modified Group IVA nanoparticle has a core material comprising one or more elements used for p-type semiconductor doping.

Clause 141. The method of any one of clauses 124-140, wherein the surface-modified Group IVA nanoparticle has a core material comprising one or more elements used for p-type semiconductor doping, the elements independently selected from boron, aluminum, and gallium.

Clause 142. The method of any one of clauses 124-141, wherein the surface-modified Group IVA nanoparticle has a core material comprising one or more elements used for n-type semiconductor doping.

Clause 143. The method of any one of clauses 124-142, wherein the surface-modified Group IVA nanoparticle has a core material comprising one or more elements used for n-type semiconductor doping, the elements independently selected from nitrogen, phosphorous, arsenic, and antimony.

Clause 144. The method of any one of clauses 124-143, wherein the surface-modified Group IVA nanoparticle has a core material comprising one or more elements found in metallurgical silicon.

Clause 145. The method of any one of clauses 124-144, wherein the surface-modified Group IVA nanoparticle has a core material comprising one or more elements found in metallurgical silicon, the elements independently selected from aluminum, calcium, titanium, iron, and copper.

Clause 146. The method of any one of clauses 124-145, wherein the surface-modified Group IVA nanoparticle has a core material comprising a crystalline phase.

Clause 147. The method of any one of clauses 124-146, wherein the surface-modified Group IVA nanoparticle has a core material comprising an amorphous phase.

Clause 148. The method of any one of clauses 124-147, wherein the surface-modified Group IVA nanoparticle has a core material comprising an amorphous sublithium phase.

Clause 149. The method of any one of clauses 124-148, wherein the surface-modified Group IVA nanoparticle has a core material comprising a mixed-phase.

Clause 150. The method of any one of clauses 124-149, wherein the surface-modified Group IVA nanoparticle has a core material comprising a homogenous phase.

Clause 151. The method of any one of clauses 124-150, wherein the surface-modified Group IVA nanoparticle has a core material comprising a lithium-active phase.

Clause 152. The method of any one of clauses 124-151, wherein the surface-modified Group IVA nanoparticle has a core material comprising a lithium-non-active phase.

Clause 153. The method of any one of clauses 124-152, wherein the surface-modified Group IVA nanoparticle has a core material comprising one or more conductive metals.

Clause 154. The method of any one of clauses 124-153, wherein the surface-modified Group IVA nanoparticle has a core material comprising one or more conductive metals independently selected from aluminum, nickel, iron, copper, molybdenum, zinc, silver, and gold.

Clause 155. The method of any one of clauses 124-154, wherein the surface-modified Group IVA nanoparticle has a core material that is surface-modified with one or more electrically conductive surface-modifying chemical entities.

Clause 156. The method of any one of clauses 124-155, wherein the surface-modified Group IVA nanoparticle has a core material that is surface-modified with one or more surface-modifying chemical entities independently selected from monocyclic aromatic compounds, polycyclic aromatic compounds, polynuclear aromatic compounds, inorganic conductive carbon, fullerenes, carbon nanotubes, graphene, boranes, and electrically conductive polymers, or any combination thereof.

Clause 157. The method of any one of clauses 124-156, wherein the surface-modified Group IVA nanoparticle has a core material that is surface-modified with one or more chemical entities independently selected from benzene, mesitylene, xylene, unsaturated alkanes, an alcohol, a carboxylic acid, a saccharide, an alkyllithium, a borane, a carborane, an alkene, an alkyne, an aldehyde, a ketone, a carbonic acid, an ester, an amine, an acetamine, an amide, an imide, a pyrrole, a nitrile, an isocyanide, a hydrocarbon substituted with boron, silicon, sulfur, phosphorous, or halogen, 2,3-dihydroxyanthracene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, pentacene, fluorine substituted pentacene, trifluromethyl substituted pentacene, pyrene, a polythiophene, poly(3-hexylthiophene-2,5-diyl), poly(3-hexylthiophene), polyvinylidene fluoride, a polyacrylonitrile, polyaniline crosslinked with phytic acid, and conducting carbon additives.

Clause 158. The method of any one of clauses 124-157, wherein the surface-modified Group IVA nanoparticle has a core material that is surface-modified with one or more conducting carbon additives independently selected from single wall carbon nanotubes, multi-walled carbon nanotubes, C₆₀ fullerenes, C₇₀ fullerenes, graphene, and carbon black.

Clause 159. The method of any one of clauses 124-158, wherein the surface-modified Group IVA nanoparticle has a core material that is surface modified with a metal-organic framework, a covalent-organic framework, or a combination thereof.

Clause 160. The method of any one of clauses 124-159, wherein the micrometer-sized Group IVA-containing materials are derived from metallurgical grade silicon.

Clause 161. The method of any one of clauses 124-160, wherein the micrometer-sized Group IVA-containing materials are derived from a p-type silicon wafer.

Clause 162. The method of any one of clauses 124-161, wherein the micrometer-sized Group IVA-containing materials are derived from a p-type silicon wafer having a measured resistivity of 0.001-100 ohm/cm².

Clause 163. The method of any one of clauses 124-162, wherein the micrometer-sized Group IVA-containing materials are derived from n-type silicon wafer.

Clause 164. The method of any one of clauses 124-163, wherein the micrometer-sized Group IVA-containing materials are derived from a bulk MG Group IVA ingot material.

Clause 165. The method of any one of clauses 124-164, wherein prior micrometer-sized Group IVA-containing materials are prepared by crushing, grinding, milling, or a combination thereof, an ingot or wafer material comprising a Group IVA element.

Clause 166. A method of preparing an anode comprising: providing a dispersion comprising the functionalized Group IVA particle of any one of clauses 1-29, a composite according to any one of clauses 30-38, or a composition according to any one of clauses 39-60; and applying the dispersion as a film on a current collector to provide an anode film.

Clause 167. The method of clause 166, where the dispersion is applied to the current collector under an inert atmosphere.

Clause 168. The method of clause 166 or 167, wherein the dispersion comprises one or more solvents.

Clause 169. The method of any one of clauses 166-168, wherein the dispersion comprises one or more solvents that substantially evaporate after application of the film to provide the anode film.

Clause 170. The method of any one of clauses 166-169, wherein the dispersion comprises one or more solvents selected from dichloromethane, 1,2-dichloroethane, 1,2,3-trichloropropane, or any combination thereof.

Clause 171. The method of any one of clauses 166-170, wherein the dispersion is applied with a doctor blade, an air brush, an ink jet printer, by gravure printing, by screen printing, or any combination thereof.

Clause 172. The method of any one of clauses 166-171, further comprising drying the anode film.

Clause 173. The method of any one of clauses 166-172, further comprising calendaring the anode film.

Clause 174. The method of any one of clauses 166-173, further comprising calendaring the anode film to provide anode disks or anode sheets.

Clause 175. The method of any one of clauses 166-174, further comprising pre-lithiating the anode.

Clause 176. The method of any one of clauses 166-175, further comprising pre-lithiating the anode by soaking in a solution comprising one or more lithium salts.

Clause 177. The method of any one of clauses 166-176, further comprising pre-lithiating the anode by soaking in a solution comprising one or more lithium salts selected from Li⁺R₃NB₁₂H₁₁⁻, Li⁺R₃NB₁₂F₁₁⁻, (H₃N)₂B₁₂H₁₀, (H₃N)₂B₁₂F₁₀, LiAl(OR_{F})₄, or any combination thereof, wherein R₃ at each occurrence is independently selected from methyl, ethyl, and butyl, and R_{F} at each occurrence is independently selected from fluoroalkyl.

Clause 178. The method of any one of clauses 166-177, further comprising pre-lithiating the anode by soaking in a solution comprising one or more lithium salts selected from Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

Clause 179. The method of any one of clauses 166-178, further comprising pre-lithiating the anode by assembling the anode in an electrochemical cell with a lithium foil counter electrode separated by an electrically insulating porous membrane; and lithiating the anode.

Clause 180. A method of pre-lithiating an anode providing a negative electrode comprising an anode film disposed on a substrate, the anode film comprising a functionalized Group IVA particle of any one of clauses 1-29, a composite according to any one of clauses 30-38, or a composition according to any one of clauses 39-60; providing a lithium source; and lithiating the negative electrode.

Clause 181. The method of clause 180, wherein the anode film is disposed on a copper substrate.

Clause 182. The method of clause 180 or clause 181, wherein the lithium source is lithium foil.

Clause 183. The method of any one of clauses 180-182, wherein the negative electrode and the lithium source are positioned on opposite sides of an electrically insulating but ion permeable separator film, pressed together between rigid current collectors of the same shape, with the negative electrode and the lithium source connected electrically; and submerged in a lithium-ion electrolyte solution.

Clause 184. A method of forming a surface-modified Group IVA nanoparticle, comprising milling micrometer-sized Group IVA-containing materials under anaerobic conditions in the presence of one or more alkane solvents to provide a slurry of Group IVA nanoparticles; and treating the Group IVA nanoparticles with one or more surface-modifying agents.

Clause 185. The method of clause 184, wherein the treating the Group IVA nanoparticles with the one or more surface-modifying agents occurs after recovery of the slurry from the milling of the micrometer-sized Group IVA-containing materials.

Clause 186. The method of clause 184, wherein the treating the Group IVA nanoparticles with the one or more surface-modifying agents occurs during the milling of the micrometer-sized Group IVA-containing materials.

Clause 187. The method of any one of clauses 184-186, wherein the alkane solvent is heptane.

Clause 188. A method of forming a synthetic SEI layer or shell around a Group-IVA-containing nanoparticle, comprising: milling micrometer-sized Group IVA-containing materials under anaerobic conditions in the presence of one or more alkane solvents to provide a slurry of Group IVA nanoparticles; treating the Group IVA nanoparticles with one or more synthetic-SEI layer forming agents; and treating the Group IVA nanoparticles with one or more surface-modifiers.

Clause 189. The method of clause 184, wherein the treating the Group IVA nanoparticles with the one or more surface-modifying agents occurs after recovery of the slurry from the milling of the micrometer-sized Group IVA-containing materials.

Clause 190. The method of clause 184, wherein the treating the Group IVA nanoparticles with the one or more surface-modifying agents occurs during the milling of the micrometer-sized Group IVA-containing materials.

Clause 191. The method of any one of clauses 188-190, wherein the treating the Group IVA nanoparticles with the one or more synthetic-SEI layer forming agents occurs after recovery of the slurry from the milling of the micrometer-sized Group IVA-containing materials.

Clause 192. The method of any one of clauses 188-190, wherein the treating the Group IVA nanoparticles with the one or more synthetic-SEI layer forming agents occurs during the milling of the micrometer-sized Group IVA-containing materials.

Clause 193. The method of any one of clauses 188-192, wherein the alkane solvent is heptane.

Clause 194. The method of any one of clauses 188-193, wherein the synthetic-SEI layer forming agent is selected from a lithium aluminum alkoxide, a lithium ammonia borofluoride, an ammonia borofluoride, or a combination thereof.

Clause 195. The method of any one of clauses 188-194, wherein the synthetic-SEI layer forming agent is selected from formula LiAl(OR_{F})₄, wherein R_{F} at each occurrence is independently fluoroalkyl, fluoroaryl, and aryl. One exemplary lithium alkoxide is

Clause 196. The method of any one of clauses 188-194, wherein the synthetic-SEI layer forming agent is selected from formula LiAl(OC(Ph)CF₃)₂)₄.

Clause 197. The method of any one of clauses 188-194, wherein the synthetic-SEI layer forming agent is selected from formula Li⁺R₃NB₁₂H₁₁⁻, Li⁺R₃NB₁₂F₁₁⁻, (H₃N)₂B₁₂H₁₀, and (H₃N)₂B₁₂F₁₀, wherein R₃ at each occurrence is independently selected from hydrogen and C₁-C₄ alkyl (e.g., methyl, ethyl, propyl, butyl).

Clause 198. The method of any one of clauses 188-194, wherein the synthetic-SEI layer forming agent is selected from Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, and 1,12-(H₃N)₂B₁₂F₁₀.

Clause 199. Use of the Group-IVA-containing nanoparticle with a synthetic SEI layer or shell in the anode of a lithium ion battery.

Clause 200. A surface-modified nanoparticle, comprising: a core material comprising silicon, germanium, tin, or a combination thereof; and an outer surface modified with one or more surface-modifying agents; wherein the outer surface of the nanoparticle is substantially free of silicon oxide species, as characterized by X-ray photoelectron spectroscopy (XPS).

Clause 201. The surface-modified nanoparticle of clause 200, wherein the outer surface of the nanoparticle has a SiOₓ content of less than or equal to 1%, as characterized by X-ray photoelectron spectroscopy (XPS), wherein x is ≦2.

Clause 202. The surface-modified nanoparticle of clause 200 or 201, wherein the core material further comprises: one or more elements used for p-type semiconductor doping, the elements independently selected from boron, aluminum, and gallium; one or more elements used for n-type semiconductor doping, the elements independently selected from nitrogen, phosphorous, arsenic, and antimony; one or more elements found in metallurgical silicon, the elements independently selected from aluminum, calcium, titanium, iron, and copper; one or more conductive metals independently selected from aluminum, nickel, iron, copper, molybdenum, zinc, silver, and gold; or any combination thereof.

Clause 203. The surface-modified particle of any one of clauses 200-202, wherein the core material is free of p-type and n-type semiconductor doping elements.

Clause 204. The surface-modified nanoparticle of any one of clauses 200-203, wherein the core material comprises a silicon/tin alloy, a silicon/germanium alloy, a silicon/tin/nickel alloy, a silicon/titanium/nickel alloy, or a combination thereof.

Clause 205. The surface-modified nanoparticle of clause 204, wherein the core material comprises a polycrystalline or mixed-phase material comprising silicon, tin, germanium, nickel, titanium, or a combination thereof.

Clause 206. The surface-modified nanoparticle of any one of clauses 200-205, wherein the surface-modifying agent is benzene, mesitylene, xylene, 2,3-dihydroxynaphthalene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, pentacene, fluorine substituted pentacene, naphthalene, anthracene, pyrene, perylene, triphenylene, chrysene, phenanthrene, azulene, pentacene, pyrene, a polythiophene, poly(3-hexylthiophene-2,5-diyl), poly(3-hexylthiophene), polyvinylidene fluoride, a polyacrylonitrile, polyaniline crosslinked with phytic acid, single wall carbon nanotubes, multi-walled carbon nanotubes, C₆₀ fullerenes, C₇₀ fullerenes, nanospherical carbon, graphene, graphite nanoplatelets, carbon black, soot, carbonized conductive carbon, or any combination thereof.

Clause 207. The surface-modified nanoparticle of any one of clauses 200-206, selected from the group consisting of: a nanoparticle having a core material comprising silicon, and an outer surface modified with benzene; a nanoparticle having a core material comprising silicon, and an outer surface modified with p-xylene; a nanoparticle having a core material comprising silicon, and an outer surface modified with mesitylene; a nanoparticle having a core material comprising silicon, and an outer surface modified with naphthalene; a nanoparticle having a core material comprising silicon, and an outer surface modified with phenanthrene; a nanoparticle having a core material comprising silicon, and an outer surface modified with pyrene; a nanoparticle having a core material comprising silicon, and an outer surface modified with perylene; a nanoparticle having a core material comprising silicon, and an outer surface modified with azulene; a nanoparticle having a core material comprising silicon, and an outer surface modified with chrysene; a nanoparticle having a core material comprising silicon, and an outer surface modified with triphenylene; a nanoparticle having a core material comprising silicon, and an outer surface modified with 2,3-dihydroxynaphthalene; a nanoparticle having a core material comprising silicon, and an outer surface modified with 2,3-dihydroxyanthracene; a nanoparticle having a core material comprising silicon, and an outer surface modified with 9,10-phenanthrenequinone; a nanoparticle having a core material comprising silicon, and an outer surface modified with 2,3-dihydroxytetracene; a nanoparticle having a core material comprising silicon, and an outer surface modified with fluorine- or trifluoromethyl-substituted 2,3-dihydroxytetracene; a nanoparticle having a core material comprising silicon, and an outer surface modified with 2,3-dihydroxypentacene; a nanoparticle having a core material comprising silicon, and an outer surface modified with pentacene; a nanoparticle having a core material comprising silicon, and an outer surface modified with fluorine- or trifluoromethyl-substituted pentacene; a nanoparticle having a core material comprising silicon, and an outer surface modified with C₆₀ fullerene, C₇₀ fullerene, or a combination thereof; a nanoparticle having a core material comprising silicon, and an outer surface modified with graphene; a nanoparticle having a core material comprising silicon, and an outer surface modified with single-wall carbon nanotubes; a nanoparticle having a core material comprising silicon, and an outer surface modified with multi-wall carbon nanotubes; a nanoparticle having a core material comprising silicon, and an outer surface modified with styrene; a nanoparticle having a core material comprising a silicon/tin alloy, and an outer surface modified with benzene; a nanoparticle having a core material comprising a silicon/tin alloy, and an outer surface modified with p-xylene; a nanoparticle having a core material comprising a silicon/tin alloy, and an outer surface modified with mesitylene; a nanoparticle having a core material comprising a silicon/tin alloy, and an outer surface modified with 2,3-dihydroxynaphthalene; a nanoparticle having a core material comprising a silicon/tin alloy, and an outer surface modified with 2,3-dihydroxyanthracene; a nanoparticle having a core material comprising a silicon/tin alloy, and an outer surface modified with 9,10-phenanthrenequinone; a nanoparticle having a core material comprising a silicon/tin alloy, and an outer surface modified with 2,3-dihydroxytetracene; a nanoparticle having a core material comprising a silicon/tin alloy, and an outer surface modified with fluorine- or trifluoromethyl-substituted 2,3-dihydroxytetracene; a nanoparticle having a core material comprising a silicon/tin alloy, and an outer surface modified with 2,3-dihydroxypentacene; a nanoparticle having a core material comprising a silicon/tin alloy, and an outer surface modified with pentacene; a nanoparticle having a core material comprising a silicon/tin alloy, and an outer surface modified with fluorine- or trifluoromethyl-substituted pentacene; a nanoparticle having a core material comprising a silicon/tin alloy, and an outer surface modified with C₆₀ fullerene, C₇₀ fullerene, or a combination thereof; a nanoparticle having a core material comprising a silicon/tin alloy, and an outer surface modified with graphene; a nanoparticle having a core material comprising a silicon/tin alloy, and an outer surface modified with single-wall carbon nanotubes; a nanoparticle having a core material comprising a silicon/tin alloy, and an outer surface modified with multi-wall carbon nanotubes; a nanoparticle having a core material comprising silicon/tin alloy, and an outer surface modified with naphthalene; a nanoparticle having a core material comprising silicon/tin alloy, and an outer surface modified with phenanthrene; a nanoparticle having a core material comprising silicon/tin alloy, and an outer surface modified with pyrene; a nanoparticle having a core material comprising silicon/tin alloy, and an outer surface modified with perylene; a nanoparticle having a core material comprising silicon/tin alloy, and an outer surface modified with azulene; a nanoparticle having a core material comprising silicon/tin alloy, and an outer surface modified with chrysene; a nanoparticle having a core material comprising silicon/tin alloy, and an outer surface modified with triphenylene; a nanoparticle having a core material comprising silicon/tin alloy, and an outer surface modified with styrene; a nanoparticle having a core material comprising a silicon/germanium alloy, and an outer surface modified with benzene; a nanoparticle having a core material comprising a silicon/germanium alloy, and an outer surface modified with p-xylene; a nanoparticle having a core material comprising a silicon/germanium alloy, and an outer surface modified with mesitylene; a nanoparticle having a core material comprising a silicon/germanium alloy, and an outer surface modified with 2,3-dihydroxynaphthalene; a nanoparticle having a core material comprising a silicon/germanium alloy, and an outer surface modified with 2,3-dihydroxyanthracene; a nanoparticle having a core material comprising a silicon/germanium alloy, and an outer surface modified with 9,10-phenanthrenequinone; a nanoparticle having a core material comprising a silicon/germanium alloy, and an outer surface modified with 2,3-dihydroxytetracene; a nanoparticle having a core material comprising a silicon/germanium alloy, and an outer surface modified with fluorine- or trifluoromethyl-substituted 2,3-dihydroxytetracene; a nanoparticle having a core material comprising a silicon/germanium alloy, and an outer surface modified with 2,3-dihydroxypentacene; a nanoparticle having a core material comprising a silicon/germanium alloy, and an outer surface modified with pentacene; a nanoparticle having a core material comprising a silicon/germanium alloy, and an outer surface modified with fluorine- or trifluoromethyl-substituted pentacene; a nanoparticle having a core material comprising a silicon/germanium alloy, and an outer surface modified with C₆₀ fullerene, C₇₀ fullerene, or a combination thereof; a nanoparticle having a core material comprising a silicon/germanium alloy, and an outer surface modified with graphene; a nanoparticle having a core material comprising a silicon/germanium alloy, and an outer surface modified with single-wall carbon nanotubes; a nanoparticle having a core material comprising a silicon/germanium alloy, and an outer surface modified with multi-wall carbon nanotubes; a nanoparticle having a core material comprising silicon/germanium alloy, and an outer surface modified with naphthalene; a nanoparticle having a core material comprising silicon/germanium alloy, and an outer surface modified with phenanthrene; a nanoparticle having a core material comprising silicon/germanium alloy, and an outer surface modified with pyrene; a nanoparticle having a core material comprising silicon/germanium alloy, and an outer surface modified with perylene; a nanoparticle having a core material comprising silicon/germanium alloy, and an outer surface modified with azulene; a nanoparticle having a core material comprising silicon/germanium alloy, and an outer surface modified with chrysene; a nanoparticle having a core material comprising silicon/germanium alloy, and an outer surface modified with triphenylene; a nanoparticle having a core material comprising silicon/germanium alloy, and an outer surface modified with styrene; a nanoparticle having a core material comprising a silicon/tin/nickel alloy, and an outer surface modified with benzene; a nanoparticle having a core material comprising a silicon/tin/nickel alloy, and an outer surface modified with p-xylene; a nanoparticle having a core material comprising a silicon/tin/nickel alloy, and an outer surface modified with mesitylene; a nanoparticle having a core material comprising a silicon/tin/nickel alloy, and an outer surface modified with 2,3-dihydroxynaphthalene; a nanoparticle having a core material comprising a silicon/tin/nickel alloy, and an outer surface modified with 2,3-dihydroxyanthracene; a nanoparticle having a core material comprising a silicon/tin/nickel alloy, and an outer surface modified with 9,10-phenanthrenequinone; a nanoparticle having a core material comprising a silicon/tin/nickel alloy, and an outer surface modified with 2,3-dihydroxytetracene; a nanoparticle having a core material comprising a silicon/tin/nickel alloy, and an outer surface modified with fluorine- or trifluoromethyl-substituted 2,3-dihydroxytetracene; a nanoparticle having a core material comprising a silicon/tin/nickel alloy, and an outer surface modified with 2,3-dihydroxypentacene; a nanoparticle having a core material comprising a silicon/tin/nickel alloy, and an outer surface modified with pentacene; a nanoparticle having a core material comprising a silicon/tin/nickel alloy, and an outer surface modified with fluorine- or trifluoromethyl-substituted pentacene; a nanoparticle having a core material comprising a silicon/tin/nickel alloy, and an outer surface modified with C₆₀ fullerene, C₇₀ fullerene, or a combination thereof; a nanoparticle having a core material comprising a silicon/tin/nickel alloy, and an outer surface modified with graphene; a nanoparticle having a core material comprising a silicon/tin/nickel alloy, and an outer surface modified with single-wall carbon nanotubes; a nanoparticle having a core material comprising a silicon/tin/nickel alloy, and an outer surface modified with multi-wall carbon nanotubes; a nanoparticle having a core material comprising silicon/tin/nickel alloy, and an outer surface modified with naphthalene; a nanoparticle having a core material comprising silicon/tin/nickel alloy, and an outer surface modified with phenanthrene; a nanoparticle having a core material comprising silicon/tin/nickel alloy, and an outer surface modified with pyrene; a nanoparticle having a core material comprising silicon/tin/nickel alloy, and an outer surface modified with perylene; a nanoparticle having a core material comprising silicon/tin/nickel alloy, and an outer surface modified with azulene; a nanoparticle having a core material comprising silicon/tin/nickel alloy, and an outer surface modified with chrysene; a nanoparticle having a core material comprising silicon/tin/nickel alloy, and an outer surface modified with triphenylene; a nanoparticle having a core material comprising silicon/tin/nickel alloy, and an outer surface modified with styrene; a nanoparticle having a core material comprising a silicon/titanium/nickel alloy, and an outer surface modified with benzene; a nanoparticle having a core material comprising a silicon/titanium/nickel alloy, and an outer surface modified with p-xylene; a nanoparticle having a core material comprising a silicon/titanium/nickel alloy, and an outer surface modified with mesitylene; a nanoparticle having a core material comprising a silicon/titanium/nickel alloy, and an outer surface modified with 2,3-dihydroxynaphthalene; a nanoparticle having a core material comprising a silicon/titanium/nickel alloy, and an outer surface modified with 2,3-dihydroxyanthracene; a nanoparticle having a core material comprising a silicon/titanium/nickel alloy, and an outer surface modified with 9,10-phenanthrenequinone; a nanoparticle having a core material comprising a silicon/titanium/nickel alloy, and an outer surface modified with 2,3-dihydroxytetracene; a nanoparticle having a core material comprising a silicon/titanium/nickel alloy, and an outer surface modified with fluorine- or trifluormethyl-substituted 2,3-dihydroxytetracene; a nanoparticle having a core material comprising a silicon/titanium/nickel alloy, and an outer surface modified with 2,3-dihydroxypentacene; a nanoparticle having a core material comprising a silicon/titanium/nickel alloy, and an outer surface modified with pentacene; a nanoparticle having a core material comprising a silicon/titanium/nickel alloy, and an outer surface modified with fluorine- or trifluormethyl-substituted pentacene; a nanoparticle having a core material comprising a silicon/titanium/nickel alloy, and an outer surface modified with C₆₀ fullerene, C₇₀ fullerene, or a combination thereof; a nanoparticle having a core material comprising a silicon/titanium/nickel alloy, and an outer surface modified with graphene; a nanoparticle having a core material comprising a silicon/titanium/nickel alloy, and an outer surface modified with single-wall carbon nanotubes; a nanoparticle having a core material comprising a silicon/titanium/nickel alloy, and an outer surface modified with multi-wall carbon nanotubes; a nanoparticle having a core material comprising silicon/titanium/nickel alloy, and an outer surface modified with naphthalene; a nanoparticle having a core material comprising silicon/titanium/nickel alloy, and an outer surface modified with phenanthrene; a nanoparticle having a core material comprising silicon/titanium/nickel alloy, and an outer surface modified with pyrene; a nanoparticle having a core material comprising silicon/titanium/nickel alloy, and an outer surface modified with perylene; a nanoparticle having a core material comprising silicon/titanium/nickel alloy, and an outer surface modified with azulene; a nanoparticle having a core material comprising silicon/titanium/nickel alloy, and an outer surface modified with chrysene; a nanoparticle having a core material comprising silicon/titanium/nickel alloy, and an outer surface modified with triphenylene; and a nanoparticle having a core material comprising silicon/titanium/nickel alloy, and an outer surface modified with styrene.

Clause 208. The surface-modified nanoparticle of any one of clauses 200-207, further comprising a solid electrolyte interface (SEI) shell or layer, wherein the solid electrolyte interface is a polymer comprising repeating units derived from ethylene carbonate, propylene carbonate, fluorinated ethylene carbonate, fluorinated propylene carbonate, or a combination thereof.

Clause 209. An electrode film comprising a surface-modified nanoparticle according to any one of clauses 200-208, and one or more additives independently selected from polythiophenes, polyacrylonitrile, polyaniline crosslinked with phytic acid, sodium alginate, carbon black, nanospherical carbon, graphene, fullerenes, single-wall carbon nanotubes (SWCNT), and multi-wall carbon nanotubes (MWCNT).

Clause 210. The electrode film of clause 209, further comprising one or more polymer binders independently selected from polythiophenes, polyvinylidene difluoride (PVDF), polyacrylonitrile, sodium alginate, and lithium polyacrylates.

Clause 211. The electrode film of clause 209 or 210, further comprising one or more lithium reagents (e.g., for forming robust/stable SEI), each independently selected from the group consisting of Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, and 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

Clause 212. A lithium ion battery comprising: a positive electrode; a negative electrode comprising a surface-modified nanoparticle according to any one of clauses 200-208, wherein the negative electrode comprises a stable solid electrolyte interface (SEI) layer (e.g., a synthetic SEI layer; wherein natural SEI is formed from lithium and electrolyte in a cell); a lithium ion permeable separator between the positive electrode and the negative electrode; an electrolyte comprising lithium ions; and a solvent comprising ethylene carbonate, dimethyl carbonate, diethyl carbonate, methylethyl carbonate, or a combination thereof.

Clause 213. The lithium ion battery of clause 212, wherein the electrolyte comprises one or more of monofluoroethylene carbonate, Li⁺R₃NB₁₂H₁₁⁻, Li⁺R₃NB₁₂F₁₁⁻, Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R at each occurrence is independently selected from methyl, ethyl, propyl, iso-propyl, n-butyl, iso-butyl sec-butyl and t-butyl, and R_{F} at each occurrence is independently selected from fluorinated-alkyl and fluorinated-aryl, provided the fluorinated-alkyl and fluorinated-aryl are not perfluorinated.

Clause 214. A method of preparing a surface-modified nanoparticle having a core material comprising silicon, germanium, tin, or combination thereof, and an outer surface modified with one or more surface-modifying agents, the method comprising: (a) comminuting micrometer-sized or nanometer-sized silicon-containing materials, optionally under anaerobic conditions, in the presence of (i) one or more surface-modifying agents; (ii) optionally one or more alkane solvents; and (iii) optionally one or more lithium-containing reagents [e.g., including, but not limited to Li metal, lithiated graphite, buthyl-lithium, naphtalene-lithium and the like, which can be used for pre-lithiation and/or synthetic SEI layer formation, preferably under anaerobic and anhydrous environment]; to provide a slurry of surface-modified nanoparticles; and (b) recovering the surface-modified nanoparticles from the slurry (e.g., via evaporation), or using the slurry directly to manufacture a dispersion useful for manufacturing electrode films.

Clause 215. The method of clause 214, wherein the one or more alkane solvents are each independently selected from n-heptane, heptanes, hexanes, and C₆-C₁₀ hydrocarbon solvents.

Clause 216. The method of clause 214 or 215, wherein the comminuting of step (a) is performed in a bead mill with beads having a diameter of 0.05 mm to 0.6 mm.

Clause 217. The method of any one of clauses 214-216, wherein the comminuting of step (a) is performed in a bead mill with a tip speed of equal to or greater than 6 meters/second, a tip speed of equal to or greater than 7 meters/second, a tip speed of equal to or greater than 8 meters/second, a tip speed of equal to or greater than 9 meters/second, a tip speed of equal to or greater than 10 meters/second, a tip speed of equal to or greater than 11 meters/second, a tip speed of equal to or greater than 12 meters/second, a tip speed of equal to or greater than 13 meters/second, a tip speed of equal to or greater than 14 meters/second, a tip speed of equal to or greater than 15 meters/second, a tip speed of equal to or greater than 16 meters/second, a tip speed of equal to or greater than 17 meters/second, a tip speed of equal to or greater than 18 meters/second, a tip speed of equal to or greater than 19 meters/second, or a tip speed of equal to or greater than 20 meters/second (e.g., a tip speed of 10 or greater can lead to blending (e.g., Si, Sn, Ge) to amorphous phase without use of melting).

Clause 218. The method of any one of clauses 214-217, wherein the micrometer-sized or nanometer-sized silicon-containing materials of step (a) are comminuted in the presence of one or more lithium-containing reagents independently selected from lithium metal, alkyllithium reagents, and lithium salts.

Clause 219. The method of any one of clauses 214-218, wherein the micrometer-sized or nanometer-sized silicon-containing materials of step (a) are comminuted in the presence of (iv) one or more solvents configured to prevent or reduce sedimentation or colloid formation of the particles in the slurry, wherein the solvent that prevents or reduces sedimentation is diglyme, triglyme, or a combination thereof.

Clause 220. The method of any one of clauses 214-219, wherein prior to the comminuting step (a), the micrometer-sized or nanometer-sized silicon-containing materials are treated with a protic acid to provide hydrogen-passivated micrometer-sized or nanometer-sized silicon-containing materials (e.g., leach with HCl follow by removal of surface oxides with HF).

Clause 221. The method of any one of clauses 214-220, wherein the comminuting of step (a) is conducted under anaerobic conditions, the anaerobic conditions defined as an O₂ content of less than 5 ppm and an H₂O content of less than 5 ppm (e.g., slurry can go through a feed system that is purged; and diffusion of O₂ and H₂O into the alkane solvent is low).

Clause 222. The method of any one of clauses 214-221, wherein the micrometer-sized or nanometer-sized silicon-containing materials are derived from metallurgical grade silicon, or crystalline silicon or polycrystalline silicon with a purity of metallurgical grade silicon.

Clause 223. The method of any one of clauses 214-222, wherein the micrometer-sized or nanometer-sized silicon-containing materials are derived from silicon wafers or ingots.

Clause 224. The method of any one of clauses 214-223, wherein the surface-modifying agent is benzene, mesitylene, xylenes, 2,3-dihydroxynaphthalene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, fluorine substituted pentacene, trifluromethyl substituted pentacene, naphthalene, anthracene, phenanthrene, triphenylene, perylene, pyrene, chrysene, azulene, pentacene, a polythiophene, poly(3-hexylthiophene-2,5-diyl), poly(3-hexylthiophene), polyvinylidene fluoride, a polyacrylonitrile, polyaniline crosslinked with phytic acid, single wall carbon nanotubes, multi-walled carbon nanotubes, C₆₀ fullerenes, C₇₀ fullerenes, nanospherical carbon, graphene, carbon black, soot, carbonized conductive carbon, or any combination thereof.

Clause 225. The method of any one of clauses 214-224, wherein the outer surface of the surface-modified nanoparticle is substantially free of silicon oxide and other dielectric species, as characterized by X-ray photoelectron spectroscopy (XPS).

Clause 226. The method of any one of clauses 214-225, wherein the core material of the surface-modified nanoparticle further comprises: one or more elements used for p-type semiconductor doping, the elements independently selected from boron, aluminum, and gallium; one or more elements used for n-type semiconductor doping, the elements independently selected from nitrogen, phosphorous, arsenic, and antimony; one or more elements found in metallurgical silicon, the elements independently selected from aluminum, calcium, titanium, iron, and copper; one or more conductive metals independently selected from aluminum, nickel, iron, copper, molybdenum, zinc, silver, and gold; or any combination thereof.

Clause 227. The method of any one of clauses 214-226, wherein the micrometer-sized or nanometer-sized silicon-containing materials of step (a) are comminuted in the presence of one or more solid electrolyte interface (SEI)-forming reagents, each independently selected from ethylene carbonate, propylene carbonate, dimethyl carbonate, diethyl carbonate, methyl-ethyl carbonate, acetonitrile, dimethoxyethane, olygo- and poly-ethylene glycols with or without methyl or ethyl end groups and/or oxymethylene groups incorporated in the chain, lithium hexafluorophosphate, lithium bis(oxalato)borate, lithium fluoride, lithium oxide, lithium trifluoromethanesulfonate, lithium bis-trifluoromethanesulfonimide, and lithium perchlorate.

Clause 228. A method of preparing an electrode film, the electrode film comprising one or more surface-modified nanoparticles having a core material comprising silicon and an outer surface modified with one or more surface-modifying agents; and one or more additives independently selected from polythiophenes, polyvinylidene difluoride (PVDF), polyacrylonitrile, polyaniline crosslinked with phytic acid, sodium alginate, carbon black, nanospherical carbon, graphite, graphene, fullerenes, single-wall carbon nanotubes (SWCNT), and multi-wall carbon nanotubes (MWCNT); the method comprising: providing a dispersion comprising the one or more surface-modified nanoparticles, the one or more conductive additives, and one or more solvents independently selected from dichloromethane, 1,2-dichloroethane, 1,2,3-trichloropropane, deionized water, N-methyl pyrrolidone (NMP), acrylonitrile, N,N-dimethylacetamide, N,N-dimethylformamide (DMF), tetrahydrofuran (THF), triethyleneglycol dimethylether, diethyleneglycol dimethylether, and n-heptane; applying the dispersion to a substrate; and evaporating the one or more solvents after application of the dispersion to provide an electrode film.

Clause 229. The method of clause 228, wherein the dispersion is applied to the substrate with a doctor blade, an air brush, an ink jet printer, by gravure printing, by screen printing, or any combination thereof.

It is understood that the foregoing detailed description and accompanying examples are merely illustrative and are not to be taken as limitations upon the scope of the invention, which is defined solely by the appended claims and their equivalents.

Various changes and modifications to the disclosed embodiments will be apparent to those skilled in the art. Such changes and modifications, including without limitation those relating to the chemical structures, substituents, derivatives, intermediates, syntheses, compositions, formulations, or methods of use of the invention, may be made without departing from the spirit and scope thereof.

What is claimed is:

1. A surface-modified nanoparticle, comprising:
a core material comprising silicon, germanium, tin, or a combination thereof; and
an outer surface modified with one or more surface-modifying agents;
wherein the outer surface of the nanoparticle is substantially free of silicon oxide species, as characterized by X-ray photoelectron spectroscopy (XPS).

2. The surface-modified nanoparticle of claim 1, wherein the outer surface of the nanoparticle has a SiOₓ content of less than or equal to 1%, as characterized by X-ray photoelectron spectroscopy (XPS), wherein x is ≦2.

3. The surface-modified nanoparticle of claim 1, wherein the core material further comprises:
one or more elements used for p-type semiconductor doping, the elements independently selected from boron, aluminum, and gallium;
one or more elements used for n-type semiconductor doping, the elements independently selected from nitrogen, phosphorous, arsenic, and antimony;
one or more elements found in metallurgical silicon, the elements independently selected from aluminum, calcium, titanium, iron, and copper;
one or more conductive metals independently selected from aluminum, nickel, iron, copper, molybdenum, zinc, silver, and gold;
or any combination thereof.

4. The surface-modified particle of claim 1, wherein the core material is free of p-type and n-type semiconductor doping elements.

5. The surface-modified nanoparticle of claim 1, wherein the core material comprises a silicon/tin alloy, a silicon/germanium alloy, a silicon/tin/nickel alloy, a silicon/titanium/nickel alloy, or a combination thereof.

6. The surface-modified nanoparticle of claim 5, wherein the core material comprises a polycrystalline or mixed-phase material comprising silicon, tin, germanium, nickel, titanium, or a combination thereof.

7. The surface-modified nanoparticle of claim 1, wherein the surface-modifying agent is benzene, mesitylene, xylene, 2,3-dihydroxynaphthalene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, pentacene, fluorine substituted pentacene, naphthalene, anthracene, pyrene, perylene, triphenylene, chrysene, phenanthrene, azulene, pentacene, pyrene, a polythiophene, poly(3-hexylthiophene-2,5-diyl), poly(3-hexylthiophene), polyvinylidene fluoride, a polyacrylonitrile, polyaniline crosslinked with phytic acid, single wall carbon nanotubes, multi-walled carbon nanotubes, C₆₀ fullerenes, C₇₀ fullerenes, nanospherical carbon, graphene, graphite nanoplatelets, carbon black, soot, carbonized conductive carbon, or any combination thereof.

8. The surface-modified nanoparticle of claim 1, selected from the group consisting of:
a nanoparticle having a core material comprising silicon, and an outer surface modified with benzene;
a nanoparticle having a core material comprising silicon, and an outer surface modified with p-xylene;
a nanoparticle having a core material comprising silicon, and an outer surface modified with mesitylene;
a nanoparticle having a core material comprising silicon, and an outer surface modified with naphthalene;
a nanoparticle having a core material comprising silicon, and an outer surface modified with phenanthrene;
a nanoparticle having a core material comprising silicon, and an outer surface modified with pyrene;
a nanoparticle having a core material comprising silicon, and an outer surface modified with perylene;
a nanoparticle having a core material comprising silicon, and an outer surface modified with azulene;
a nanoparticle having a core material comprising silicon, and an outer surface modified with chrysene;
a nanoparticle having a core material comprising silicon, and an outer surface modified with triphenylene;
a nanoparticle having a core material comprising silicon, and an outer surface modified with 2,3-dihydroxynaphthalene;
a nanoparticle having a core material comprising silicon, and an outer surface modified with 2,3-dihydroxyanthracene;
a nanoparticle having a core material comprising silicon, and an outer surface modified with 9,10-phenanthrenequinone;
a nanoparticle having a core material comprising silicon, and an outer surface modified with 2,3-dihydroxytetracene;
a nanoparticle having a core material comprising silicon, and an outer surface modified with fluorine- or trifluoromethyl-substituted 2,3-dihydroxytetracene;
a nanoparticle having a core material comprising silicon, and an outer surface modified with 2,3-dihydroxypentacene;
a nanoparticle having a core material comprising silicon, and an outer surface modified with pentacene;
a nanoparticle having a core material comprising silicon, and an outer surface modified with fluorine- or trifluoromethyl-substituted pentacene;
a nanoparticle having a core material comprising silicon, and an outer surface modified with C₆₀ fullerene, C₇₀ fullerene, or a combination thereof.
a nanoparticle having a core material comprising silicon, and an outer surface modified with graphene;
a nanoparticle having a core material comprising silicon, and an outer surface modified with single-wall carbon nanotubes;
a nanoparticle having a core material comprising silicon, and an outer surface modified with multi-wall carbon nanotubes;
a nanoparticle having a core material comprising silicon, and an outer surface modified with styrene;
a nanoparticle having a core material comprising a silicon/tin alloy, and an outer surface modified with benzene;
a nanoparticle having a core material comprising a silicon/tin alloy, and an outer surface modified with p-xylene;
a nanoparticle having a core material comprising a silicon/tin alloy, and an outer surface modified with mesitylene;
a nanoparticle having a core material comprising a silicon/tin alloy, and an outer surface modified with 2,3-dihydroxynaphthalene;
a nanoparticle having a core material comprising a silicon/tin alloy, and an outer surface modified with 2,3-dihydroxyanthracene;
a nanoparticle having a core material comprising a silicon/tin alloy, and an outer surface modified with 9,10-phenanthrenequinone;
a nanoparticle having a core material comprising a silicon/tin alloy, and an outer surface modified with 2,3-dihydroxytetracene;
a nanoparticle having a core material comprising a silicon/tin alloy, and an outer surface modified with fluorine- or trifluoromethyl-substituted 2,3-dihydroxytetracene;
a nanoparticle having a core material comprising a silicon/tin alloy, and an outer surface modified with 2,3-dihydroxypentacene;
a nanoparticle having a core material comprising a silicon/tin alloy, and an outer surface modified with pentacene;
a nanoparticle having a core material comprising a silicon/tin alloy, and an outer surface modified with fluorine- or trifluoromethyl-substituted pentacene;
a nanoparticle having a core material comprising a silicon/tin alloy, and an outer surface modified with C₆₀ fullerene, C₇₀ fullerene, or a combination thereof;
a nanoparticle having a core material comprising a silicon/tin alloy, and an outer surface modified with graphene;
a nanoparticle having a core material comprising a silicon/tin alloy, and an outer surface modified with single-wall carbon nanotubes;
a nanoparticle having a core material comprising a silicon/tin alloy, and an outer surface modified with multi-wall carbon nanotubes;
a nanoparticle having a core material comprising silicon/tin alloy, and an outer surface modified with naphthalene;
a nanoparticle having a core material comprising silicon/tin alloy, and an outer surface modified with phenanthrene;
a nanoparticle having a core material comprising silicon/tin alloy, and an outer surface modified with pyrene;
a nanoparticle having a core material comprising silicon/tin alloy, and an outer surface modified with perylene;
a nanoparticle having a core material comprising silicon/tin alloy, and an outer surface modified with azulene;
a nanoparticle having a core material comprising silicon/tin alloy, and an outer surface modified with chrysene;
a nanoparticle having a core material comprising silicon/tin alloy, and an outer surface modified with triphenylene;
a nanoparticle having a core material comprising silicon/tin alloy, and an outer surface modified with styrene;
a nanoparticle having a core material comprising a silicon/germanium alloy, and an outer surface modified with benzene;
a nanoparticle having a core material comprising a silicon/germanium alloy, and an outer surface modified with p-xylene;
a nanoparticle having a core material comprising a silicon/germanium alloy, and an outer surface modified with mesitylene;
a nanoparticle having a core material comprising a silicon/germanium alloy, and an outer surface modified with 2,3-dihydroxynaphthalene;
a nanoparticle having a core material comprising a silicon/germanium alloy, and an outer surface modified with 2,3-dihydroxyanthracene;
a nanoparticle having a core material comprising a silicon/germanium alloy, and an outer surface modified with 9,10-phenanthrenequinone;
a nanoparticle having a core material comprising a silicon/germanium alloy, and an outer surface modified with 2,3-dihydroxytetracene;
a nanoparticle having a core material comprising a silicon/germanium alloy, and an outer surface modified with fluorine- or trifluoromethyl-substituted 2,3-dihydroxytetracene;
a nanoparticle having a core material comprising a silicon/germanium alloy, and an outer surface modified with 2,3-dihydroxypentacene;
a nanoparticle having a core material comprising a silicon/germanium alloy, and an outer surface modified with pentacene;
a nanoparticle having a core material comprising a silicon/germanium alloy, and an outer surface modified with fluorine- or trifluoromethyl-substituted pentacene;
a nanoparticle having a core material comprising a silicon/germanium alloy, and an outer surface modified with C₆₀ fullerene, C₇₀ fullerene, or a combination thereof;
a nanoparticle having a core material comprising a silicon/germanium alloy, and an outer surface modified with graphene;
a nanoparticle having a core material comprising a silicon/germanium alloy, and an outer surface modified with single-wall carbon nanotubes;
a nanoparticle having a core material comprising a silicon/germanium alloy, and an outer surface modified with multi-wall carbon nanotubes;
a nanoparticle having a core material comprising silicon/germanium alloy, and an outer surface modified with naphthalene;
a nanoparticle having a core material comprising silicon/germanium alloy, and an outer surface modified with phenanthrene;
a nanoparticle having a core material comprising silicon/germanium alloy, and an outer surface modified with pyrene;
a nanoparticle having a core material comprising silicon/germanium alloy, and an outer surface modified with perylene;
a nanoparticle having a core material comprising silicon/germanium alloy, and an outer surface modified with azulene;
a nanoparticle having a core material comprising silicon/germanium alloy, and an outer surface modified with chrysene;
a nanoparticle having a core material comprising silicon/germanium alloy, and an outer surface modified with triphenylene;
a nanoparticle having a core material comprising silicon/germanium alloy, and an outer surface modified with styrene;
a nanoparticle having a core material comprising a silicon/tin/nickel alloy, and an outer surface modified with benzene;
a nanoparticle having a core material comprising a silicon/tin/nickel alloy, and an outer surface modified with p-xylene;
a nanoparticle having a core material comprising a silicon/tin/nickel alloy, and an outer surface modified with mesitylene;
a nanoparticle having a core material comprising a silicon/tin/nickel alloy, and an outer surface modified with 2,3-dihydroxynaphthalene;
a nanoparticle having a core material comprising a silicon/tin/nickel alloy, and an outer surface modified with 2,3-dihydroxyanthracene;
a nanoparticle having a core material comprising a silicon/tin/nickel alloy, and an outer surface modified with 9,10-phenanthrenequinone;
a nanoparticle having a core material comprising a silicon/tin/nickel alloy, and an outer surface modified with 2,3-dihydroxytetracene;
a nanoparticle having a core material comprising a silicon/tin/nickel alloy, and an outer surface modified with fluorine- or trifluoromethyl-substituted 2,3-dihydroxytetracene;
a nanoparticle having a core material comprising a silicon/tin/nickel alloy, and an outer surface modified with 2,3-dihydroxypentacene;
a nanoparticle having a core material comprising a silicon/tin/nickel alloy, and an outer surface modified with pentacene;
a nanoparticle having a core material comprising a silicon/tin/nickel alloy, and an outer surface modified with fluorine- or trifluoromethyl-substituted pentacene;
a nanoparticle having a core material comprising a silicon/tin/nickel alloy, and an outer surface modified with C₆₀ fullerene, C₇₀ fullerene, or a combination thereof;
a nanoparticle having a core material comprising a silicon/tin/nickel alloy, and an outer surface modified with graphene;
a nanoparticle having a core material comprising a silicon/tin/nickel alloy, and an outer surface modified with single-wall carbon nanotubes;
a nanoparticle having a core material comprising a silicon/tin/nickel alloy, and an outer surface modified with multi-wall carbon nanotubes;
a nanoparticle having a core material comprising silicon/tin/nickel alloy, and an outer surface modified with naphthalene;
a nanoparticle having a core material comprising silicon/tin/nickel alloy, and an outer surface modified with phenanthrene;
a nanoparticle having a core material comprising silicon/tin/nickel alloy, and an outer surface modified with pyrene;
a nanoparticle having a core material comprising silicon/tin/nickel alloy, and an outer surface modified with perylene;
a nanoparticle having a core material comprising silicon/tin/nickel alloy, and an outer surface modified with azulene;
a nanoparticle having a core material comprising silicon/tin/nickel alloy, and an outer surface modified with chrysene;
a nanoparticle having a core material comprising silicon/tin/nickel alloy, and an outer surface modified with triphenylene;
a nanoparticle having a core material comprising silicon/tin/nickel alloy, and an outer surface modified with styrene;
a nanoparticle having a core material comprising a silicon/titanium/nickel alloy, and an outer surface modified with benzene;
a nanoparticle having a core material comprising a silicon/titanium/nickel alloy, and an outer surface modified with p-xylene;
a nanoparticle having a core material comprising a silicon/titanium/nickel alloy, and an outer surface modified with mesitylene;
a nanoparticle having a core material comprising a silicon/titanium/nickel alloy, and an outer surface modified with 2,3-dihydroxynaphthalene;
a nanoparticle having a core material comprising a silicon/titanium/nickel alloy, and an outer surface modified with 2,3-dihydroxyanthracene;
a nanoparticle having a core material comprising a silicon/titanium/nickel alloy, and an outer surface modified with 9,10-phenanthrenequinone;
a nanoparticle having a core material comprising a silicon/titanium/nickel alloy, and an outer surface modified with 2,3-dihydroxytetracene;
a nanoparticle having a core material comprising a silicon/titanium/nickel alloy, and an outer surface modified with fluorine- or trifluormethyl-substituted 2,3-dihydroxytetracene;
a nanoparticle having a core material comprising a silicon/titanium/nickel alloy, and an outer surface modified with 2,3-dihydroxypentacene;
a nanoparticle having a core material comprising a silicon/titanium/nickel alloy, and an outer surface modified with pentacene;
a nanoparticle having a core material comprising a silicon/titanium/nickel alloy, and an outer surface modified with fluorine- or trifluormethyl-substituted pentacene;
a nanoparticle having a core material comprising a silicon/titanium/nickel alloy, and an outer surface modified with C₆₀ fullerene, C₇₀ fullerene, or a combination thereof;
a nanoparticle having a core material comprising a silicon/titanium/nickel alloy, and an outer surface modified with graphene;
a nanoparticle having a core material comprising a silicon/titanium/nickel alloy, and an outer surface modified with single-wall carbon nanotubes;
a nanoparticle having a core material comprising a silicon/titanium/nickel alloy, and an outer surface modified with multi-wall carbon nanotubes;
a nanoparticle having a core material comprising silicon/titanium/nickel alloy, and an outer surface modified with naphthalene;
a nanoparticle having a core material comprising silicon/titanium/nickel alloy, and an outer surface modified with phenanthrene;
a nanoparticle having a core material comprising silicon/titanium/nickel alloy, and an outer surface modified with pyrene;
a nanoparticle having a core material comprising silicon/titanium/nickel alloy, and an outer surface modified with perylene;
a nanoparticle having a core material comprising silicon/titanium/nickel alloy, and an outer surface modified with azulene;
a nanoparticle having a core material comprising silicon/titanium/nickel alloy, and an outer surface modified with chrysene;
a nanoparticle having a core material comprising silicon/titanium/nickel alloy, and an outer surface modified with triphenylene; and
a nanoparticle having a core material comprising silicon/titanium/nickel alloy, and an outer surface modified with styrene.

9. The surface-modified nanoparticle of claim 1, further comprising a solid electrolyte interface (SEI) shell or layer, wherein the solid electrolyte interface is a polymer comprising repeating units derived from ethylene carbonate, propylene carbonate, fluorinated ethylene carbonate, fluorinated propylene carbonate, or a combination thereof.

10. An electrode film comprising a surface-modified nanoparticle according to claim 1, and one or more additives independently selected from polythiophenes, polyacrylonitrile, polyaniline crosslinked with phytic acid, sodium alginate, carbon black, nanospherical carbon, graphene, fullerenes, single-wall carbon nanotubes (SWCNT), and multi-wall carbon nanotubes (MWCNT).

11. The electrode film of claim 10, further comprising one or more polymer binders independently selected from polythiophenes, polyvinylidene difluoride (PVDF), polyacrylonitrile, sodium alginate, and lithium polyacrylates.

12. The electrode film of claim 10, further comprising one or more lithium reagents independently selected from the group consisting of Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, and 1,12-(H₃N)₂B₁₂F₁₀, LiAl(OR_{F})₄, or any combination thereof, wherein R_{F} at each occurrence is independently selected from fluorinated-alkyl and fluorinated-aryl, provided the fluorinated-alkyl and fluorinated-aryl are not perfluorinated.

13. A lithium ion battery comprising:
a positive electrode;
a negative electrode comprising a surface-modified nanoparticle according to claim 1, wherein the negative electrode comprises a stable solid electrolyte interface (SEI) layer;
a lithium ion permeable separator between the positive electrode and the negative electrode;
an electrolyte comprising lithium ions; and
a solvent comprising ethylene carbonate, dimethyl carbonate, diethyl carbonate, methylethyl carbonate, or a combination thereof.

14. The lithium ion battery of claim 13, wherein the electrolyte comprises one or more of monofluoroethylene carbonate, Li⁺R₃NB₁₂H₁₁⁻, Li⁺R₃NB₁₂F₁₁⁻, Li⁺H₃NB₁₂H₁₁⁻, Li⁺H₃NB₁₂F₁₁⁻, 1,2-(H₃N)₂B₁₂H₁₀, 1,7-(H₃N)₂B₁₂H₁₀, 1,12-(H₃N)₂B₁₂H₁₀, 1,2-(H₃N)₂B₁₂F₁₀, 1,7-(H₃N)₂B₁₂F₁₀, 1,12-(H₃N)₂B₁₂F₁₀, LiAl(OR_{F})₄, or any combination thereof, wherein R at each occurrence is independently selected from methyl, ethyl, propyl, iso-propyl, n-butyl, iso-butyl sec-butyl and t-butyl, and R_{F} at each occurrence is independently selected from fluorinated-alkyl and fluorinated-aryl, provided the fluorinated-alkyl and fluorinated-aryl are not perfluorinated.

15. A method of preparing a surface-modified nanoparticle having a core material comprising silicon, germanium, tin, or combination thereof, and an outer surface modified with one or more surface-modifying agents, the method comprising:
(a) comminuting micrometer-sized or nanometer-sized silicon-containing materials, optionally under anaerobic conditions, in the presence of
(i) one or more surface-modifying agents;
(ii) optionally one or more alkane solvents; and
(iii) optionally one or more lithium-containing reagents;
to provide a slurry of surface-modified nanoparticles; and
(b) recovering the surface-modified nanoparticles from the slurry, or using the slurry directly to manufacture a dispersion useful for manufacturing electrode films.

16. The method of claim 15, wherein the one or more alkane solvents are each independently selected from n-heptane, heptanes, hexanes, and C₆-C₁₀ hydrocarbon solvents.

17. The method of claim 15, wherein the comminuting of step (a) is performed in a bead mill with beads having a diameter of 0.05 mm to 0.6 mm.

18. The method of claim 15, wherein the comminuting of step (a) is performed in a bead mill with a tip speed of equal to or greater than 6 meters/second.

19. The method of claim 15, wherein the micrometer-sized or nanometer-sized silicon-containing materials of step (a) are comminuted in the presence of one or more lithium-containing reagents independently selected from lithium metal, alkyllithium reagents, and lithium salts.

20. The method of claim 15, wherein the micrometer-sized or nanometer-sized silicon-containing materials of step (a) are comminuted in the presence of (iv) one or more solvents configured to prevent or reduce sedimentation or colloid formation of the particles in the slurry, wherein the solvent that prevents or reduces sedimentation is diglyme, triglyme, or a combination thereof.

21. The method of claim 15, wherein prior to the comminuting step (a), the micrometer-sized or nanometer-sized silicon-containing materials are treated with a protic acid to provide hydrogen-passivated micrometer-sized or nanometer-sized silicon-containing materials.

22. The method of claim 15, wherein the comminuting of step (a) is conducted under anaerobic conditions, the anaerobic conditions defined as an O₂ content of less than 5 ppm and an H₂O content of less than 5 ppm.

23. The method of claim 15, wherein the micrometer-sized or nanometer-sized silicon-containing materials are derived from metallurgical grade silicon, or crystalline silicon or polycrystalline silicon with a purity of metallurgical grade silicon.

24. The method of claim 15, wherein the micrometer-sized or nanometer-sized silicon-containing materials are derived from silicon wafers or ingots.

25. The method of claim 15, wherein the surface-modifying agent is benzene, mesitylene, xylenes, 2,3-dihydroxynaphthalene, 2,3-dihydroxyanthracene, 9,10-phenanthrenequinone, 2,3-dihydroxytetracene, fluorine substituted 2,3-dihydroxytetracene, trifluromethyl substituted 2,3-dihydroxytetracene, 2,3-dihydroxypentacene, fluorine substituted 2,3-dihydroxypentacene, trifluromethyl substituted 2,3-dihydroxypentacene, fluorine substituted pentacene, trifluromethyl substituted pentacene, naphthalene, anthracene, phenanthrene, triphenylene, perylene, pyrene, chrysene, azulene, pentacene, a polythiophene, poly(3-hexylthiophene-2,5-diyl), poly(3-hexylthiophene), polyvinylidene fluoride, a polyacrylonitrile, polyaniline crosslinked with phytic acid, single wall carbon nanotubes, multi-walled carbon nanotubes, C₆₀ fullerenes, C₇₀ fullerenes, nanospherical carbon, graphene, carbon black, soot, carbonized conductive carbon, or any combination thereof.

26. The method of claim 15, wherein the outer surface of the surface-modified nanoparticle is substantially free of silicon oxide and other dielectric species, as characterized by X-ray photoelectron spectroscopy (XPS).

27. The method of claim 15, wherein the core material of the surface-modified nanoparticle further comprises:
one or more elements used for p-type semiconductor doping, the elements independently selected from boron, aluminum, and gallium;
one or more elements used for n-type semiconductor doping, the elements independently selected from nitrogen, phosphorous, arsenic, and antimony;
one or more elements found in metallurgical silicon, the elements independently selected from aluminum, calcium, titanium, iron, and copper;
one or more conductive metals independently selected from aluminum, nickel, iron, copper, molybdenum, zinc, silver, and gold;
or any combination thereof.

28. The method of claim 15, wherein the micrometer-sized or nanometer-sized silicon-containing materials of step (a) are comminuted in the presence of one or more solid electrolyte interface (SEI)-forming reagents, each independently selected from ethylene carbonate, propylene carbonate, dimethyl carbonate, diethyl carbonate, methyl-ethyl carbonate, acetonitrile, dimethoxyethane, olygo- and poly-ethylene glycols with or without methyl or ethyl end groups and/or oxymethylene groups incorporated in the chain, lithium hexafluorophosphate, lithium bis(oxalato)borate, lithium fluoride, lithium oxide, lithium trifluoromethanesulfonate, lithium bis-trifluoromethanesulfonimide, and lithium perchlorate.

29. A method of preparing an electrode film, the electrode film comprising one or more surface-modified nanoparticles having a core material comprising silicon and an outer surface modified with one or more surface-modifying agents; and one or more additives independently selected from polythiophenes, polyvinylidene difluoride (PVDF), polyacrylonitrile, polyaniline crosslinked with phytic acid, sodium alginate, carbon black, nanospherical carbon, graphite, graphene, fullerenes, single-wall carbon nanotubes (SWCNT), and multi-wall carbon nanotubes (MWCNT);
the method comprising:
providing a dispersion comprising the one or more surface-modified nanoparticles, the one or more conductive additives, and one or more solvents independently selected from dichloromethane, 1,2-dichloroethane, 1,2,3-trichloropropane, deionized water, N-methyl pyrrolidone (NMP), acrylonitrile, N,N-dimethylacetamide, N,N-dimethylformamide (DMF), tetrahydrofuran (THF), triethyleneglycol dimethylether, diethyleneglycol dimethylether, and n-heptane;
applying the dispersion to a substrate; and
evaporating the one or more solvents after application of the dispersion to provide an electrode film.

30. The method of claim 29, wherein the dispersion is applied to the substrate with a doctor blade, an air brush, an ink jet printer, by gravure printing, by screen printing, or any combination thereof.
